(19) United States
(12) Patent Application Publication
(10) Pub. No.: US 2024/0276725 A1
(43) Pub. Date: Aug. 15, 2024

(54) THREE-DIMENSIONAL MEMORY DEVICE WITH INTEGRATED CONTACT AND SUPPORT STRUCTURE AND METHOD OF MAKING THE SAME

(71) Applicant: SANDISK TECHNOLOGIES LLC, ADDISON, TX (US)

(72) Inventors: Adarsh RAJASHEKHAR, Santa Clara, CA (US); Senaka KANAKAMEDALA, San Jose, CA (US); Koichi MATSUNO, Fremont, CA (US)

(21) Appl. No.: 18/616,682

(22) Filed: Mar. 26, 2024

Related U.S. Application Data
(63) Continuation-in-part of application No. 18/356,825, filed on Jul. 21, 2023.
(60) Provisional application No. 63/484,619, filed on Feb. 13, 2023.

(51) Int. Cl. H10B 43/27

(52) U.S. Cl. CPC H10B 43/27

(57) ABSTRACT

A memory device includes an alternating stack of insulating layers and electrically conductive layers located over a substrate, memory openings vertically extending through the alternating stack, memory opening fill structures located in the memory openings, each including a respective vertical semiconductor channel and a vertical stack of memory elements, a contact via structure contacting a reference electrically conductive layer that is one of the electrically conductive layers, and at least one silicon oxide liner laterally surrounding a cylindrical portion of the contact via structure and contacting a laterally protruding portion of the contact via structure.

### RELATED APPLICATIONS

This application is a continuation-in-part (CIP) application of U.S. application Ser. No. 18/356,825 filed on Jul. 21, 2023, which claims priority from U.S. Provisional Application Ser. No. 63/484,619 filed on Feb. 13, 2023, the entire contents of which are incorporated herein by reference.

### FIELD

The present disclosure relates generally to the field of semiconductor devices, and particularly to a three-dimensional memory device including through-stack contact via structures and methods for manufacturing the same.

### BACKGROUND

Three-dimensional vertical NAND strings having one bit per cell are disclosed in an article by T. Endoh et al., titled “Novel Ultra High-Density Memory With A Stacked-Surrounding Gate Transistor (S-SGT) Structured Cell”, IEDM Proc. (2001) 33-36.

### SUMMARY

According to an aspect of the present disclosure, a memory device includes an alternating stack of insulating layers and electrically conductive layers located over a substrate, memory openings vertically extending through the alternating stack, memory opening fill structures located in the memory openings, each including a respective vertical semiconductor channel and a vertical stack of memory elements, a contact via structure contacting a reference electrically conductive layer that is one of the electrically conductive layers, and at least one silicon oxide liner laterally surrounding a cylindrical portion of the contact via structure and contacting a laterally protruding portion of the contact via structure.

According to another aspect of the present disclosure, a method of forming a device structure is provided, which comprises: forming an alternating stack of insulating layers and sacrificial material layers over a substrate; forming stepped surfaces by pattering the alternating stack; forming a sacrificial material plate on a top surface segment of one of the sacrificial material layers; forming a dielectric material portion over the sacrificial material plate and over the stepped surfaces; forming a contact via cavity through the dielectric material portion, the sacrificial material plate, and a portion of the alternating stack that underlies the sacrificial material plate; laterally expanding the contact via cavity by laterally recessing at least the sacrificial material plate and said one of the sacrificial material layers to expand the contact via cavity to include a fin cavity; forming a sacrificial via fill structure in the contact via cavity; replacing the sacrificial material layers with material portions including electrically conductive layers; and replacing the sacrificial via fill structure with a contact via structure such that the contact via structure contacts a vertical cylindrical sidewall of the electrically conductive layers.

According to an aspect of the present disclosure, a memory device is provided, which comprises: a first-tier alternating stack of first insulating layers and first electrically conductive layers located over a substrate; a second-tier alternating stack of second insulating layers and second electrically conductive layers overlying the first-tier alternating stack; memory openings vertically extending through the first-tier alternating stack and the second-tier alternating stack; memory opening fill structures located in the memory openings, wherein each of the memory opening fill structures comprises a respective vertical stack of memory elements; and a first support and contact assembly vertically extending through the first-tier alternating stack and the second-tier alternating stack and comprising: a first contact via structure contacting an annular top surface of a first reference electrically conductive layer that is one of the first electrically conductive layers of the first-tier alternating stack and having a top surface located above a horizontal plane including a topmost surface of the second-tier alternating stack; a first dielectric pillar structure having at least one first laterally-protruding fin portion that protrudes outward at each level of a first subset of the first electrically conductive layers that underlies the first reference electrically conductive layer; and a first-tier dielectric spacer that laterally surrounds the first contact via structure, not in direct contact with the first dielectric pillar structure, and vertically extending through each first electrically conductive layer within a second subset of the first electrically conductive layers that overlies the first reference electrically conductive layer.

According to another aspect of the present disclosure, a memory device comprises a first-tier alternating stack of first insulating layers and first electrically conductive layers located over a substrate; a second-tier alternating stack of second insulating layers and second electrically conductive layers overlying the first-tier alternating stack; memory openings vertically extending through the first-tier alternating stack and the second-tier alternating stack; memory opening fill structures located in the memory openings, wherein each of the memory opening fill structures comprises a respective vertical semiconductor channel and a vertical stack of memory elements; a first support and contact assembly vertically extending through the first-tier alternating stack and the second-tier alternating stack and comprising a first contact via structure contacting an annular top surface of a first reference electrically conductive layer that is one of the first electrically conductive layers of the first-tier alternating stack, and a first dielectric pillar structure underlying the first contact via structure, wherein the first dielectric pillar structure lacks an air gap therein; and a second support and contact assembly vertically extending through the first-tier alternating stack and the second-tier alternating stack and comprising a second contact via structure contacting an annular top surface of a second reference electrically conductive layer that is one of the second electrically conductive layers of the second-tier alternating stack, and a second dielectric pillar structure underlying the second contact via structure, wherein the second dielectric pillar structure includes an air gap therein.

According to another aspect of the present disclosure, a method of forming a memory device comprises: forming a first-tier alternating stack of first insulating layers and first sacrificial material layers over a substrate; forming a first-tier via cavity in the first-tier alternating stack; vertically extending a center region of the first-tier via cavity into an upper portion of the substrate without vertically extending a peripheral region of the first-tier via cavity; filling the first-tier via cavity with a first dielectric layer stack and a first sacrificial via fill material portion; forming a second-tier alternating stack of second insulating layers and second sacrificial material layers over the first-tier alternating stack; forming a second-tier via cavity through each second sacrificial material layer of the second-tier alternating stack; filling the second-tier via cavity with a second dielectric layer stack and a second sacrificial via fill material portion; replacing the first sacrificial material layers and the second sacrificial material layers with electrically conductive layers and second electrically conductive layers, respectively; forming a contact via cavity by removing the second sacrificial via fill material portion and the first sacrificial via fill material portion; physically exposing an annular top surface segment of a reference-level electrically conductive layer that is one of the electrically conductive layers by removing an annular portion of the first dielectric layer stack; and forming a first contact via structure in the contact via cavity.

### BRIEF DESCRIPTION OF THE DRAWINGS

FIG. 1A is a vertical cross-sectional view of a first exemplary structure after formation of combinations of a substrate dielectric liner and a sacrificial substrate pad structure according to an embodiment of the present disclosure.

FIG. 1B is a top-down view of the first exemplary structure of FIG. 1A. The hinged vertical plane A-A′ is the plane of the vertical cross-sectional view of FIG. 1A.

FIG. 2A is a vertical cross-sectional view of the first exemplary structure after formation of a first-tier alternating stack of first insulating layers and first sacrificial material layers, first-tier memory openings, and first-tier support openings according to an embodiment of the present disclosure.

FIG. 2B is a partial see-through top-down view of the first exemplary structure of FIG. 2A. The hinged vertical plane A-A′ is the plane of the vertical cross-sectional view of FIG. 2A.

FIG. 3 is a vertical cross-sectional view of the first exemplary structure after formation of first-tier sacrificial opening fill structures and an inter-tier insulating layer according to an embodiment of the present disclosure.

FIG. 4A is a vertical cross-sectional view of the first exemplary structure after formation a first patterned hard mask layer and first-tier contact via cavities according to an embodiment of the present disclosure.

FIG. 4B is a partial see-through top-down view of the first exemplary structure of FIG. 4A. The hinged vertical plane A-A′ is the plane of the vertical cross-sectional view of FIG. 4A.

FIG. 5 is a vertical cross-sectional view of the first exemplary structure after formation of a first sacrificial spacer material layer according to an embodiment of the present disclosure.

FIG. 6 is a vertical cross-sectional view of the first exemplary structure after formation of a first patterned photoresist layer and after performing a first anisotropic etch process that vertically extends center portions of the first-tier contact via cavities according to an embodiment of the present disclosure.

FIG. 7 is a vertical cross-sectional view of the first exemplary structure after removal of remaining portions of the first sacrificial spacer material layer and the first patterned hard mask layer and removal of the sacrificial substrate pad structures according to an embodiment of the present disclosure.

FIG. 8 is a vertical cross-sectional view of the first exemplary structure after formation of a first continuous dielectric liner according to an embodiment of the present disclosure.

FIG. 9 is a vertical cross-sectional view of the first exemplary structure after formation of a first continuous dielectric material layer according to an embodiment of the present disclosure.

FIG. 10 is a vertical cross-sectional view of the first exemplary structure after formation of a first dielectric fill material layer according to an embodiment of the present disclosure.

FIG. 11 is a vertical cross-sectional view of the first exemplary structure after deposition and vertical recessing of a first sacrificial via fill material according to an embodiment of the present disclosure.

FIG. 12 is a vertical cross-sectional view of the first exemplary structure after formation of in-process first-via-cavity fill structures according to an embodiment of the present disclosure.

FIG. 13 is a vertical cross-sectional view of the first exemplary structure after formation of a second-tier alternating stack of second insulating layers and second sacrificial material layers according to an embodiment of the present disclosure.

FIG. 14 is a vertical cross-sectional view of the first exemplary structure after formation of second-tier memory openings and second-tier support openings according to an embodiment of the present disclosure.

FIG. 15 is a vertical cross-sectional view of the first exemplary structure after formation of inter-tier memory openings and inter-tier support openings according to an embodiment of the present disclosure.

FIG. 16A is a vertical cross-sectional view of the first exemplary structure after formation of memory opening fill structures and support pillar structures according to an embodiment of the present disclosure.

FIG. 16B is a partial see-through top-down view of the first exemplary structure of FIG. 16A. The hinged vertical plane A-A′ is the plane of the vertical cross-sectional view of FIG. 16A.

FIG. 17A is a vertical cross-sectional view of the first exemplary structure after formation a first contact-level dielectric layer, a second patterned hard mask layer, and second-tier contact via cavities according to an embodiment of the present disclosure.

FIG. 17B is a partial see-through top-down view of the first exemplary structure of FIG. 17A. The hinged vertical plane A-A′ is the plane of the vertical cross-sectional view of FIG. 17A.

FIG. 18 is a vertical cross-sectional view of the first exemplary structure after formation of a second sacrificial spacer material layer according to an embodiment of the present disclosure.

FIG. 19 is a vertical cross-sectional view of the first exemplary structure after formation of a second patterned photoresist layer and after performing a second anisotropic etch process that vertically extends center portions of a first subset of the second-tier contact via cavities according to an embodiment of the present disclosure.

FIG. 20 is a vertical cross-sectional view of the first exemplary structure after removal of remaining portions of the second sacrificial spacer material layer and the second patterned hard mask layer, removal of a first subset of first sacrificial via fill material portions, and formation of a second continuous dielectric liner according to an embodiment of the present disclosure.

FIG. 21 is a vertical cross-sectional view of the first exemplary structure after formation of a second continuous dielectric material layer according to an embodiment of the present disclosure.

FIG. 22 is a vertical cross-sectional view of the first exemplary structure after formation of a second dielectric fill material layer according to an embodiment of the present disclosure.

FIG. 23 is a vertical cross-sectional view of the first exemplary structure after formation of a third patterned photoresist layer and after performing a third anisotropic etch process that vertically extends center portions of a second subset of the third-tier contact via cavities according to an embodiment of the present disclosure.

FIG. 24 is a vertical cross-sectional view of the first exemplary structure after deposition and vertical recessing of a second sacrificial via fill material according to an embodiment of the present disclosure.

FIG. 25 is a vertical cross-sectional view of the first exemplary structure after formation of in-process second-via-cavity fill structures according to an embodiment of the present disclosure.

FIG. 26A is a vertical cross-sectional view of the first exemplary structure after formation of a second contact-level dielectric layer and backside trenches according to an embodiment of the present disclosure.

FIG. 26B is a partial see-through top-down view of the first exemplary structure of FIG. 26A. The hinged vertical plane A-A′ is the plane of the vertical cross-sectional view of FIG. 26A.

FIG. 27 is a vertical cross-sectional view of the first exemplary structure after replacement of sacrificial material layers with electrically conductive layers according to an embodiment of the present disclosure.

FIG. 28 is a vertical cross-sectional view of the first exemplary structure after formation of backside trench fill structures according to an embodiment of the present disclosure.

FIG. 29A is a vertical cross-sectional view of the first exemplary structure after formation of a third contact-level dielectric layer and connection via cavities according to an embodiment of the present disclosure.

FIG. 29B is a partial see-through top-down view of the first exemplary structure of FIG. 29A. The hinged vertical plane A-A′ is the plane of the vertical cross-sectional view of FIG. 29A.

FIG. 30 is a vertical cross-sectional view of the first exemplary structure after removal of second sacrificial via fill material portions and a second subset of the first sacrificial via fill material portions according to an embodiment of the present disclosure.

FIG. 31 is a vertical cross-sectional view of the first exemplary structure after performing a first anisotropic etch process that removes horizontally-extending portions of the second dielectric fill material layer and first dielectric fill material layer according to an embodiment of the present disclosure.

FIG. 32 is a vertical cross-sectional view of the first exemplary structure after performing an isotropic etch process that isotropically recesses remaining portions of the second dielectric fill material layer and first dielectric fill material layer according to an embodiment of the present disclosure.

FIG. 33 is a vertical cross-sectional view of the first exemplary structure after performing a second anisotropic etch process that removes horizontally-extending portions of the second dielectric material layers and the first dielectric material layers according to an embodiment of the present disclosure.

FIG. 34 is a vertical cross-sectional view of the first exemplary structure after performing an etch process that removes horizontally-extending portions of the second dielectric liners and the first dielectric liners according to an embodiment of the present disclosure.

FIG. 35A is a vertical cross-sectional view of the first exemplary structure after formation of contact via structures on physically exposed annular surfaces of the electrically conductive layers according to an embodiment of the present disclosure.

FIG. 35B is a partial see-through top-down view of the first exemplary structure of FIG. 35A. The hinged vertical plane A-A′ is the plane of the vertical cross-sectional view of FIG. 35A.

FIGS. 36, 37 and 38 are vertical cross-sectional views of the first exemplary structure according to an alternative embodiment of the present disclosure.

FIG. 39 is a vertical cross-sectional view of a second exemplary structure after formation of a first-tier alternating stack according to an embodiment of the present disclosure.

FIGS. 40A-40J are sequential vertical cross-sectional views of a region of the second exemplary structure during formation of a sacrificial via fill structure according to an embodiment of the present disclosure.

FIGS. 41A-41E are sequential vertical cross-sectional views of a region of a first configuration of the second exemplary structure during replacement of sacrificial material layers with electrically conductive layers and replacement of the sacrificial via fill structures with contact via structures according to an embodiment of the present disclosure.

FIGS. 42A-42E are sequential vertical cross-sectional views of a region of a second configuration of the second exemplary structure during replacement of sacrificial material layers with electrically conductive layers and replacement of the sacrificial via fill structures with contact via structures according to an embodiment of the present disclosure.

### DETAILED DESCRIPTION

As discussed above, the present disclosure is directed to a three-dimensional memory device including through-stack contact via structures and methods for manufacturing the same, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased by in a single erase operation. Each block contains a number of pages, which are the smallest unit that can be programmed, i.e., a smallest unit on which a read operation can be performed.

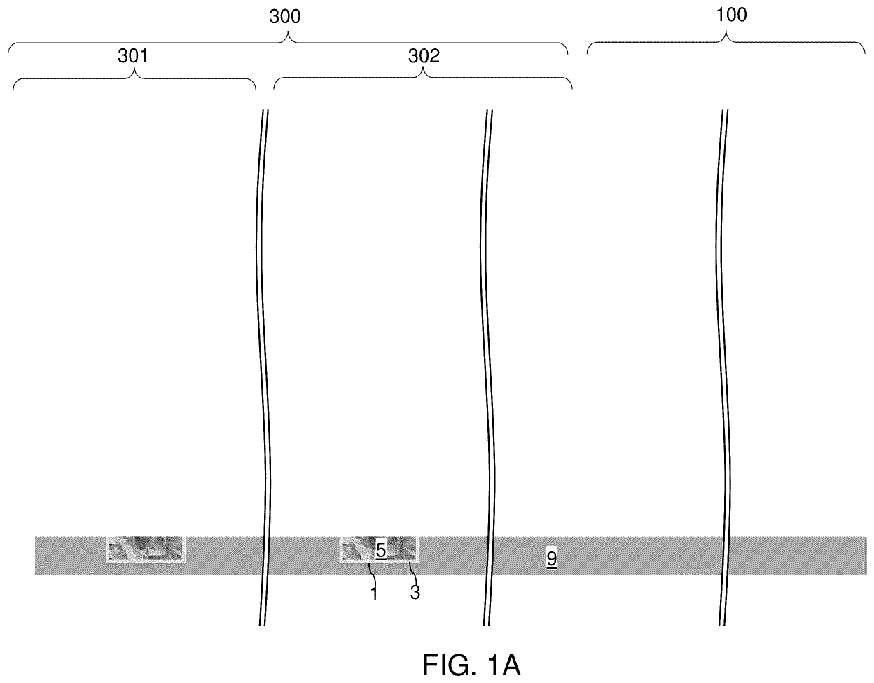

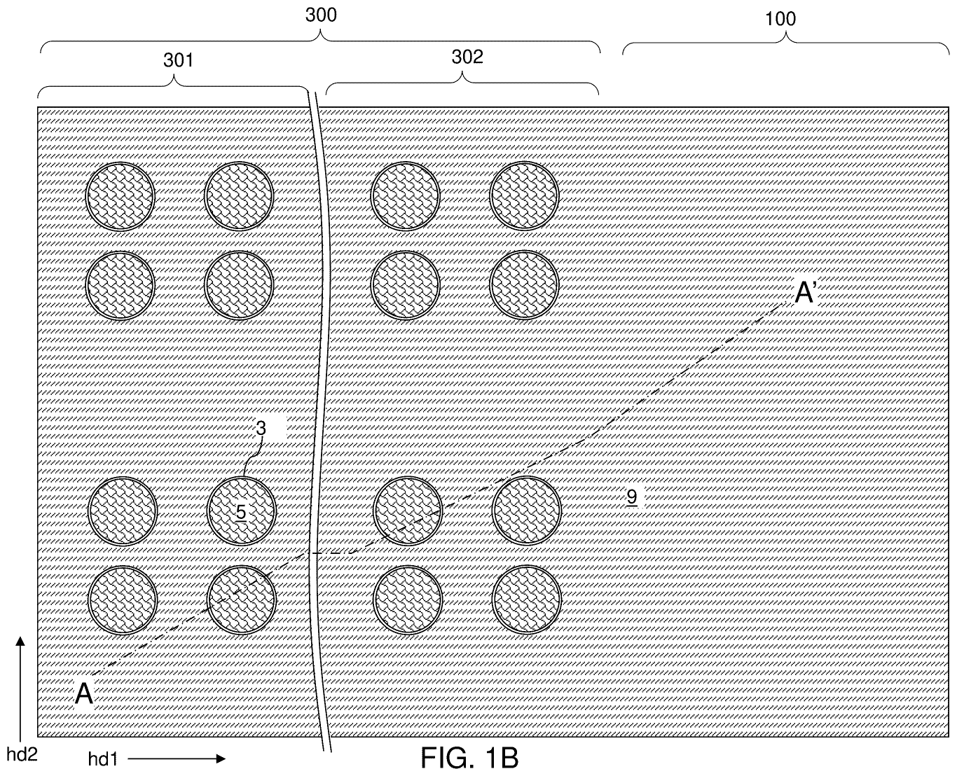

Referring to FIGS. 1A and 1B, a first exemplary structure according to a first embodiment of the present disclosure is illustrated, which includes a substrate 9 containing a semiconductor material layer at least at an upper portion thereof. The semiconductor material layer may comprise a single crystalline semiconductor material layer or a polycrystalline semiconductor material layer. The substrate 9 may or may not comprise additional layers (such as dielectric material layers embedding metal interconnect structures) and/or semiconductor devices (such as a peripheral circuit for controlling operation of a three-dimensional memory array to be subsequently formed) underneath the semiconductor material layer. In one embodiment, the substrate 9 may comprise a commercially available semiconductor wafer such as a single crystalline silicon wafer. The semiconductor material layer may comprise an upper portion of the silicon wafer, a doped well in the silicon wafer, an epitaxial silicon layer on the silicon wafer, etc.

An array of substrate recesses 1 may be formed in the upper portion of the substate in a contact region 300. The contact region 300 may comprise a first contact region 301 in which first contact via structures providing electrical connections to first electrically conductive layers are subsequently formed, and a second contact region 302 in which second contact via structures providing electrical connections to second electrically conductive layers are subsequently formed. A memory array region 100 can be provided adjacent to the contact region. In one embodiment, the substrate recesses 1 may be arranged as rows that laterally extend along a first horizontal direction (e.g., word line direction) hd1, which is the perpendicular to a boundary between the memory array region 100 and the contact region 300. The rows of the substrate recesses 1 may be laterally spaced apart from each other along a second horizontal direction (e.g., bit line direction) hd2, which can be perpendicular to the first horizontal direction hd1 and is parallel to the boundary between the memory array region 100 and the contact region 300.

The depth of the substrate recesses 1 may be in a range from 50 nm to 500 nm, and the lateral dimensions (such as a diameter) of the recesses may be in a range from 200 nm to 2,000 nm, although lesser and greater dimensions may also be employed for the depth and the lateral dimensions. A substrate dielectric liner layer including a dielectric material (such as silicon oxide) can be deposited in the substrate recesses 1, and a sacrificial fill material (which is also referred to as a sacrificial substrate fill material or a substrate pad fill material) can be deposited in remaining volumes of the substrate recesses. The sacrificial fill material may comprise a carbon material (e.g., amorphous carbon or diamond-like carbon) or a metal (e.g., tungsten). Excess portions of the sacrificial fill material and the substrate dielectric liner layer can be removed from above the horizontal plane including a top surface of the substrate 9 by performing a planarization process such as a chemical mechanical planarization process. Each remaining portion of the sacrificial fill material constitutes a sacrificial substrate pad 5. Each remaining portion of the substrate dielectric liner layer constitutes a substrate dielectric liner 3. Each contiguous combination of a substrate dielectric liner 3 and a sacrificial substrate pad 5 fills a respective substrate recess 1.

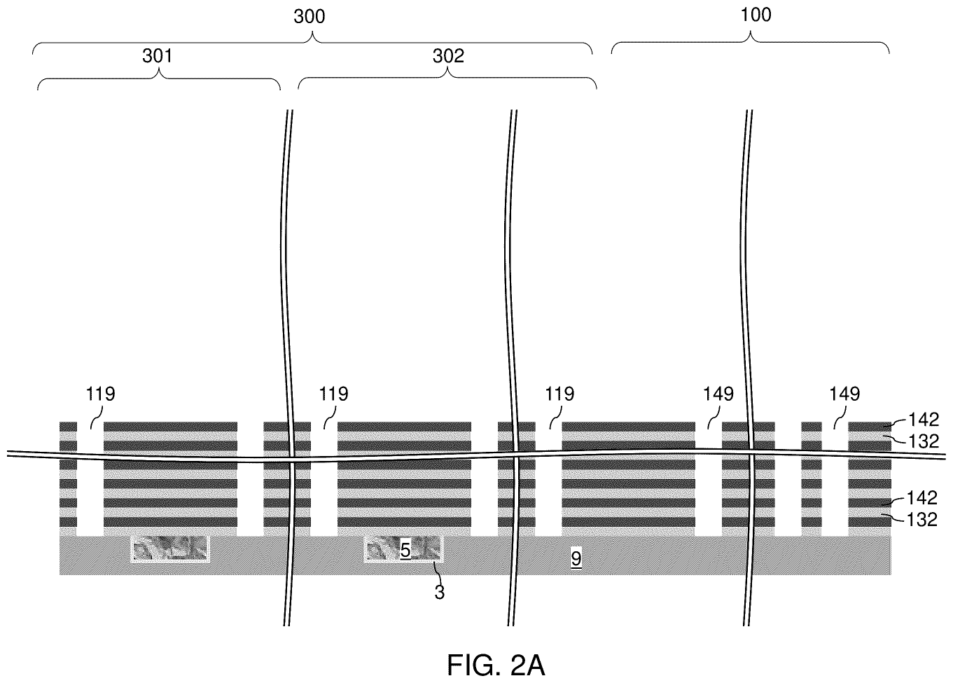

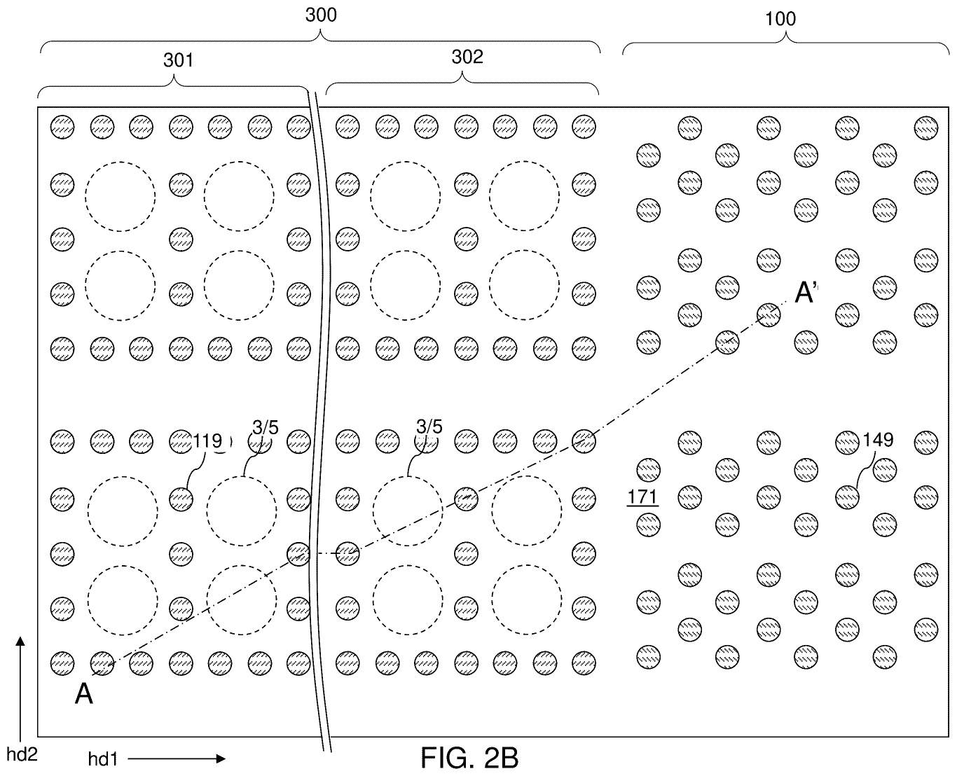

Referring to FIGS. 2A and 2B, a first-tier alternating stack of first insulating layers 132 and first sacrificial material layers 142 can be formed over the substrate 9. The first insulating layers 132 comprise an insulating material such as undoped silicate glass or a doped silicate glass, and the first sacrificial material layers 142 comprise a sacrificial material such as silicon nitride or a silicon-germanium alloy. The first-tier alternating stack (132, 142) may comprise multiple repetitions of a unit layer stack including a first insulating layer 132 and a first sacrificial material layer 142. The total number of repetitions of the unit layer stack within the first-tier alternating stack (132, 142) may be, for example, in a range from 8 to 1,024, such as from 32 to 256, although lesser and greater number of repetitions may also be employed. Each of the first insulating layers 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed.

An etch mask layer (not shown) can be formed over the first-tier alternating stack (132, 142), and can be lithographically patterned to form various openings therein. An anisotropic etch process can be performed to transfer the pattern of the openings in the etch mask layer through the first-tier alternating stack (132, 142). First-tier openings (149, 119) can be formed through the first-tier alternating stack (132, 142). The first-tier openings (149, 119) may comprise first-tier memory openings 149 that vertically extend through each layer within the first-tier alternating stack (132, 142) in the memory array region 100, and may further comprise first-tier support openings 119 that are formed through the first-tier alternating stack (132, 142) in the contact region 300 and are subsequently employed to form support pillar structures therein. In one embodiment, the first-tier memory openings 149 may be formed in rows that laterally extend along the first horizontal direction hd1. The rows of first-tier memory openings 149 may be laterally spaced apart along the second horizontal direction hd1 that is perpendicular to the first horizontal direction hd1. In one embodiment, the first-tier memory openings 149 may be formed as periodic two-dimensional arrays (such as hexagonal periodic two-dimensional arrays). The etch mask layer can be subsequently removed.

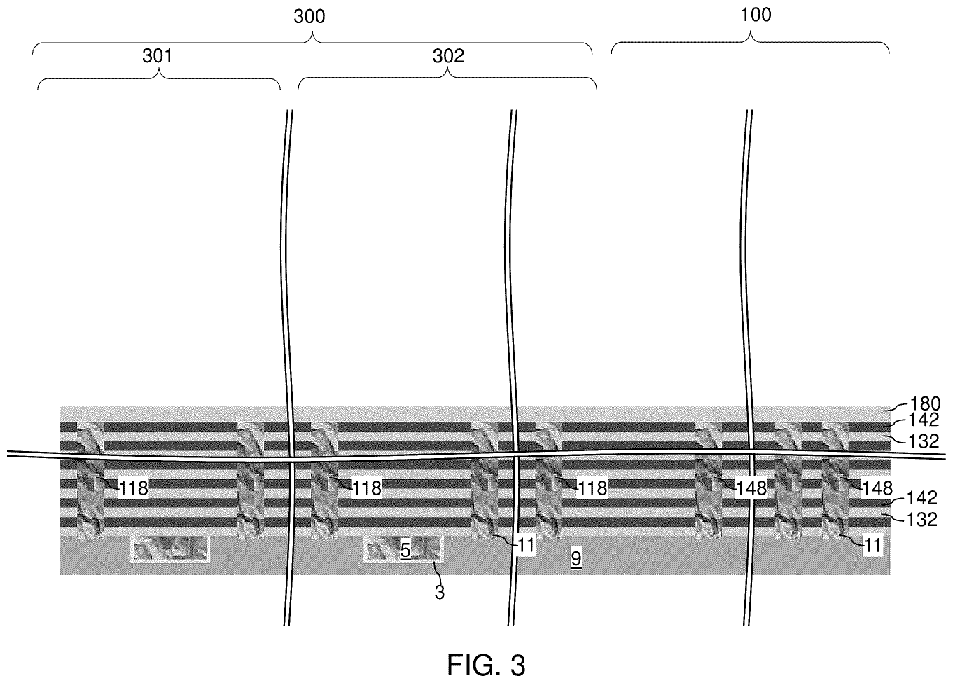

Referring to FIG. 3, pedestal channel portions 11 can optionally be formed at the bottom of each of the first-tier openings (149, 119). The pedestal channel portions 11 may comprise a semiconductor material that can be deposited by a selective semiconductor material deposition process which grows a semiconductor material from physically exposed surfaces of the substrate 9. A selective semiconductor deposition process such as a selective epitaxy process may be employed to form the pedestal channel portions 11. The pedestal channel portion 11 may comprise single crystalline silicon in epitaxial alignment with a single crystalline semiconductor material in the substrate 9, or may comprise a polycrystalline semiconductor material (e.g., polysilicon). In one embodiment the top surfaces of the pedestal channel portions 11 may be formed below an interface between the bottommost first insulating layer 132 and the bottommost first sacrificial material layer 142.

A first-tier sacrificial fill material may be deposited in the remaining unfilled volumes of the first-tier openings (149, 119). Excess portions of the first-tier sacrificial fill material can be removed from above the horizontal plane including the top surface of the topmost first insulating layer 132 by performing a planarization process. Each remaining portion of the first-tier sacrificial fill material constitutes a first-tier sacrificial opening fill structure (148, 118). The first-tier sacrificial opening fill structure (148, 118) comprises first-tier sacrificial memory opening fill structures 148 that are formed in the first-tier memory openings 149, and first-tier sacrificial support opening fill structures 118 that are formed in the first-tier support openings 119. The first-tier sacrificial fill material may comprise amorphous carbon, diamond-like carbon, a semiconductor material, organosilicate glass, a polymer material, or any other material that can be subsequently removed selective to materials of the first-tier alternating stack (132, 142) and the pedestal channel portions 11.

An insulating layer may be optionally formed over the first-tier alternating stack (132, 142). The insulating layer, if formed, is herein referred to as an inter-tier insulating layer 180. The inter-tier insulating layer 180 may have the same material composition as and about the same thickness range as the first insulating layers 132.

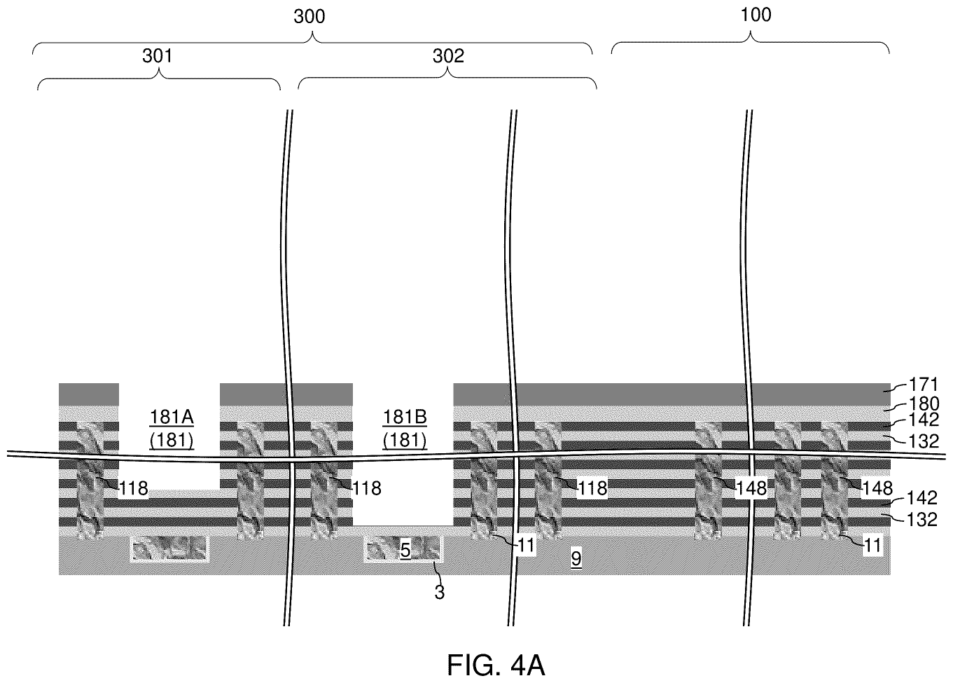

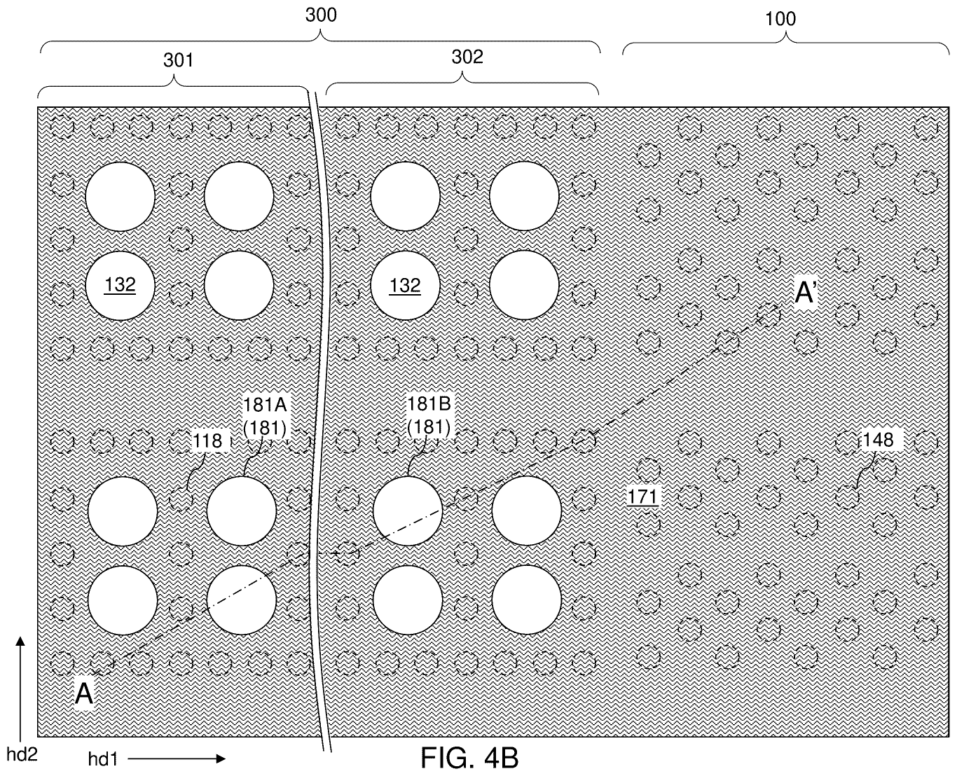

Referring to FIGS. 4A and 4B, a first patterned hard mask layer 171 may be formed above the inter-tier insulating layer 180 by depositing and patterning a hard mask material. The first patterned hard mask layer 171 comprises a material that can function as an etch mask material during subsequent anisotropic etch processes. In one embodiment, the first patterned hard mask layer 171 may comprise a semiconductor material, such as amorphous silicon, and may have a thickness in a range from 50 nm to 500 nm, although lesser and grater thicknesses may be employed. The hard mask material may be patterned by applying and lithographically patterning a photoresist material over the hard mask material, and by transferring the pattern in the photoresist material through the hard mask material. In one embodiment, the pattern of the openings in the first patterned hard mask layer 171 may be the same as the pattern of the substrate recesses 1 (in which the substrate dielectric liners 3 and a sacrificial substrate pads 5 are present), or may be modified from the pattern of the substrate recesses 1 such that each opening in the first patterned hard mask layer 171 has at least partial overlap with the pattern of a respective substrate recess 1. In some embodiments, each opening in the first patterned hard mask layer 171 may have a periphery that is located on or outside a periphery of a respective underlying substrate recess 1 in a top-down view.

First-tier via cavities 181 are formed through a respective subset of layers within the first-tier alternating stack (132, 142). Each of the first-tier via cavities 181 can vertically extend through the inter-tier dielectric layer 170 and through a respective subset of the first sacrificial material layers 142 and the first insulating layers 132 such that a top surface of a selected first insulating layer 132 is physically exposed at the bottom of each first-tier via cavity 181. In one embodiment, the first-tier via cavities 181 may have different depths from each other, and each first insulating layer 132 an be physically exposed to a respective overlying first-tier via cavity 181.

The first-tier via cavities 181 having different depths may be formed employing a plurality of masked anisotropic etch processes. In an illustrative example, the openings in the first patterned hard mask layer 171 may have the pattern of all of the first-tier via cavities 181 to be subsequently formed. An anisotropic etch process may be performed to transfer the pattern of the openings in the first patterned hard mask layer 171 through the inter-tier insulating layer 180

Subsequently, multiple iterations of a combination of a respective masking process and a respective anisotropic etch process may be performed to etch through a respective subset of first sacrificial material layers 142 and a respective subset of the first insulating layers 132. Each masking process forms a respective patterned photoresist layer (not shown) that masks a respective subset of the openings in the first patterned hard mask layer 171 without masking a respective complementary subset of the openings. Each anisotropic etch process etches a respective number of first sacrificial material layers 142 and a respective number of insulating layers 32 underneath each opening in the first pattered hard mask layer 171 that is not masked by a respective patterned photoresist layer. In one embodiment, the number of etched first sacrificial material layers 142 and etched first insulating layers 132 underneath unmasked openings in the first patterned hard mask layer 171 may be a non-negative integer power of 2, i.e., 1, 2, 4, 8, 16, 32, 64, etc. By employing a combination of various masking patterns for the patterned photoresist layers, the total depths of the first-tier via cavities 181 can be varied to enable physical exposure of the top surfaces of first insulating layers 132 at each level. The first patterned hard mask layer 171 can be subsequently removed.

The first-tier via cavities 181 may comprise first-type first-tier via cavities 181A that are formed in the first contact region 301 and second-type first-tier via cavities 181B that are formed in the second contact region 302. In one embodiment, the first-type first-tier via cavities 181A have various depths such that each of the first insulating layers 132 and the inter-tier insulating layer 180 has a top surface segment that is physically exposed to a respective overlying first-type first-tier via cavity 181A. In one embodiment, each of the second-type first-tier via cavities 181B may extend through each layer within the first-tier alternating stack (132, 142) except the bottommost first insulating layer 132. In this case, each of the second-type first-tier via cavities 181B may vertically extend through each first sacrificial material layer 142 in the first-tier alternating stack (132, 142). The lateral dimensions (such as diameters) of the first-tier via cavities 181 may be in a range from 200 nm to 3,000 nm, although lesser and greater lateral dimensions may also be employed.

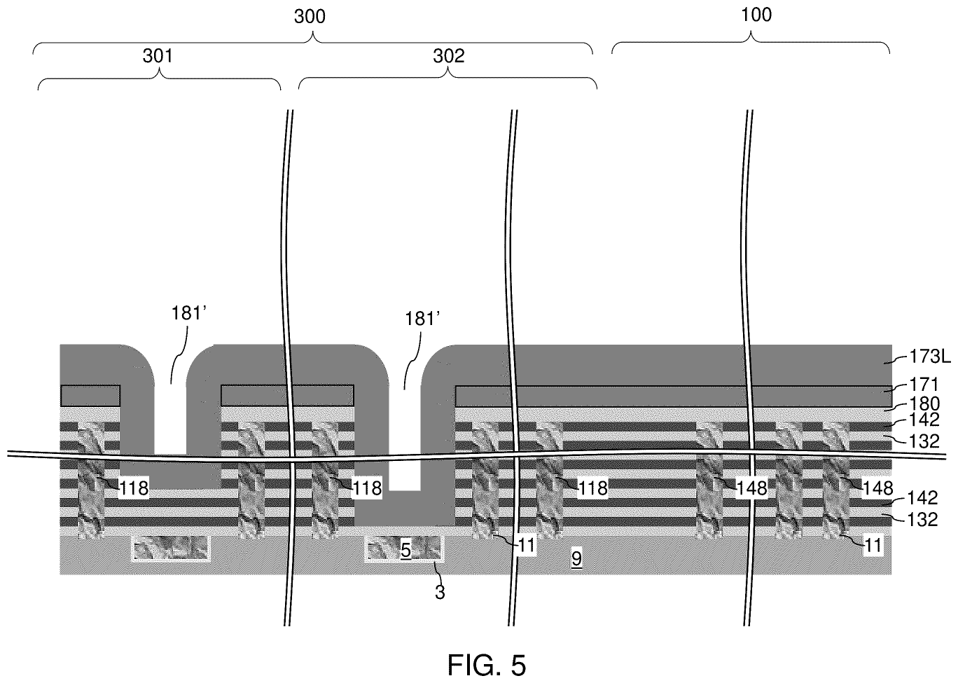

Referring to FIG. 5, a first sacrificial spacer material layer 173L can be deposited over the first patterned hard mask layer 171 and in peripheral portions of the first-tier via cavities 181. The first sacrificial spacer material layer 173L comprises a material that may be subsequently employed as an etch mask material for the materials of the first-tier alternating stack (132, 142). In one embodiment, the first sacrificial spacer material layer 173L comprises a semiconductor material, such as polysilicon or amorphous silicon. The thickness of the first sacrificial spacer material layers 173L may be in a range from 50 nm to 1,000 nm, although lesser and greater thicknesses may also be employed. A void 181′ can be formed within each volume of the first-tier via cavities 181 that is not filled with the first sacrificial spacer material layer 173L.

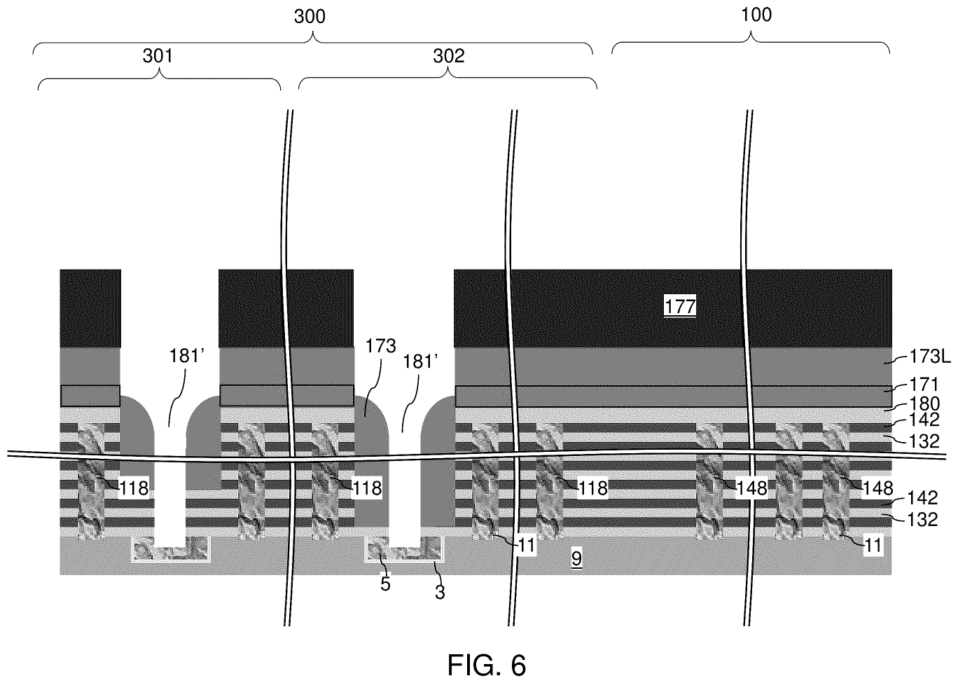

Referring to FIG. 6, a first patterned photoresist layer 177 can be formed over the first sacrificial spacer material layer 173L. Generally, the first patterned photoresist layer 177 may have openings in the areas of the first-tier via cavities 181. For example, the openings in the first patterned photoresist layer 177 may be located at, or may be located within, a periphery of a respective one of the first-tier cavities 181 in a plan view, such as a top-down view.

A first anisotropic etch process can be performed to vertically extend center portions of the first-tier contact via cavities 181 that are laterally surrounded by vertically-extending portions of the first sacrificial spacer material layer 173L. The first anisotropic etch process may include a first anisotropic etch step that etches the material of the first sacrificial spacer material layer 173L. Portions of the first sacrificial spacer material layer 173L that are not masked by the first patterned photoresist layer 177 are vertically recessed uniformly. Each portion of the first sacrificial spacer material layer 173L that underlies a respective void 181′ is etched through, and a top surface segment of a respective underlying first insulating layer 132 (or the inter-tier insulating layer 180) is physically exposed underneath the respective void 181′. A tubular portion of the first sacrificial spacer material layer 173L remains in the peripheral region of each first-tier via cavity 181 while a center portion of the first sacrificial spacer material layer 173L in each first-tier via cavity 181 is etched through during the first anisotropic etch step of the first anisotropic etch process. Each tubular portion of the first sacrificial spacer material layer 173L that remains in a respective first-tier cavity 181 constitutes a first sacrificial spacer 173.

The first anisotropic etch process may include a second anisotropic etch step that etches the materials of the first insulating layers 132 and the first sacrificial material layers 142 selective to the materials of the first sacrificial spacers 173 and the sacrificial substrate pads 5. The second anisotropic etch step of the first anisotropic etch process etches portions of the first-tier alternating stack (132, 142) that underlie the first-tier via cavities 181 and are not covered by the tubular portions of the first sacrificial spacer material layer 173L, i.e., the first sacrificial spacers 173. Each center region of the first-tier via cavities 181 can be vertically extended into a respective sacrificial substrate pad 5 that fills a respective substrate recess while the peripheral region of the first-tier via cavities 181 occupied by the first sacrificial spacers 173 are not vertically extended.

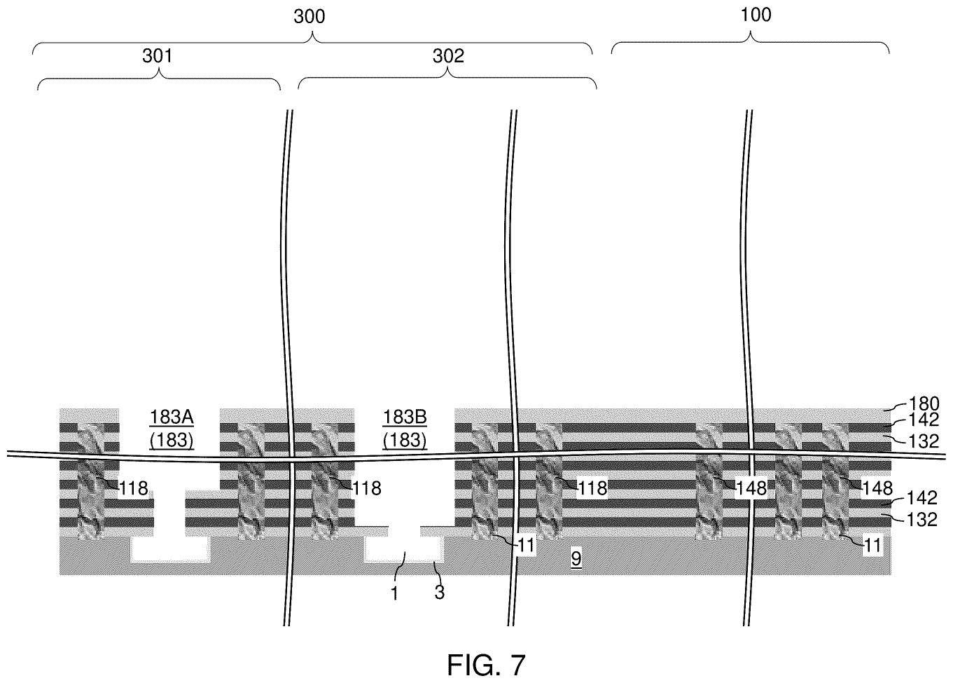

Referring to FIG. 7, the first patterned photoresist layer 177, the first sacrificial spacer material layer 173L, the first sacrificial spacers 173, and the first patterned hard mask layer 171, and the sacrificial substrate pads 5 can be subsequently removed. For example, the first patterned photoresist layer 177 can be removed by performing an ashing process. In case the first sacrificial spacer material layer 173L, the first sacrificial spacers 173, and the first patterned hard mask layer 171, and the sacrificial substrate pads 5 comprise semiconductor materials, such as polysilicon or amorphous silicon, a wet etch process employing tetramethylammonium hydroxide (TMAH) or trimethyl-2 hydroxyethyl ammonium hydroxide (“hot TMY”) may be performed to remove the first sacrificial spacer material layer 173L, the first sacrificial spacers 173, and the first patterned hard mask layer 171, and the sacrificial substrate pads 5. If the sacrificial substrate pads 5 comprise carbon, then they may be removed by ashing. Stepped cavities having a wider upper portion and a narrower lower portion can be formed.

After the above removal steps, the first-tier via cavities 181 vertically extend through the entirety of the first-tier alternating stack (132, 142) and are referred to as first through-tier cavities 183. The first through-tier cavities 183 extend into an upper portion of the substrate 9. Each of the first through-tier cavities 183 includes the entire volume of a respective one of the first-tier via cavities 181 as formed at the processing steps of FIGS. 4A and 4B. The first through-tier cavities 183 further comprise voids that are formed by the second anisotropic etch process and by removal of the first sacrificial spacers 173 and the sacrificial substrate pads 5. The first through-tier cavities 183 can include first-type through-tier cavities 183A that are formed in the first contact region 301 and second-type through-tier cavities 183B that are formed in the second contact region 302.

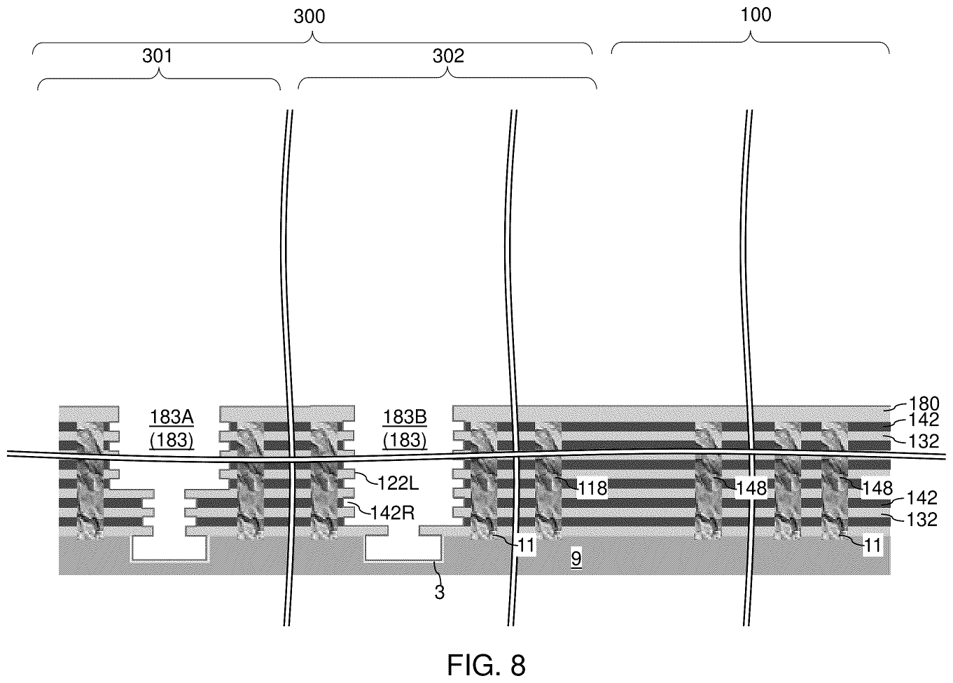

Referring to FIG. 8, a selective isotropic etch process can be performed to laterally recess the first sacrificial material layers 142 selective to the materials of the first insulating layers 132. For example, if the first sacrificial material layers 142 comprise silicon nitride, a wet etch process employing hot phosphoric acid can be performed to laterally recess the first sacrificial material layers 142. Generally, sidewalls of the first sacrificial material layers 142 may be laterally recessed relative to sidewalls of the first insulating layers 132 around the first through-tier cavities 183. Each of the first through-tier cavities 183 may comprise a respective set of lateral protrusions at each level of the first sacrificial material layers 142 (i.e., a lateral recess 142R is formed each level of the first sacrificial material layers 142). A first continuous dielectric liner layer 122L can be deposited in the first through-tier cavities 183, including in the lateral recesses 142R by a conformal deposition process. The first continuous dielectric liner layer 122L comprises a dielectric material, such as silicon oxide, and may have a thickness in a range from 3 nm to 10 nm, although lesser and greater thicknesses may also be employed. Alternatively, the silicon oxide first continuous dielectric liner layer 122L can be formed by radical oxidation (e.g., in-situ steam generation (ISSG)) of exposed silicon nitride sacrificial material layers 142.

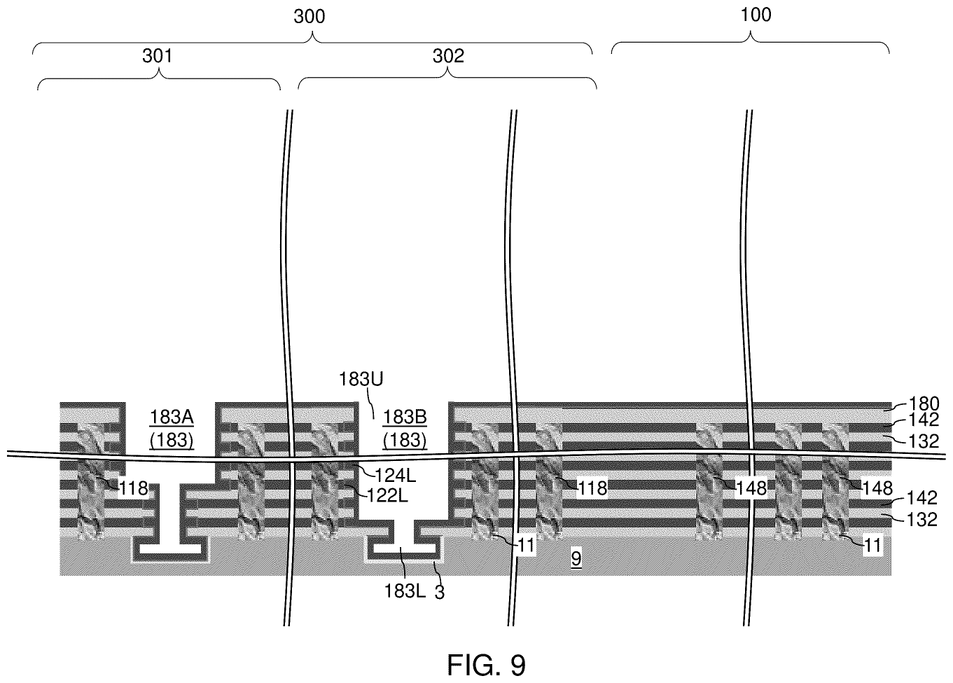

Referring to FIG. 9, a first continuous dielectric material layer 124L can be conformally deposited to fill remaining volumes of the lateral recesses 142R in the first sacrificial material layers 142 around the first through-tier cavities 183. The first continuous dielectric material layer 124L comprises a dielectric material, such as silicon nitride or silicon carbonitride, which is different from the material of the first continuous dielectric liner layer 122L. The thickness of the first continuous dielectric material layer 124L may be in a range from 30 nm to 300 nm, although lesser and greater thicknesses may also be employed. Each remaining volume of the first through-tier cavities 183 includes a narrower lower portion 183L below the bottommost first insulating layer 132 and a wider upper portion 183U above the bottommost first insulating layer 132.

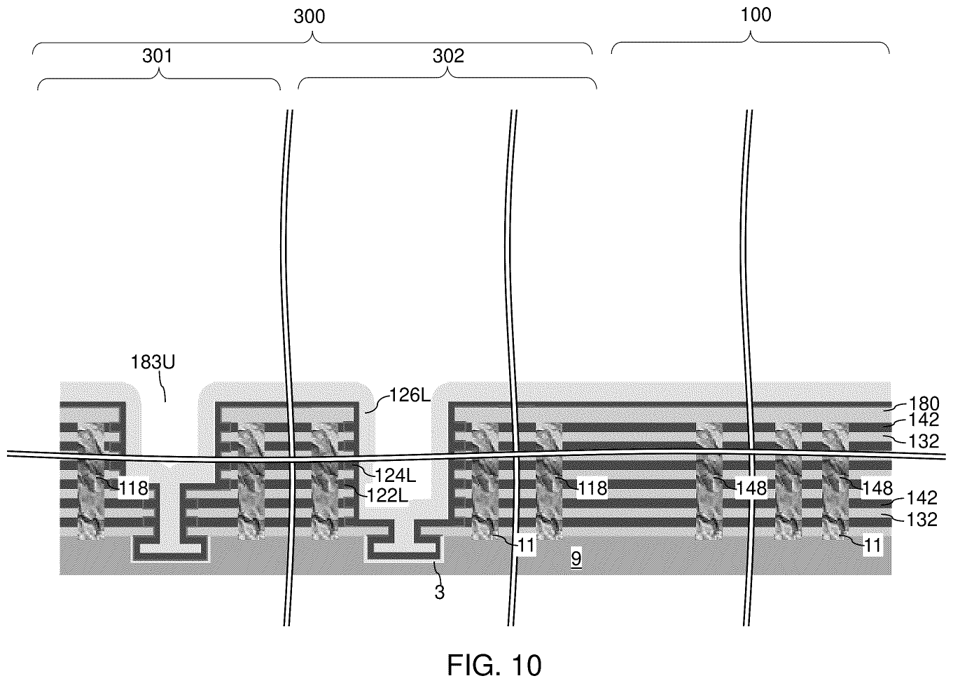

Referring to FIG. 10, a first dielectric fill material layer 126L can be deposited to fill a narrower lower portion 183L of each of the first through-tier cavities 183 without completely filling a wider upper portion 183U of each of the first through-tier cavities 183. The first dielectric fill material layer 126L comprises a dielectric fill material such as silicon oxide.

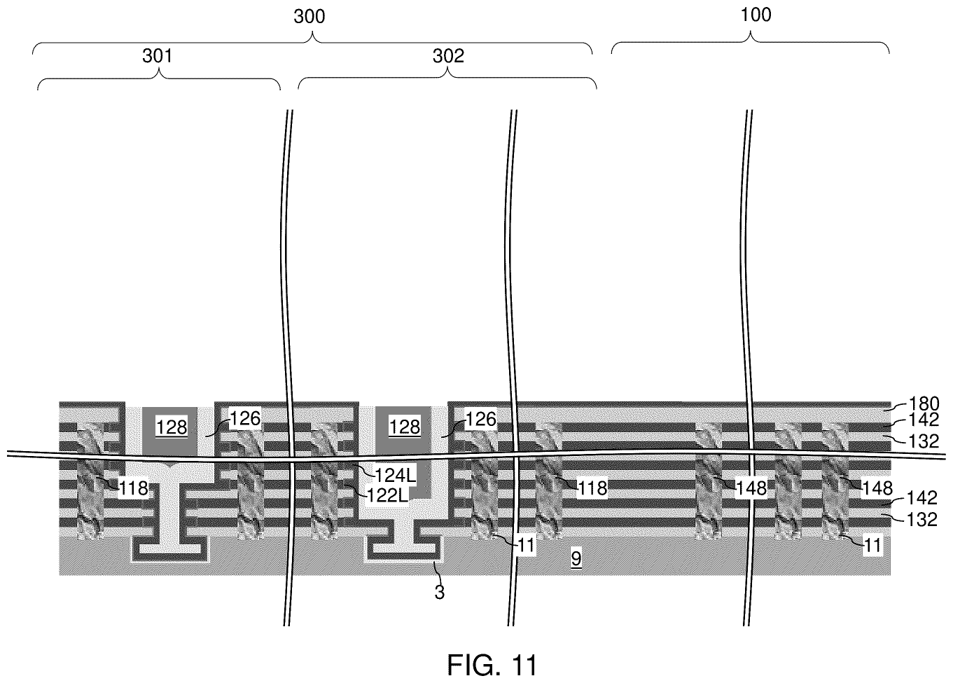

Referring to FIG. 11, a first sacrificial via fill material can be deposited in remaining unfilled volumes (e.g., the upper portions 183U) of the first through-tier cavities 183. The first sacrificial via fill material comprise a different fill material than the material of the first dielectric fill material layer 126L. In one embodiment, the first sacrificial via fill material may comprise a semiconductor material, such as polysilicon or amorphous silicon, or may comprise a carbon-based material, such as amorphous carbon or diamond-like carbon. The first sacrificial via fill material may be vertically recessed by CMP such that remaining portions of the first a sacrificial via fill material have top surfaces roughly at a horizontal plane including a topmost surface of the first continuous dielectric material layer 124L. Each remaining portion of the first sacrificial via fill material is herein referred to as a first sacrificial via fill material portion 128.

Horizontally-extending portions of the first dielectric fill material layer 126L can be removed from above the horizontal plane including the topmost a surface of the first continuous dielectric material layer 124L, for example, by performing a recess etch back process. The continuous dielectric material layer 124L may act as an etch stop during the recess etch back process. Each remaining portion of the first dielectric fill material layer 126L located within a respective one of the first through-tier cavities 183 is herein referred to as a first dielectric fill material portion 126.

Referring to FIG. 12, horizontally-extending portions of the first continuous dielectric material layer 124L and the first continuous dielectric liner layer 122L located above the horizontal plane including the top surface of the inter-tier insulating layer 180 can be removed, for example, by performing a series etch back processes. Optionally, segments of the first dielectric fill material portion 126 and the first sacrificial via fill material portion 128 that protrude the above the horizontal plane including the top surface of the inter-tier insulating layer 180 can be removed, for example, by performing a touch-up planarization process, such as a chemical mechanical polishing (CMP) process. Each remaining portion of the first continuous dielectric liner layer 122L constitutes a first dielectric liner 122. Each remaining portion of the first continuous dielectric material layer 124L constitutes a first dielectric material layer 124.

The set of all material portions that fills a first through-tier cavity 183 constitutes an in-process first-via-cavity fill structure 130, i.e., an in-process of fill structure that fills a respective via cavity. Each in-process first-via-cavity fill structure 130 comprises a substrate dielectric liner 3, a first dielectric liner 122, a first dielectric material layer 124, a first dielectric fill material portion 126, and a first sacrificial via fill material portion 128. In one embodiment, top surfaces of the first dielectric liners 122, the first dielectric material layers 124, the first dielectric fill material portions 126, and the first sacrificial via fill material portions 128 may be formed within the horizontal plane including the top surface of the inter-tier insulating layer 180. Each contiguous set of a first dielectric liner 122, a first dielectric material layer 124, and a first dielectric fill material portion 126 is herein referred to as a first dielectric layer stack (122, 124, 126).

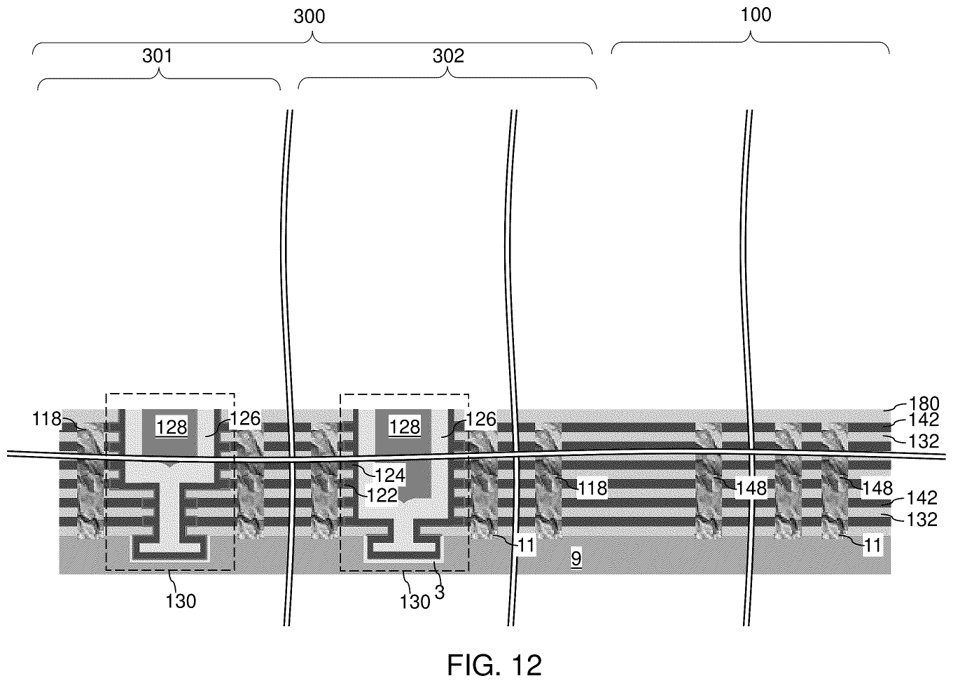

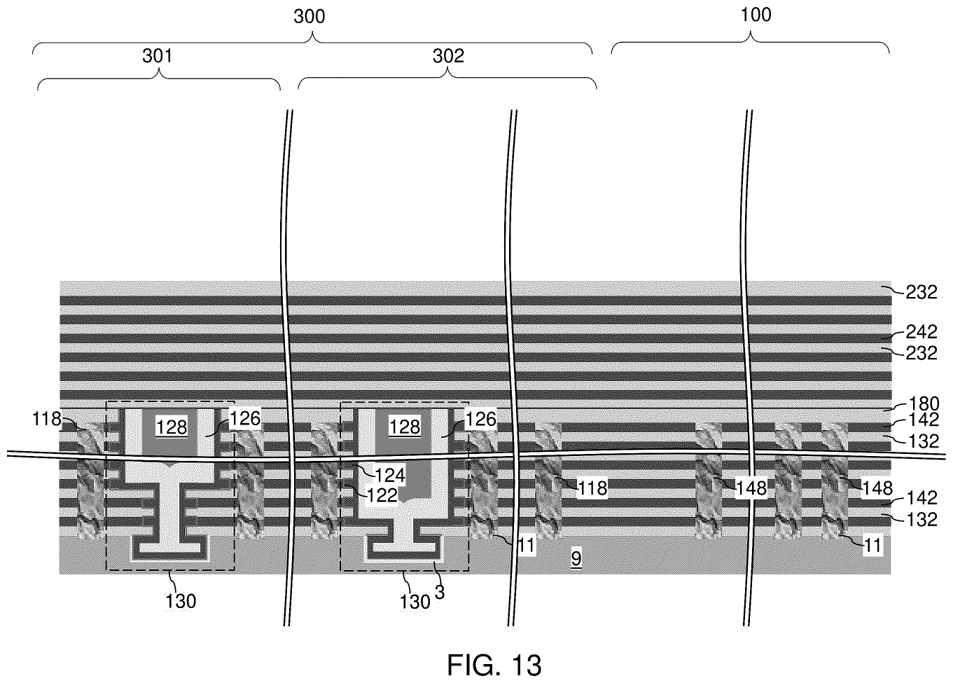

Referring to FIG. 13, a second-tier alternating stack of second insulating layers 232 and second sacrificial material layers 242 can be formed over the substrate 9. The second insulating layers 232 comprise an insulating material such as undoped silicate glass or a doped silicate glass, and the second sacrificial material layers 242 comprise a sacrificial material such as silicon nitride or a silicon-germanium alloy. The second-tier alternating stack (232, 242) may comprise multiple repetitions of a unit layer stack including a second insulating layer 232 and a second sacrificial material layer 242. The total number of repetitions of the unit layer stack within the second-tier alternating stack (232, 242) may be, for example, in a range from 8 to 1,024, such as from 32 to 256, although lesser and greater number of repetitions may also be employed. Each of the second insulating layers 232 may have a thickness in a range from 20 nm to 200 nm, such as from 30 nm to 60 nm, although lesser and greater thicknesses may also be employed. Each of the second sacrificial material layers 242 may have a thickness in a range from 20 nm to 200 nm, such as from 30 nm to 60 nm, although lesser and greater thicknesses may also be employed.

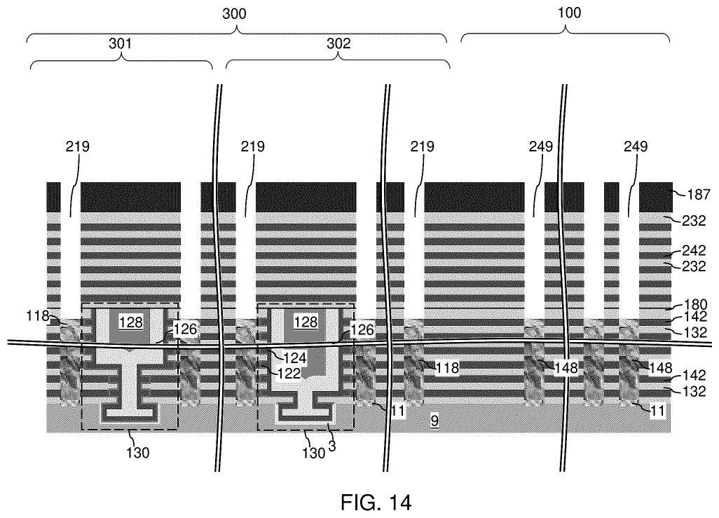

Referring to FIG. 14, an etch mask layer 187, such as a photoresist layer, can be formed over the second-tier alternating stack (232, 242), and can be lithographically patterned to form various openings therein. An anisotropic etch process can be performed to transfer the pattern of the openings in the etch mask layer 187 through the second-tier alternating stack (232, 242). Second-tier openings (249, 219) can be formed through the second-tier alternating stack (232, 242). The second-tier openings (249, 219) may comprise second-tier memory openings 249 that vertically extend through each layer within the second-tier alternating stack (232, 242) in the memory array region 200, and may further comprise second-tier support openings 219 that are formed through the second-tier alternating stack (232, 242) in the contact region 300 and are subsequently employed to form support pillar structures therein. Each of the second-tier memory openings 249 can be formed on top of a respective one of the first-tier sacrificial memory opening fill structures 148. Each of the second-tier support openings 219 can be formed on top of a respective one of the first-tier sacrificial support opening fill structures 118.

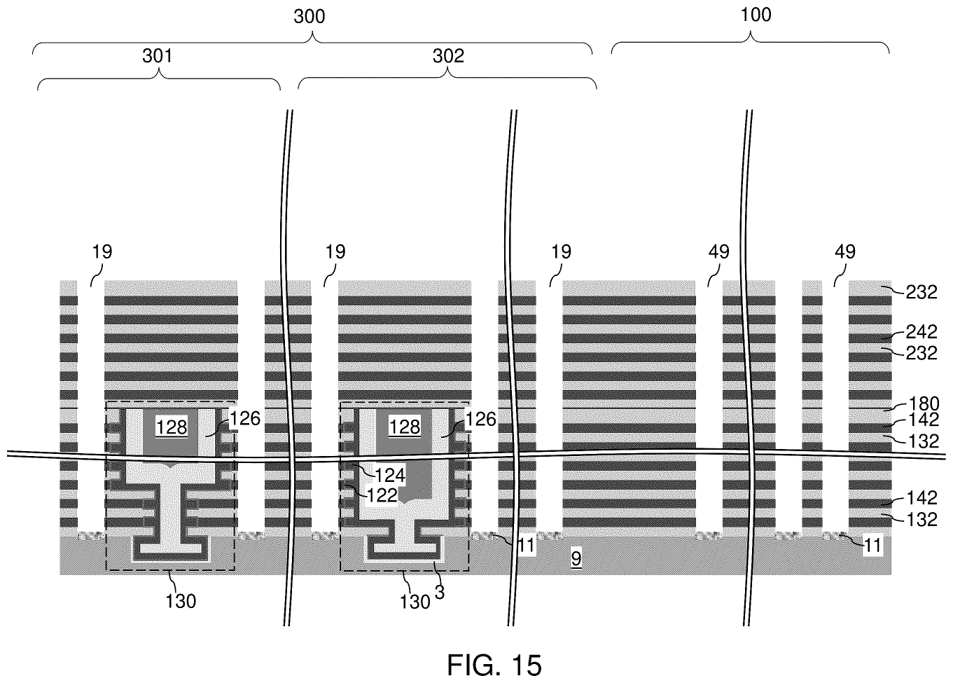

Referring to FIG. 15, the first-tier sacrificial opening fill structures (148, 118) can be subsequently removed from underneath the second-tier sacrificial openings (249, 219) selective to the materials of the pedestal channel portions 11, the first-tier alternating stack (132, 142), and the second-tier alternating stack (232, 242). For example, if the first-tier sacrificial opening fill structures (148, 118) comprise a carbon-based material, an ashing process may be performed to remove the first-tier sacrificial opening fill structures (148, 248). If the etch mask layer 187 comprises a photoresist layer, then it is removed together with the first-tier sacrificial opening fill structures (148, 118) during the ashing process. Each volume adjoining a volume of a first-tier memory opening 149 and the second-tier memory opening 249 is herein referred to as an inter-tier memory opening 49, which is also referred to as a memory opening. Each volume adjoining a volume of a first-tier support opening 119 and a second-tier support opening 219 is herein referred to as an inter-tier support opening 19, which is also referred to as a support opening. A pedestal channel portion 11 can be provided at the bottom of each of the inter-tier memory openings 49 and the inter-tier support openings 19.

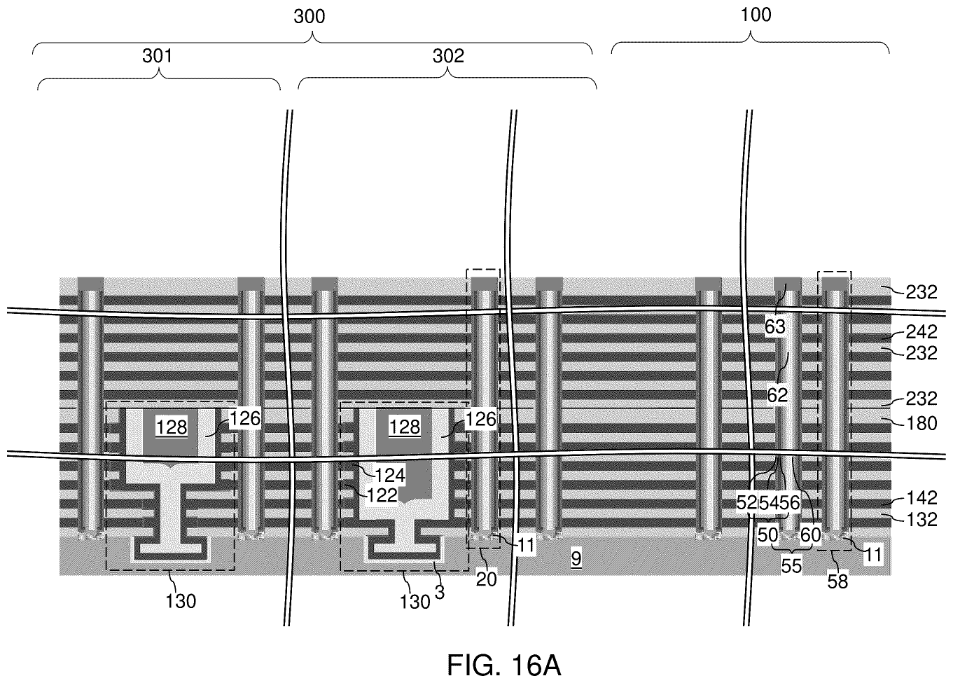

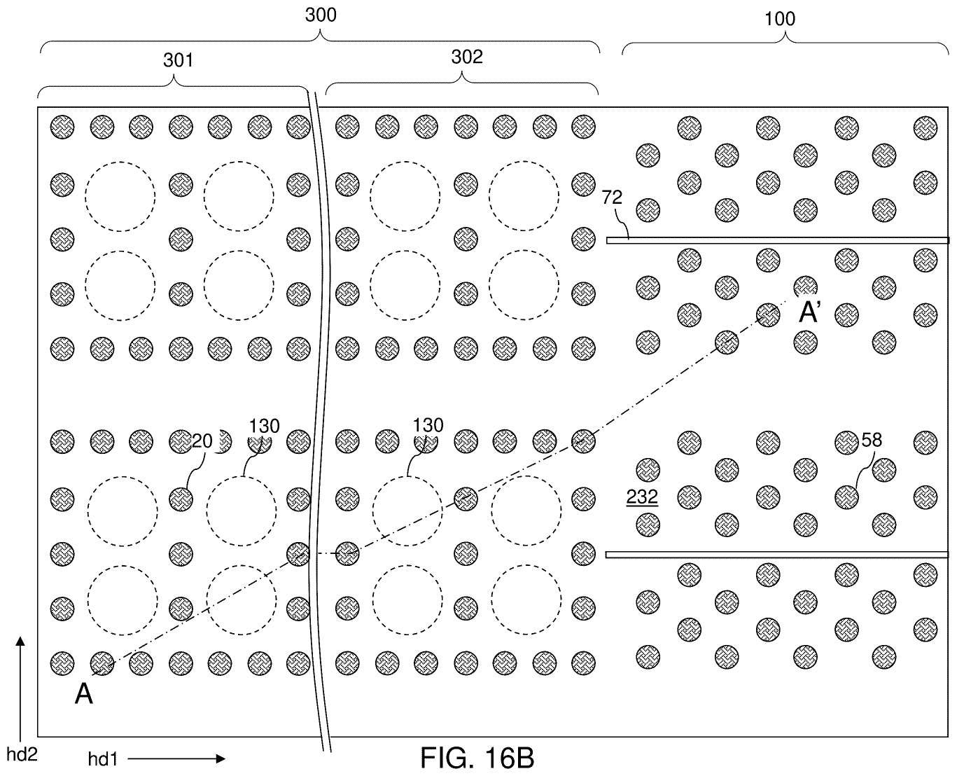

Referring to FIGS. 16A and 16B, a sequence of processing steps can be performed to form a memory opening fill structure 58 within each inter-tier memory opening 49 and within each inter-tier support opening 19. For example, a memory film 50 can be formed within each of the memory openings 49 and the support openings 19. The memory films 50 may include any memory material that can store information by charge trapping, a change in electrical resistivity, a change in the direction of ferroelectric polarization (e.g., in a ferroelectric material), or any other material that can store information therein. For example, each memory film 50 may comprise a layer stack including a blocking dielectric layer 52, a charge storage material layer 54, and a tunneling dielectric layer 56. In one embodiment, the memory films 50 can be formed by depositing material layers and/or material portions and by removing excess portions of the material layers and/or the material portions from outside and the bottoms of the memory openings 49 and the support openings 19, for example, by performing an anisotropic etch process (e.g., a sidewall spacer etch process). In one embodiment, the blocking dielectric layer 52 may comprise a silicon oxide or an aluminum oxide layer. The charge storage material layer 54 may comprise a silicon nitride layer. The tunneling dielectric layer 56 may comprise a silicon oxide layer or an “ONO” stack of silicon oxide/silicon nitride/silicon oxide layers.

A vertical semiconductor channel 60 can be formed in each of the memory openings 49 and the support openings 19 by conformal deposition of a semiconductor channel material (e.g., amorphous silicon or polysilicon) having a doping of a first conductivity type. The semiconductor channel material may have a doping of a same conductivity type as the horizontal semiconductor channels (not expressly shown) located in the substrate 9. A dielectric fill material can be deposited in the remaining volumes of the memory openings 49 and the support openings 19, and can be vertically recessed to form a dielectric core 62. A semiconductor material (e.g., amorphous silicon or polysilicon) having a doping of a second conductivity type can be deposited over each dielectric core 62 at a top end of each vertical semiconductor channel 60 to form a drain region 63 within each of the memory openings 49 and the support openings 19. The second conductivity type is opposite of the first conductivity type. Each contiguous combination of a memory film 50 and a vertical semiconductor channel 60 constitutes a memory stack structure 55. Each memory stack structure 55 comprises a respective vertical stack of memory elements. For example, each vertical stack of memory elements may comprise portions of the charge storage material layer 54 located at the levels of the sacrificial material layers (142, 242) which are subsequently replaced with electrically conductive layers.

Generally, the memory opening fill structures 58 are formed in the memory openings 49, and support pillar structures 20 are formed in the support openings 19. Each of the memory opening fill structures 58 comprises a respective vertical semiconductor channel 60, a respective vertical stack of memory elements (e.g., portions of a memory film 50), a drain region 63 and an optional dielectric core 62. Drain-select-level dielectric isolation structures (not shown) can be formed through an uppermost set of second sacrificial material layers 242.

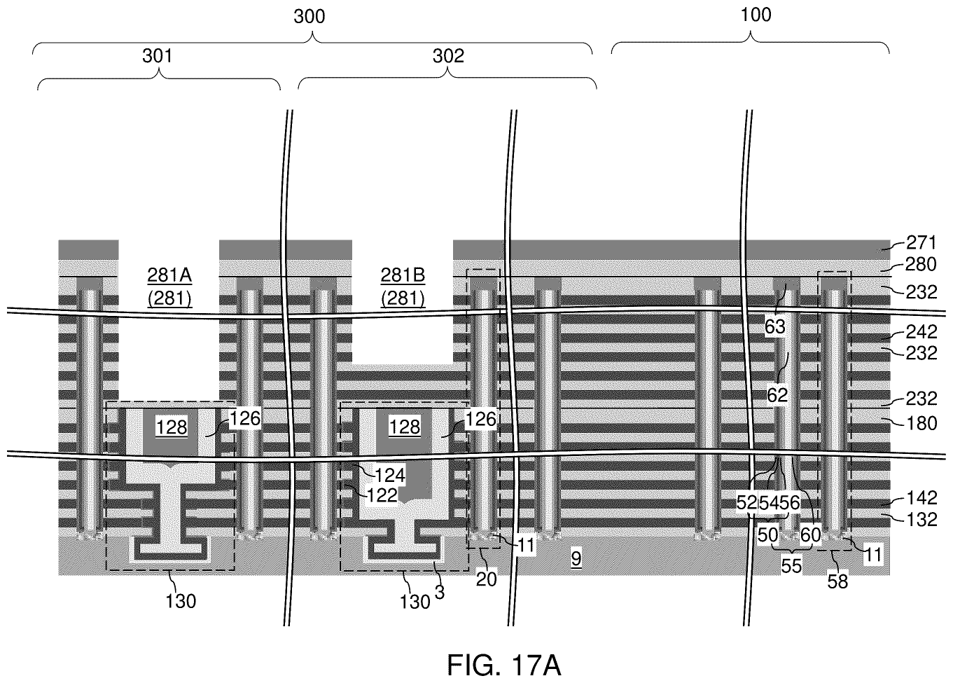

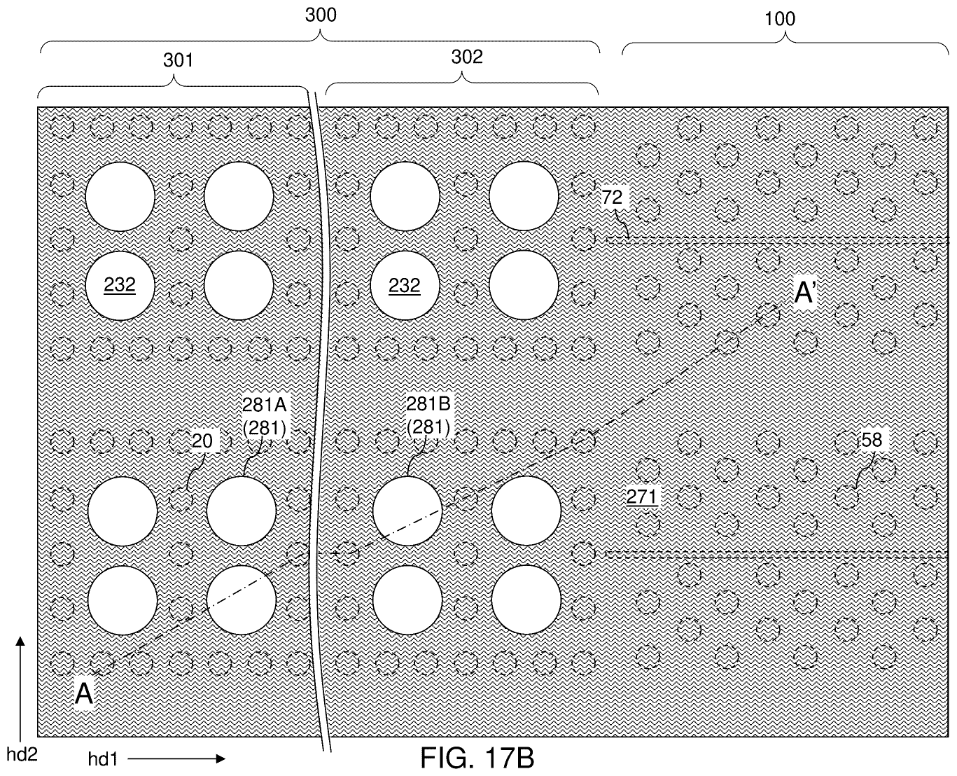

Referring to FIGS. 17A and 17B, an insulating layer may be optionally formed over the second-tier alternating stack (232, 242). The insulating layer, if formed, is herein referred to as a first contact-level dielectric layer 280. A second patterned hard mask layer 271 may be formed above the first contact-level dielectric layer 280 by depositing and patterning a hard mask material. The second patterned hard mask layer 271 comprises a material that can function as an etch mask material during subsequent anisotropic etch processes. In one embodiment, the second patterned hard mask layer 271 may comprise a semiconductor material, such as amorphous silicon, and may have a thickness in a range from 50 nm to 500 nm, although lesser and grater thicknesses may be employed. The hard mask layer 271 may be patterned by applying and lithographically patterning a photoresist material over the hard mask layer 271, and by transferring the pattern in the photoresist material through the hard mask layer 271. In one embodiment, the pattern of the openings in the second patterned hard mask layer 271 may be the same as the pattern of the in-process first-via-cavity fill structures 130, which is the same as the pattern of the first-tier via cavities 181.

Second-tier via cavities 281 are formed through a respective subset of layers within the second-tier alternating stack (232, 242). Each of the second-tier via cavities 281 can vertically extend through the contact-level dielectric layer 280 and through a respective subset of the second sacrificial material layers 242 and the second insulating layers 232 such that a top surface of a selected second insulating layer 232 is physically exposed at the bottom of each second-tier via cavity 281. In one embodiment, the second-tier via cavities 281 may have different depths from each other, and each second insulating layer 232 can be physically exposed to a respective overlying second-tier via cavity 281.

The second-tier via cavities 281 having different depths may be formed employing a plurality of masked anisotropic etch processes. In an illustrative example, the openings in the second patterned hard mask layer 271 may have the pattern of all of the second-tier via cavities 281 to be subsequently formed. An anisotropic etch process may be performed to transfer the pattern of the openings in the second patterned hard mask layer 271 through the first contact-level dielectric layer 280

Subsequently, multiple iterations of a combination of a respective masking process and a respective anisotropic etch process may be performed to etch through a respective subset of second sacrificial material layers 242 and a respective subset of the second insulating layers 232. Each masking process forms a respective patterned photoresist layer (not shown) that masks a respective subset of the openings in the second patterned hard mask layer 271 without masking a respective complementary subset of the openings. Each anisotropic etch process etches a respective number of second sacrificial material layers 242 and a respective number of insulating layers 32 underneath each opening in the second pattered hard mask layer 271 that is not masked by a respective patterned photoresist layer. In one embodiment, the number of etched second sacrificial material layers 242 and etched second insulating layers 232 underneath unmasked openings in the second patterned hard mask layer 271 may be a non-negative integer power of 2, i.e., 1, 2, 4, 8, 26, 32, 64, etc. By employing a combination of various masking patterns for the patterned photoresist layers, the total depths of the second-tier via cavities 281 can be varied to enable physical exposure of the top surfaces of second insulating layers 232 at each level. The second patterned hard mask layer 271 can be subsequently removed.

The second-tier via cavities 281 may comprise first-type second-tier via cavities 281A that are formed in the first contact region 301 and second-type second-tier via cavities 281B that are formed in the second contact region 302. In one embodiment, the second-type second-tier via cavities 281B have various depths such that each of the second insulating layers 232 has a top surface segment that is physically exposed to a respective overlying second-type second-tier via cavity 281A. In one embodiment, each of the first-type second-tier via cavities 281A may extend through each layer within the second-tier alternating stack (232, 242) except the bottommost second insulating layer 232. In this case, each of the first-type second-tier via cavities 281A may vertically extend through each second sacrificial material layer 242 in the second-tier alternating stack (232, 242). The lateral dimensions (such as diameters) of the second-tier via cavities 281 may be in a range from 200 nm to 3,000 nm, although lesser and greater lateral dimensions may also be employed.

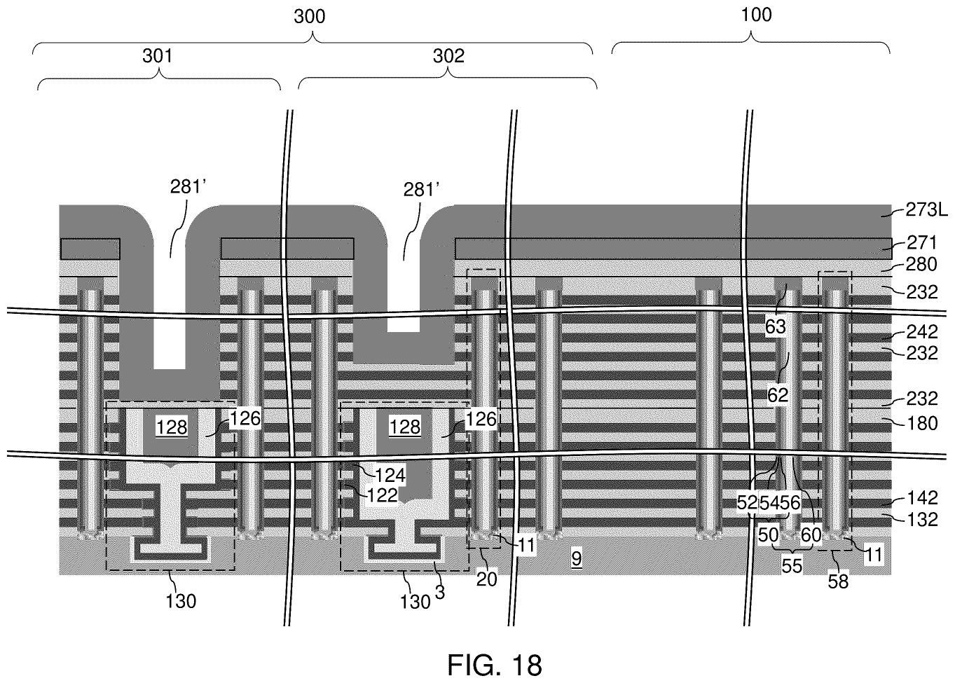

Referring to FIG. 18, a second sacrificial spacer material layer 273L can be deposited over the second patterned hard mask layer 271 and in peripheral portions of the second-tier via cavities 281. The second sacrificial spacer material layer 273L comprises a material that may be subsequently employed as an etch mask material for the materials of the second-tier alternating stack (232, 242). In one embodiment, the second sacrificial spacer material layer 273L comprises a semiconductor material, such as polysilicon or amorphous silicon. The thickness of the second sacrificial spacer material layers 273L may be in a range from 50 nm to 1,000 nm, although lesser and greater thicknesses may also be employed. A void 281′ can be formed within each volume of the second-tier via cavities 281 that is not filled with the second sacrificial spacer material layer 273L.

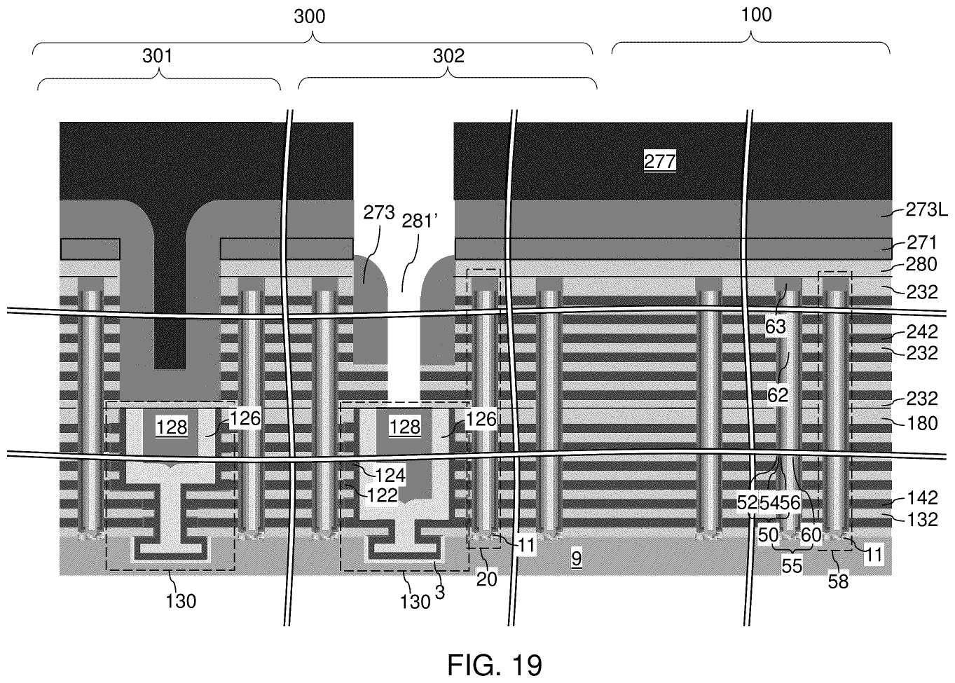

Referring to FIG. 19, a second patterned photoresist layer 277 can be formed over the second sacrificial spacer material layer 273L. Generally, the second patterned photoresist layer 277 may have openings in the areas of the second-type second-tier via cavities 281B. For example, the openings in the second patterned photoresist layer 277 may be located at or within a periphery of a respective one of the second-type second-tier cavities 281B located in the second contact region 302 in a plan view, such as a top-down view.

A second anisotropic etch process can be performed to vertically extend center portions of the second-type second-tier contact via cavities 281B that are laterally surrounded by vertically-extending portions of the second sacrificial spacer material layer 273L. The second anisotropic etch process may include a first anisotropic etch step that etches the material of the second sacrificial spacer material layer 273L. Portions of the second sacrificial spacer material layer 273L that are not masked by the second patterned photoresist layer 277 are vertically recessed uniformly. Each portion of the second sacrificial spacer material layer 273L that underlies a respective void 281′ is etched through, and a top surface segment of a respective underlying second insulating layer 232 (or the first contact-level dielectric layer 280) is physically exposed underneath the respective void 281′. A tubular portion of the second sacrificial spacer material layer 273L remains in the peripheral region of each second-type second-tier via cavity 281 while a center portion of the second sacrificial spacer material layer 273L in each second-type second-tier via cavity 281 is etched through during the second anisotropic etch step of the second anisotropic etch process. Each tubular portion of the second sacrificial spacer material layer 273L that remains in a respective second-type and second-tier cavity 281 constitutes a second sacrificial spacer 273.

The second anisotropic etch process may include a second anisotropic etch step that etches the materials of the second insulating layers 232 and the second sacrificial material layers 242 selective to the materials of the second sacrificial spacers 273 and the first sacrificial via fill material portions 128. The second anisotropic etch step of the second anisotropic etch process etches portions of the second-tier alternating stack (232, 242) that underlie the second-type second-tier via cavities 281B and are not covered by the tubular portions of the second sacrificial spacer material layer 273L, i.e., the second sacrificial spacers 273. Each center region of the second-type second-tier via cavities 281 can be vertically extended into an upper portion of a respective underlying first sacrificial via fill material portion 128 while the peripheral region of the second-type second-tier via cavities 281B occupied by the second sacrificial spacers 273 are not vertically extended.

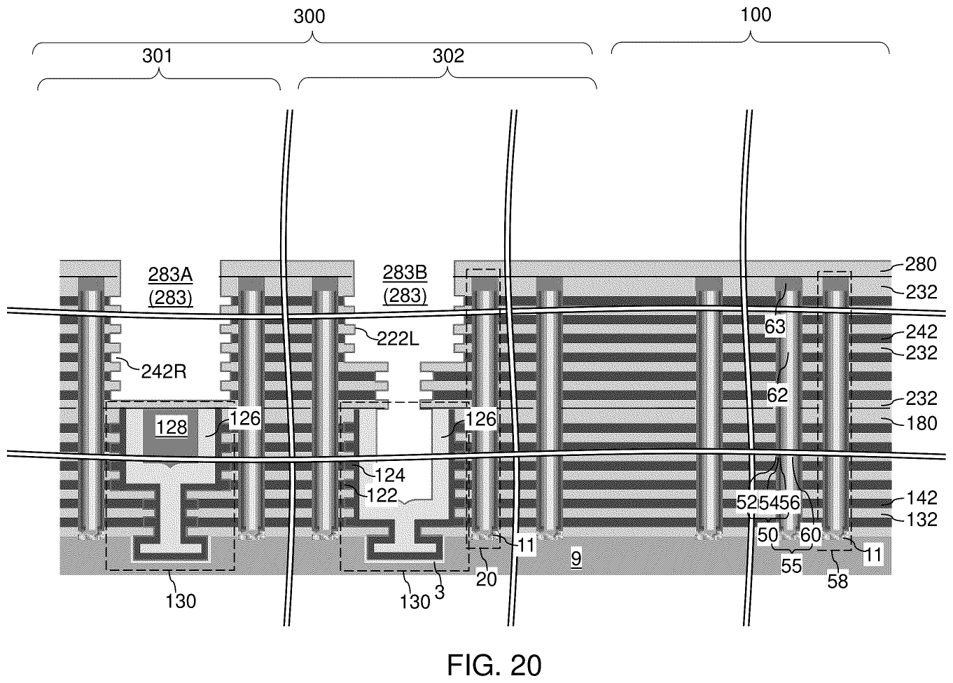

Referring to FIG. 20, the second patterned photoresist layer 277, the second sacrificial spacer material layer 273L, the second sacrificial spacers 273, and the second patterned hard mask layer 271, and a subset of the first sacrificial via fill material portions 128 in the second region 302 can be subsequently removed. For example, the second patterned photoresist layer 277 can be removed by performing an ashing process. In case the second sacrificial spacer material layer 273L, the second sacrificial spacers 273, the second patterned hard mask layer 271 and the first subset of the first sacrificial via fill material portions 128 in the second contact region 302 comprise semiconductor materials, such as polysilicon or amorphous silicon, a wet etch process employing TMAH or TMY may be performed to remove the second sacrificial spacer material layer 273L, the second sacrificial spacers 273, and the second patterned hard mask layer 271, and a first subset of the first sacrificial via fill material portions 128 that are not covered by the bottommost second insulating layer 232 and located in the second contact region 302.

Subsequently, a selective isotropic etch process can be performed to laterally recess the second sacrificial material layers 242 selective to the materials of the second insulating layers 232 and the first dielectric fill material portions 126. For example, if the second sacrificial material layers 242 comprise silicon nitride, a wet etch process employing hot phosphoric acid can be performed to laterally recess the second sacrificial material layers 242. Generally, sidewalls of the second sacrificial material layers 242 may be laterally recessed relative to sidewalls of the second insulating layers 232 around the second-tier via cavities 281, which are now referred to as second through-tier cavities 283. Each of the second through-tier cavities 283 includes the entire volume of a respective one of the second-tier via cavities 281 as formed at the processing steps of FIGS. 17A and 17B. The second through-tier cavities 283 further comprise voids that are formed by the second anisotropic etch process and by removal of the second sacrificial spacers 273 and the first subset of the first sacrificial via fill material portions 128. Finally, the second through-tier cavities 283 further comprise the lateral recesses 242R formed at the levels of the sacrificial material layers 242. The second through-tier cavities 283 can include first-type through-tier cavities 283A that are formed in the first contact region 301 and second-type through-tier cavities 283B that are formed in the second contact region 302. Each of the second through-tier cavities 283 may comprise a respective set of lateral protrusions which correspond to the lateral recesses 242R located at each level of the second sacrificial material layers 242. A second continuous dielectric liner layer 222L can be deposited in the second through-tier cavities 283 by a conformal deposition process. The second continuous dielectric liner layer 222L comprises a dielectric material, such as silicon oxide, and may have a thickness in a range from 3 nm to 20 nm, although lesser and greater thicknesses may also be employed. Alternatively, the silicon oxide second continuous dielectric liner layer 222L can be formed by radical oxidation (e.g., in-situ steam generation (ISSG)) of exposed silicon nitride second sacrificial material layers 242.

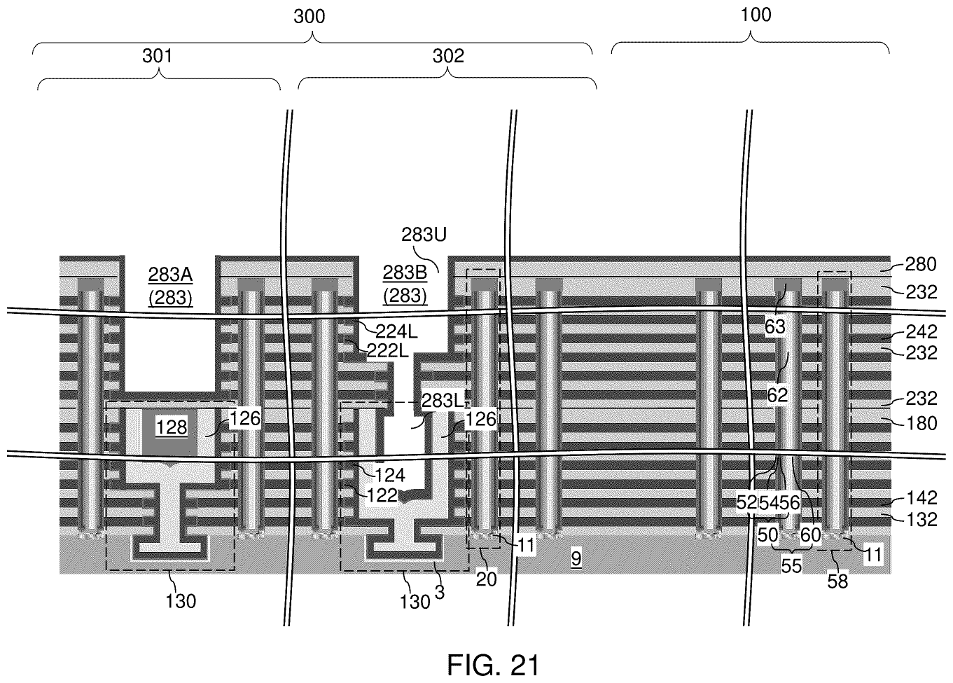

Referring to FIG. 21, a second continuous dielectric material layer 224L can be conformally deposited to fill remaining volumes of the lateral recesses in the second sacrificial material layers 242 around the second through-tier cavities 283. The second continuous dielectric material layer 224L comprises a dielectric material, such as silicon nitride or silicon carbonitride. The thickness of the second continuous dielectric material layer 224L may be in a range from 30 nm to 300 nm, although lesser and greater thicknesses may also be employed. The second through-tier cavities 283 include a narrower lower portion 283L located in the first alternating stack (132, 142) and a wider upper portion 283U in the second alternating stack (232, 242).

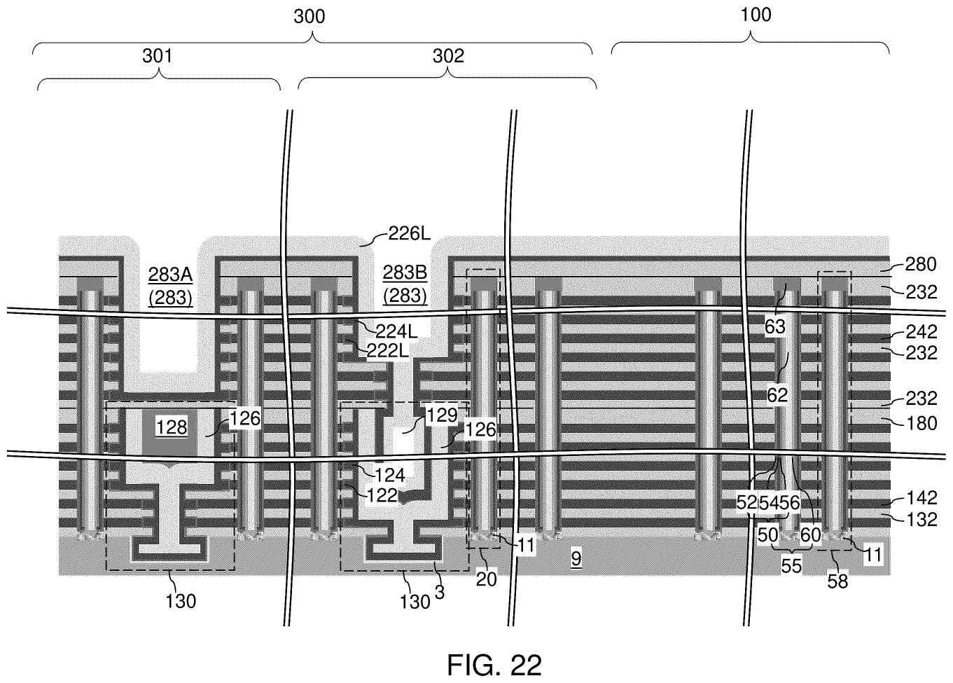

Referring to FIG. 22, a second dielectric fill material layer 226L can be deposited to fill a narrower lower portion 283L of each of the second through-tier cavities 283 without completely filling a wider upper portion 283U of each of the second through-tier cavities 283. The second dielectric fill material layer 226L comprises a dielectric fill material such as silicon oxide.

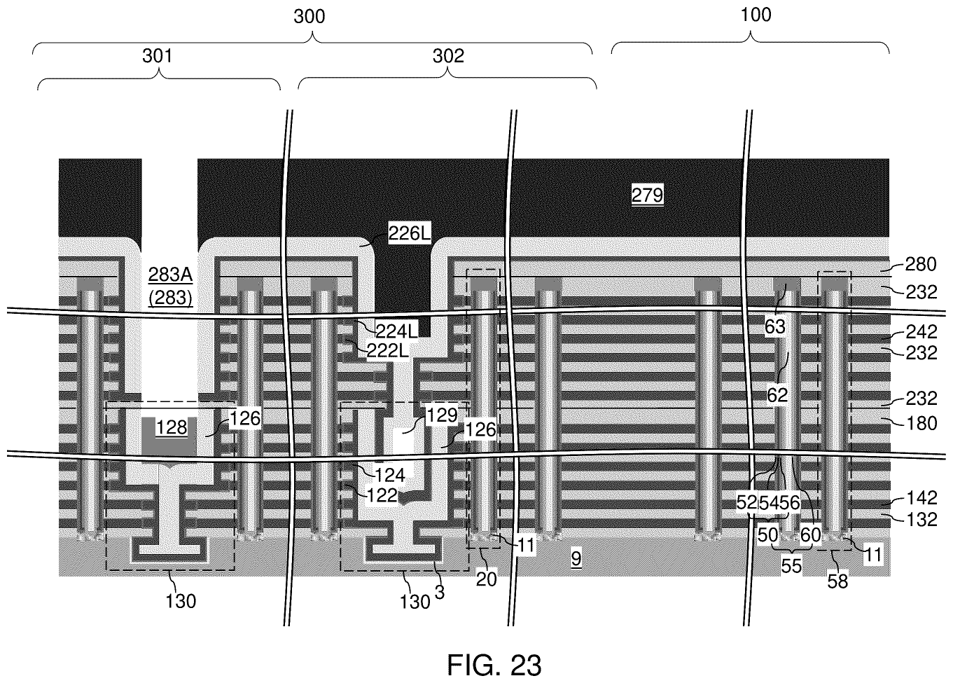

Referring to FIG. 23, a third patterned photoresist layer 279 can be formed over the second dielectric fill material layer 226L. Generally, the third patterned photoresist layer 279 may have openings in the areas of the first-type second through-tier cavities 283A. For example, the openings in the third patterned photoresist layer 279 may be located at or within vertically-extending inner sidewalls of the second dielectric fill material layer 226L located within a respective one of the first-type second through-tier cavities 283A located in the first contact region 301 in a plan view such as a top-down view.

A third anisotropic etch process can be performed to vertically extend the voids located at center portions of the first-type second-tier contact via cavities 281A, which are now center portions of the first-type second through-tier cavities 283A. The third anisotropic etch process etches through horizontally-extending unmasked portions of the second dielectric fill material layer 226 and underlying portions of the bottommost second insulating layer 232 and the inter-tier insulating layer 180. A top surface of each first sacrificial via fill material portion 128 underlying the first-type second through-tier cavities 283A can be physically exposed. The third patterned photoresist layer 279 can be subsequently removed, for example, by ashing.

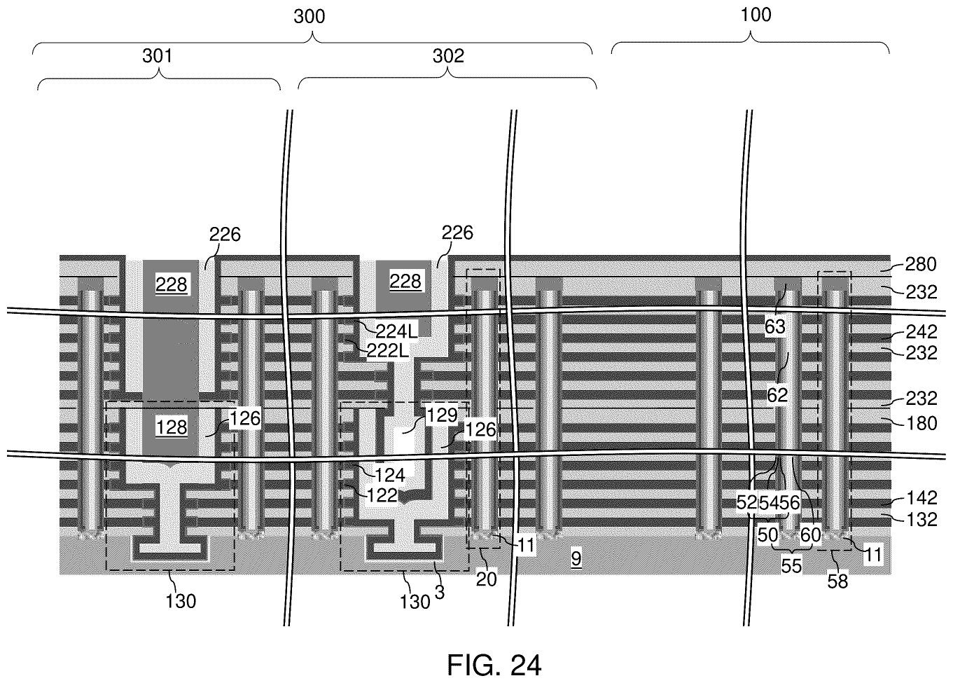

Referring to FIG. 24, a second sacrificial via fill material can be deposited in remaining unfilled volumes of the second through-tier cavities 283. The second sacrificial via fill material comprise a different fill material than the material of the second dielectric fill material layer 226L. In one embodiment, the second sacrificial via fill material may comprise a semiconductor material, such as polysilicon or amorphous silicon, or may comprise a carbon-based material, such as amorphous carbon or diamond-like carbon. The second sacrificial via fill material may be vertically recessed (e.g., by CMP) such that remaining portions of the second a sacrificial via fill material have top surfaces in or near a horizontal plane including a topmost surface of the second continuous dielectric material layer 224L. Each remaining portion of the second sacrificial via fill material is herein referred to as a second sacrificial via fill material portion 228.

Horizontally-extending portions of the second dielectric fill material layer 226L can be removed from above the horizontal plane including the topmost a surface of the second continuous dielectric material layer 224L, for example, by performing a recess etch process. Each remaining portion of the second dielectric fill material layer 226L located within a respective one of the second through-tier cavities 283 is herein referred to as a second dielectric fill material portion 226. An optional air gap 129 that is free of any solid phase material may be formed within the narrower lower portion 283L of each of the second through-tier cavities 283. The top of the air gap 129 is encapsulated by a bottom portion of a respective one of the second dielectric fill material portions 226. The bottom and sides of the air gap 129 are encapsulated by a respective one of the first dielectric fill material portions 126. However, no air gap 129 is present in the first contact region 301.

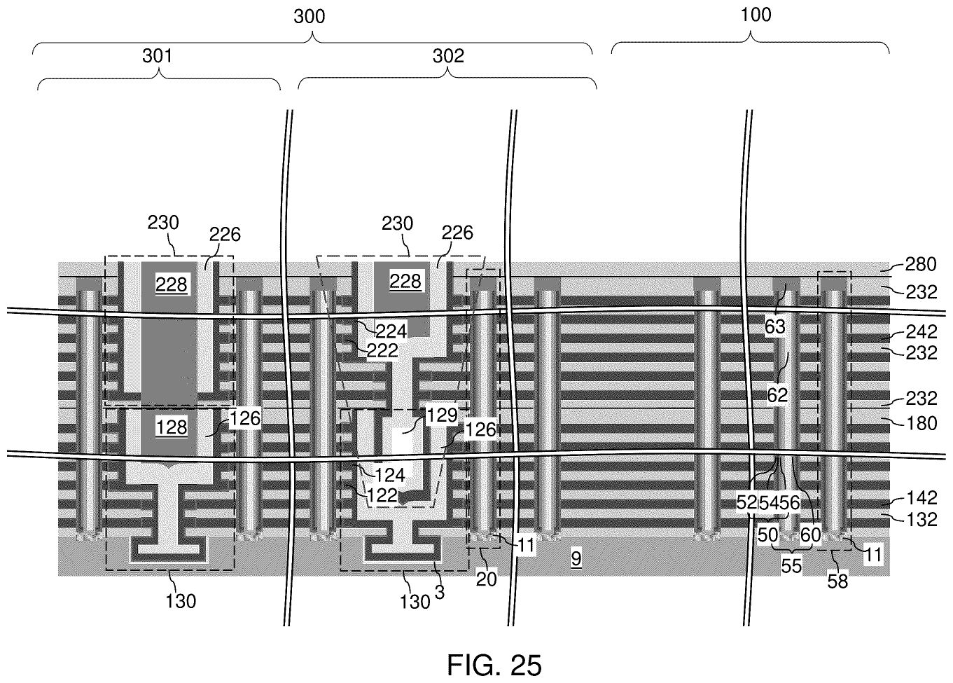

Referring to FIG. 25 horizontally-extending portions of the second continuous dielectric material layer 224L and the second continuous dielectric liner layer 222L located above the horizontal plane including the top surface of the first contact-level dielectric layer 280 can be removed, for example, by performing at least one etch process. Optionally, segments of the second dielectric fill material portion 226 and the second sacrificial via fill material portion 228 that protrude the above the horizontal plane including the top surface of the first contact-level dielectric layer 280 can be removed, for example, by performing a touch-up planarization process, such as a chemical mechanical polishing process. Each remaining portion of the second continuous dielectric liner layer 222L constitutes a second dielectric liner 222. Each remaining portion of the second continuous dielectric material layer 224L constitutes a second dielectric material layer 224.

The set of all material portions that fills a second through-tier cavity 283 constitutes an in-process second-via-cavity fill structure 230, i.e., an in-process of fill structure that fills a respective via cavity. Each in-process second-via-cavity fill structure 230 comprises a second dielectric liner 222, a second dielectric material layer 224, a second dielectric fill material portion 226, and a second sacrificial via fill material portion 228. In one embodiment, top surfaces of the second dielectric liners 222, the second dielectric material layers 224, the second dielectric fill material portions 226, and the second sacrificial via fill material portions 228 may be formed it within the horizontal plane including the top surface of the first contact-level dielectric layer 280. Each contiguous set of a second dielectric liner 222, a second dielectric material layer 224, and a second dielectric fill material portion 226 is herein referred to as a second dielectric layer stack (222, 224, 226).

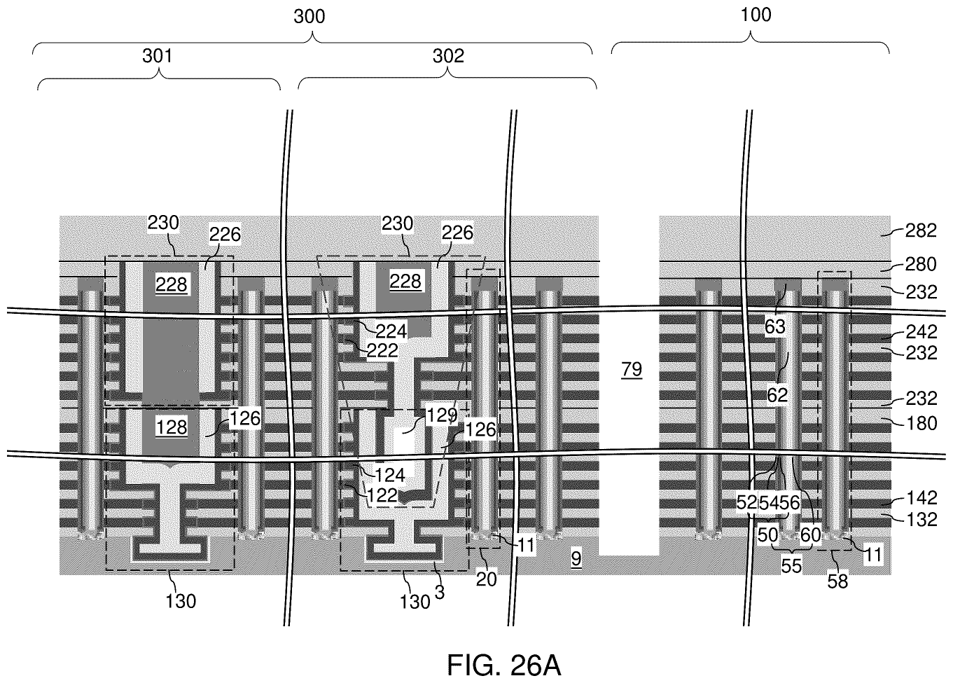

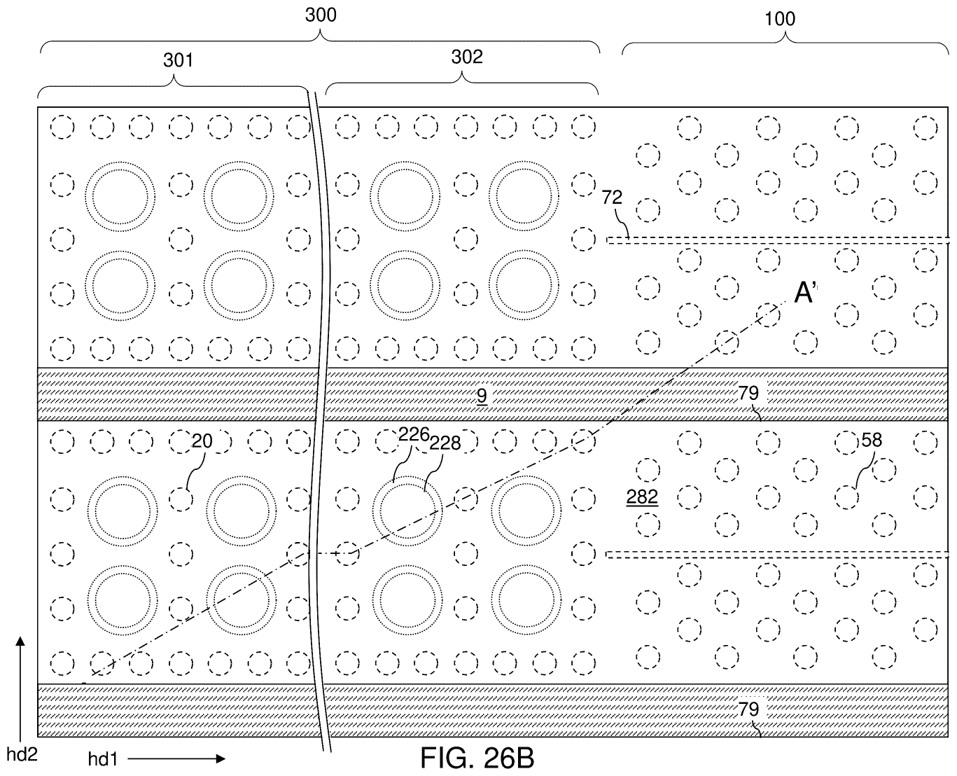

Referring to FIGS. 26A and 26B, a second contact-level dielectric layer 282 can be deposited over the first contact-level dielectric layer 280. The second contact-level dielectric layer 280 may comprise a dielectric material, such as undoped silicate glass or a doped silicate glass, and may have a thickness in a range from 100 nm to 1,000 nm, although lesser and greater thicknesses may also be employed.

A photoresist layer (not shown) can be applied over the second contact-level dielectric layer 282 and can be lithographically patterned to form openings within areas extending across the memory array region 100 and the contact region 300. The openings in the photoresist layer can laterally extend along the first horizontal direction hd1 between each neighboring cluster of memory opening fill structures 58. Backside trenches 79 can be formed by transferring the pattern in the photoresist layer through the contact-level dielectric layers (280, 282), the second-tier alternating stack (232, 242), and the first-tier alternating stack (132, 142), and into the substrate 9. Portions of the contact-level dielectric layers (280, 282), the second-tier alternating stack (232, 242), and the first-tier alternating stack (132, 142) that underlie the openings in the photoresist layer can be removed to form the backside trenches 79. In one embodiment, the backside trenches 79 can be formed between clusters of memory opening fill structures 58. The clusters of the memory opening fill structures 58 can be laterally spaced apart along the second horizontal direction hd2 by the backside trenches 79.

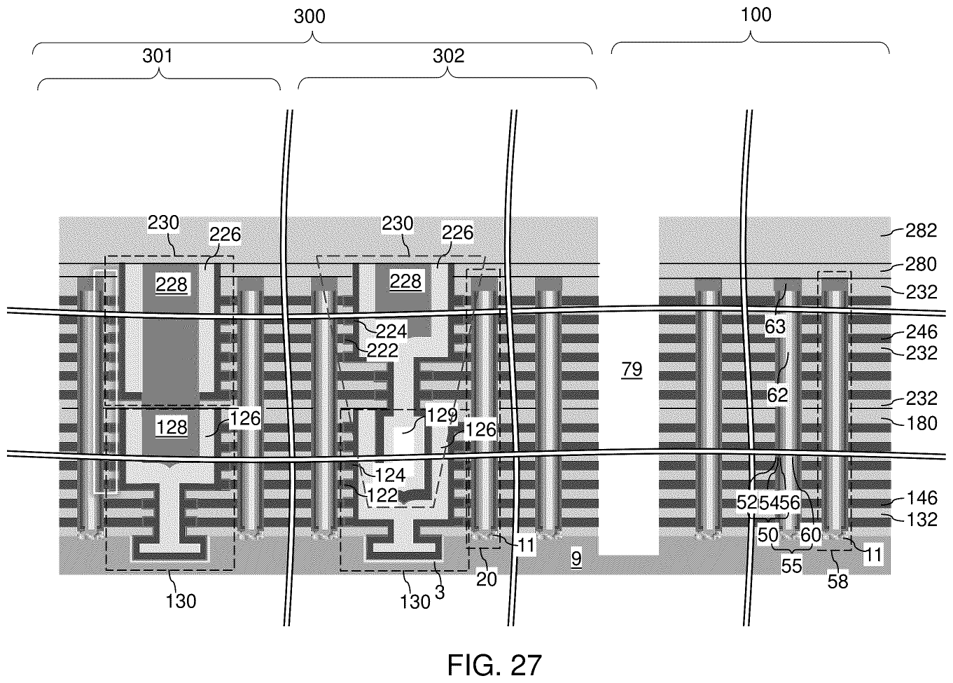

Referring to FIG. 27 an etchant that selectively etches the materials of the first and second sacrificial material layers (142, 242) with respect to the materials of the first and second insulating layers (132, 232), and the material of the outermost layer of the memory films 50 can be introduced into the backside trenches 79, for example, employing an isotropic etch process. First backside recesses are formed in volumes from which the first sacrificial material layers 142 are removed. Second backside recesses are formed in volumes from which the second sacrificial material layers 242 are removed.

The isotropic etch process can be a wet etch process employing a wet etch solution, or can be a gas phase (dry) etch process in which the etchant is introduced in a vapor phase into the backside trenches 79. For example, if the first and second sacrificial material layers (142, 242) include silicon nitride, the etch process can be a wet etch process in which the first exemplary structure is immersed within a wet etch tank including phosphoric acid, which etches silicon nitride selective to silicon oxide and silicon.

Each of the first and second backside recesses can be a laterally extending cavity having a lateral dimension that is greater than the vertical extent of the cavity. In other words, the lateral dimension of each of the first and second backside recesses can be greater than the height of the respective backside recess. A plurality of first backside recesses can be formed in the volumes from which the material of the first sacrificial material layers 142 is removed. A plurality of second backside recesses can be formed in the volumes from which the material of the second sacrificial material layers 242 is removed. Each of the first and second backside recesses can extend substantially parallel to the top surface of the substrate 9. A backside recess can be vertically bounded by a top surface of an underlying insulating layer (132 or 232) and a bottom surface of an overlying insulating layer (132 or 232). In one embodiment, each of the first and second backside recesses can have a uniform height throughout.

A backside blocking dielectric layer (not shown) can be optionally deposited in the backside recesses and the backside trenches 79 and over the contact-level dielectric layer 280. The backside blocking dielectric may comprise a dielectric metal oxide material, such as aluminum oxide. At least one conductive material can be conformally deposited in the plurality of backside recesses, on the sidewalls of the backside trench 79, and over the contact-level dielectric layer 280. The at least one conductive material can include at least one metallic material, i.e., an electrically conductive material that includes at least one metal element.

A plurality of electrically conductive layers 146 can be formed in the plurality of first backside recesses, a plurality of second electrically conductive layers 246 can be formed in the plurality of second backside recesses, and a continuous metallic material layer (not shown) can be formed on the sidewalls of each backside trench 79 and over the contact-level dielectric layer 280. Thus, the first and second sacrificial material layers (142, 242) can be replaced with the first and second conductive material layers (146, 246), respectively. Specifically, each first sacrificial material layer 142 can be replaced with an optional portion of the backside blocking dielectric layer and an electrically conductive layer 146, and each second sacrificial material layer 242 can be replaced with an optional portion of the backside blocking dielectric layer and a second electrically conductive layer 246. A backside cavity is present in the portion of each backside trench 79 that is not filled with the continuous metallic material layer.

The metallic material can be deposited by a conformal deposition method, which can be, for example, chemical vapor deposition (CVD), atomic layer deposition (ALD), electroless plating, electroplating, or a combination thereof. The metallic material can be an elemental metal, an intermetallic alloy of at least two elemental metals, a conductive nitride of at least one elemental metal, a conductive metal oxide, a conductive doped semiconductor material, a conductive metal-semiconductor alloy such as a metal silicide, alloys thereof, and combinations or stacks thereof. Non-limiting exemplary metallic materials that can be deposited in the backside recesses include tungsten, tungsten nitride, titanium, titanium nitride, tantalum, tantalum nitride, cobalt, and/or ruthenium. In one embodiment, the metallic material can comprise a metal such as tungsten and/or metal nitride. In one embodiment, the metallic material for filling the backside recesses can be a combination of titanium nitride layer and a tungsten fill material. In one embodiment, the metallic material can be deposited by chemical vapor deposition or atomic layer deposition.

The deposited metallic material of the continuous metallic material layer can be etched back from the sidewalls of each backside trench 79 and from above the contact-level dielectric layers (280, 282), for example, by an anisotropic or isotropic etch. Each remaining portion of the deposited metallic material in the first backside recesses constitutes an electrically conductive layer 146. Each remaining portion of the deposited metallic material in the second backside recesses constitutes a second electrically conductive layer 246. Each electrically conductive layer (146, 246) can be a conductive line structure (e.g., word line or select gate electrode).

Each of the memory opening fill structures 58 (which contains a respective memory stack structures 55) comprises a vertical stack of memory elements located at each level of the electrically conductive layers (146, 246). A subset of the middle electrically conductive layers (146, 246) can comprise the word lines for the memory elements. At least one uppermost electrically conductive layer 246 may comprise a drain side select gate electrode. At least one bottommost electrically conductive layer 146 may comprise a source side select gate electrode.

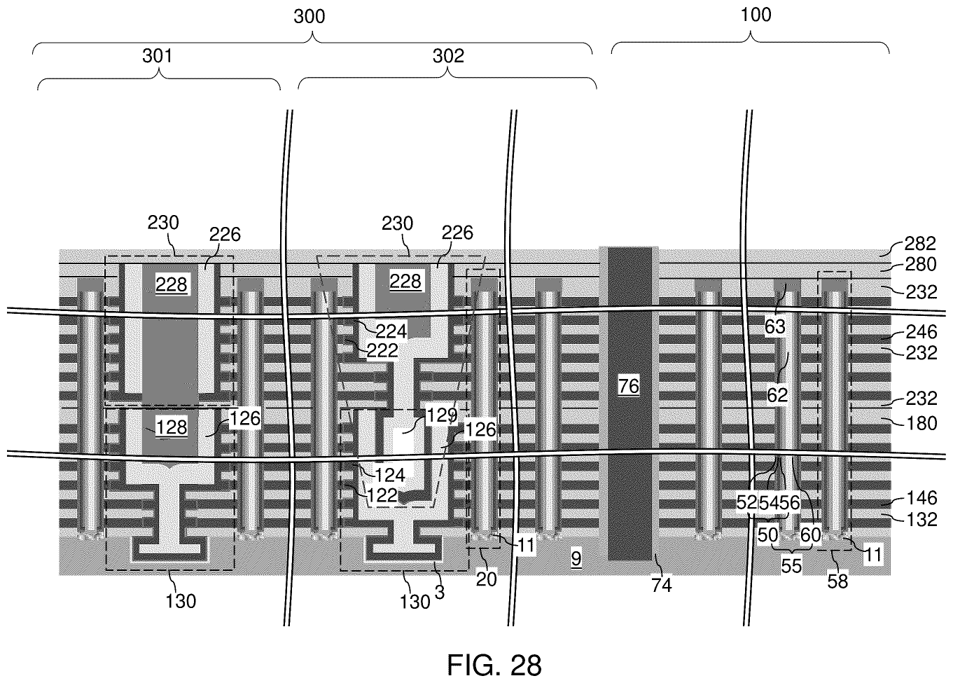

Referring to FIG. 28, an insulating spacer material layer can be conformally deposited in the backside trenches 79 and over the contact-level dielectric layers (280, 282). An anisotropic etch process can be performed to remove horizontally-extending portions of the insulating spacer material layer. Each remaining vertically-extending portion of the insulating spacer material layer constitutes an insulating spacer 74.

At least one conductive material such as at least one metallic material may be deposited in the unfilled volumes of the backside trenches 79. A planarization process such as a chemical mechanical polishing process and/or a recess etch process can be performed to remove excess portions of the at least one conductive material can be removed from above the horizontal plane including the top surface of the second contact-level dielectric layer 282. In some embodiment, an upper portion of the second contact-level dielectric layer 282 may be collaterally removed during the planarization process. Each remaining portion of the at least one conductive material that is laterally surrounded by a respective insulating spacer 74 constitutes a backside contact via structure 76.

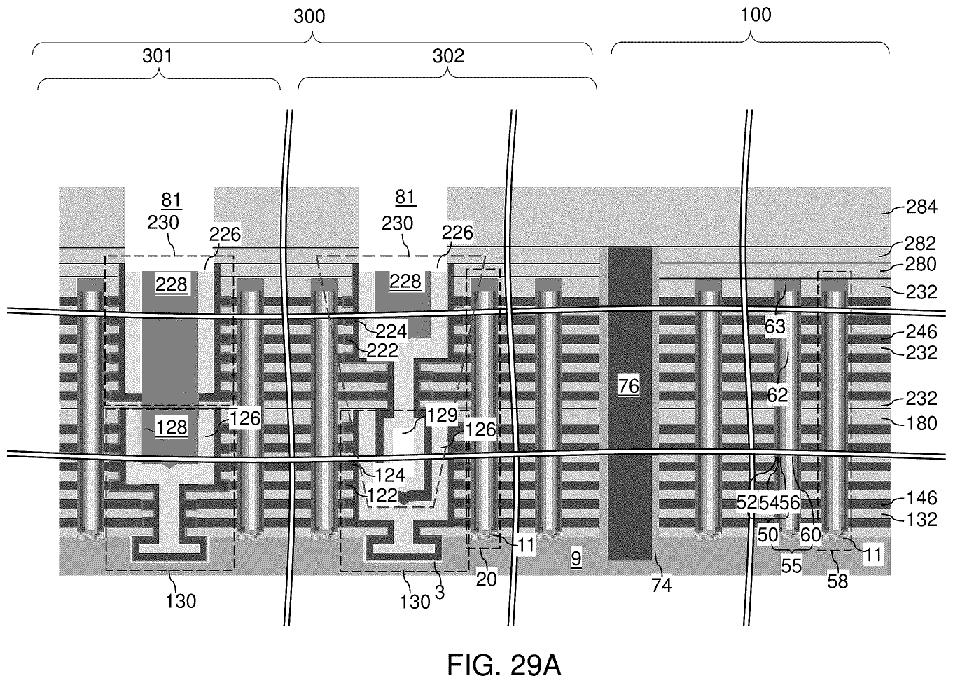

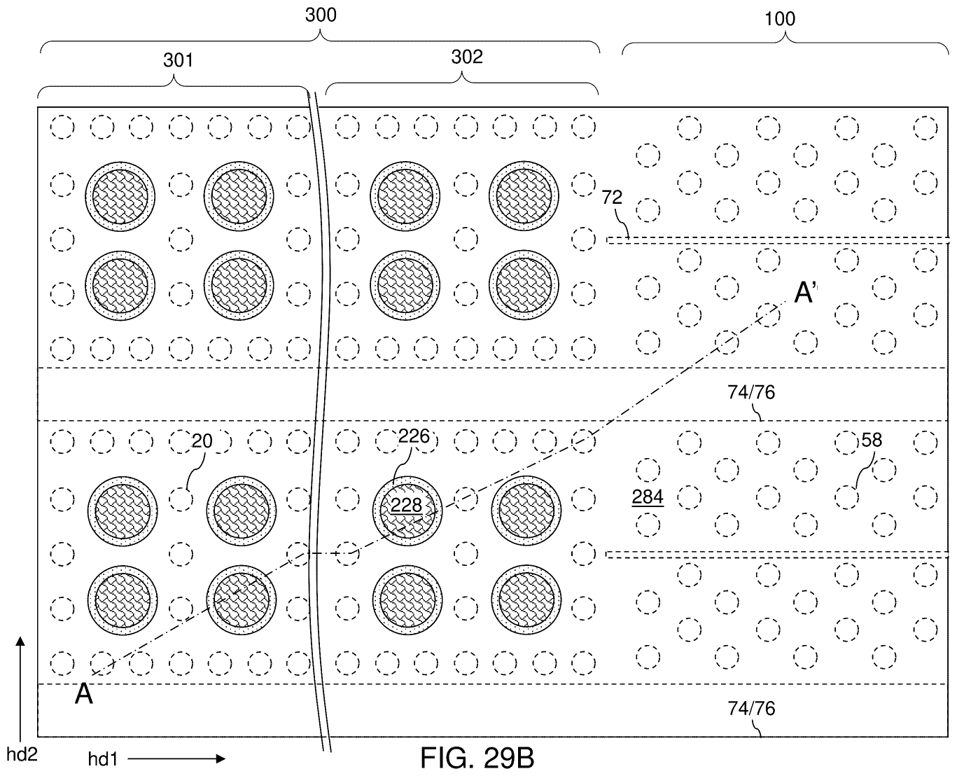

Referring to FIGS. 29A and 29B, a third contact-level dielectric layer 284 can be formed over the second contact-level dielectric layer 282. A photoresist layer (not shown) can be applied over the contact-level dielectric layers (280, 282, 284), and openings can be formed over the areas of the in-process second-via-cavity fill structures 230. An anisotropic etch process can be performed to etch through unmasked portions of the contact-level dielectric layers (280, 282, 284) to form connection via cavities 81 through the contact-level dielectric layers (280, 282, 284). Top surfaces of the in-process second-via-cavity fill structures 230 can be physically exposed at the bottom of the connection via cavities 81. The photoresist layer can be subsequently removed, for example, by ashing.

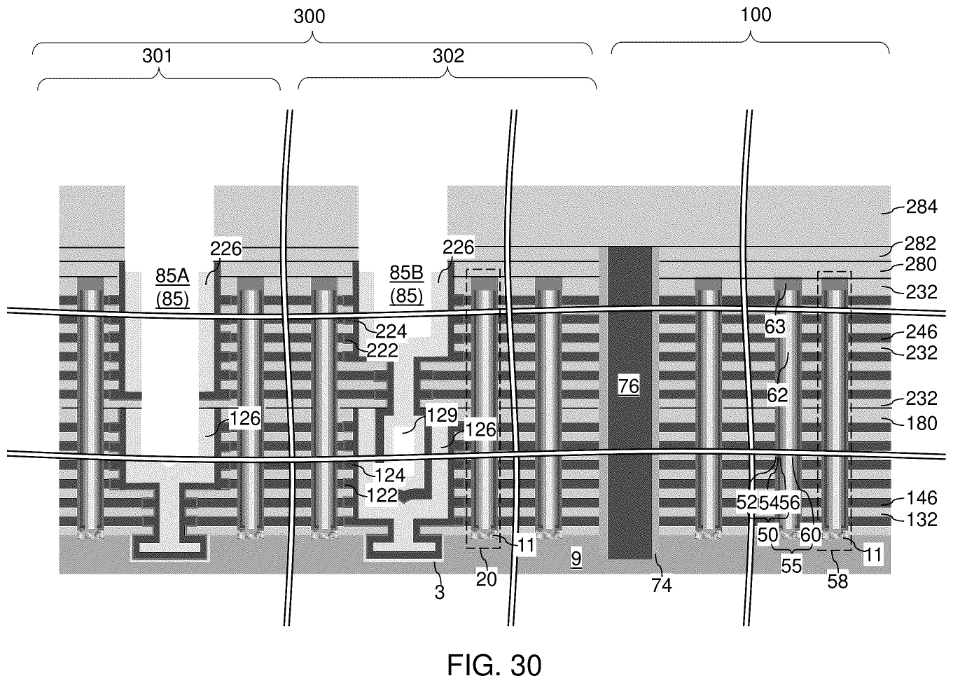

Referring to FIG. 30, the second sacrificial via fill material portions 228 and a second subset of the first sacrificial via fill material portions 128 that are present within the first contact region 301 of the first exemplary structure illustrated in FIGS. 29A and 29B can be subsequently removed selective to materials of the contact-level dielectric layers (280, 282, 284) and the second dielectric fill material portions 226. For example, if the second sacrificial via fill material portions 228 and a second subset of the first sacrificial via fill material portions 128 comprise a semiconductor material, such as amorphous silicon, then a wet etch process employing TMY or TMAH may be employed to remove the second sacrificial via fill material portions 228 and a second subset of the first sacrificial via fill material portions 128.

Contact via cavities 85 are formed in volumes from which the second sacrificial via fill material portions 228 and the second subset of the first sacrificial via fill material portions 128 are removed. A first subset of the contact via cavities 85 located in the first contact region 301 is referred to as first contact via cavities 85A. A second subset of the contact via cavities 85 located in the second contact region 302 is referred to as second contact via cavities 85B. Each of the first contact via cavities 85A can be laterally surrounded by a respective first dielectric fill material portion 126 and a respective second dielectric fill material portion 226. Each of the second contact via cavities 85B can be laterally surrounded by a respective second dielectric fill material portion 226.

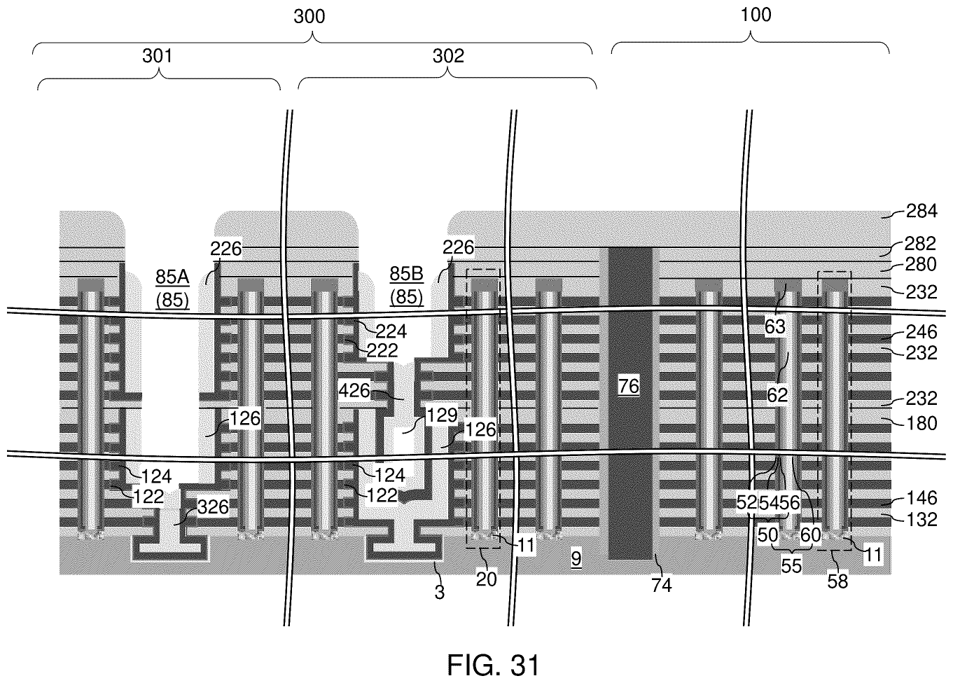

Referring to FIG. 31, a first anisotropic etch process can be performed to vertically recess physically exposed horizontal surfaces of the first dielectric fill material portions 126 and the second dielectric fill material portions 226. The third contact-level dielectric layer 284 can be collaterally vertically recessed during the anisotropic etch process. An annular top surface of a first dielectric material layer 124 can be physically exposed underneath each first contact via cavity 85A. An annular top surface of a second dielectric material layer 224 can be physically exposed underneath each second contact via cavity 85B. Each remaining portion of the first dielectric fill material portions 126 that underlies a respective first contact via cavity 85A is herein referred to as a pillar fill dielectric material portion 326. Each remaining portion of the second dielectric fill material portions 226 that underlies all a respective second contact via cavity 85B is herein referred to as an inner dielectric fill material portion 426. Each inner dielectric fill material portion 426 can vertically extended through a subset of the first electrically conductive layers 146 and the at least one second electrically conductive layer 246 including the bottommost second electrically conductive layer 246.

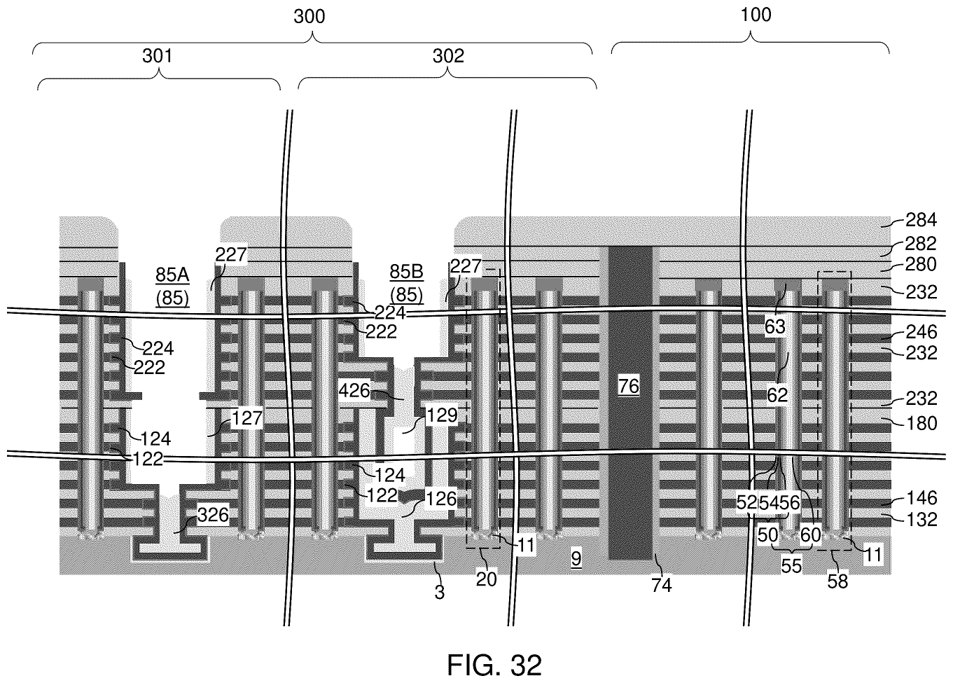

Referring to FIG. 32, an isotropic etch process can be performed to isotropically recess physically exposed surfaces of the first dielectric fill material portions 126 and the second dielectric fill material portions 226. Physically exposed as surfaces of the contact-level dielectric material layers (280, 282, 284) may be collaterally recessed during the isotropic etch process. In one embodiment, the first dielectric fill material portions 126 and the second dielectric fill material portions 226 may comprise a silicate glass material having a high etch rate (such as a doped silicate glass or organosilicate glass) and the contact-level dielectric material layers (280, 282, 284) may comprise a silicate glass material having a low etch rate (such as undoped silicate glass). In this case, the etch rate of the contact-level dielectric material layers (280, 282, 284) can be lower than the etch rate of the first dielectric fill material portions 126 and the second dielectric fill material portions 226. The duration of the isotropic etch process is selected such that a tubular portion of each of the first dielectric fill material portions 126 and the second dielectric fill material portions 226 remains around the respective contact via cavity 85 after the isotropic etch process. Each remaining tubular portion of the first dielectric fill material portions 126 around a bottom portion of a respective first contact via cavity 85A is herein referred to as a first tubular dielectric material portion 127. Each remaining tubular portion of the second dielectric fill material portions 226 around the respective contact via cavity 85 is herein referred to as a second tubular dielectric material portion 227.

Each of the second dielectric material layers 224 laterally surrounding a respective one of the first contact via cavities 85A may have an annular bottom portion having a physically exposed annular top surface, a physically exposed annular bottom surface, and a physically exposed a cylindrical sidewall. Each second tubular dielectric material portion 227 may be in contact with an inner cylindrical sidewall of a respective second dielectric material layer 224. Each first tubular dielectric material portion 227 located a around a respective one of the first contact via cavity 85A may be in contact with an inner cylindrical sidewall of a respective first dielectric material layer 124.

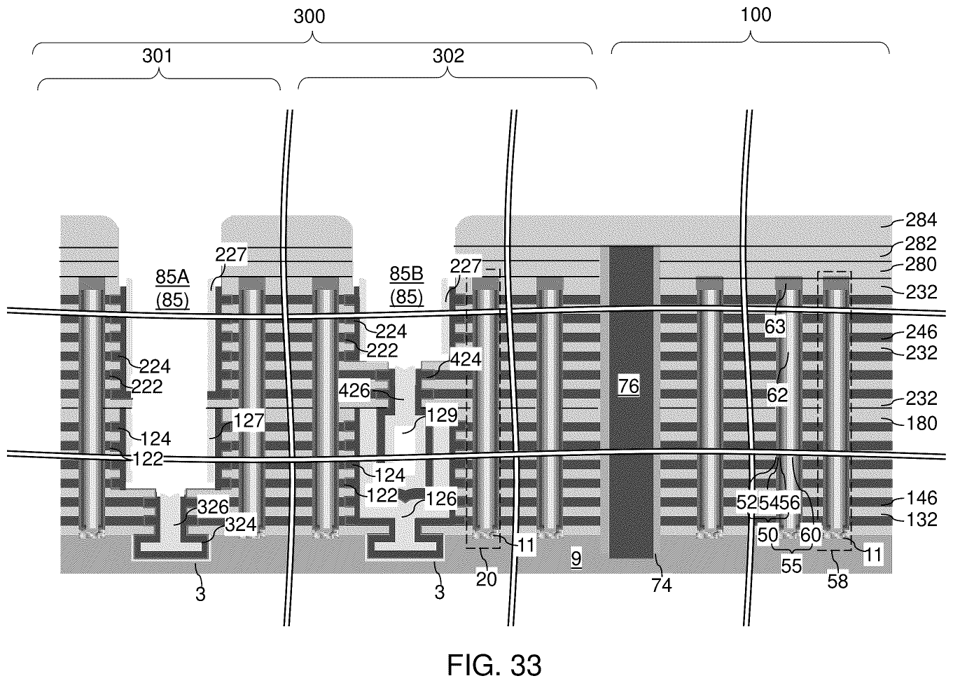

Referring to FIG. 33, a second anisotropic etch process can be performed to remove unmasked horizontally-extending portions of the second dielectric material layers 224 and the first dielectric material layers 124. Alternatively, an isotropic etch process may be used instead. Each remaining portion of the first dielectric material layers 124 located underneath a respective first contact via cavity 85A is herein referred to as a pillar dielectric material layer 324. Each remaining portion of the second dielectric material layers 224 located underneath a respective second contact via cavity 85B is herein referred to as an inner dielectric material layer 424. Each inner dielectric material layer 424 can be laterally surrounded by a respective first dielectric fill material portion 126 that underlies a second contact via cavity 85B, and may laterally surround a respective inner dielectric material portion 426.

In one embodiment, bottom portions of the first dielectric material layers 124 and the second dielectric material layers 224 may be laterally recessed outward relative to the inner sidewalls of a respective overlying first dielectric fill material portion 126 or relative to the inner sidewalls of a respective overlying second dielectric fill material portion 226. In this case, an annular recess may be formed underneath the first dielectric fill material portions 126 and underneath the second dielectric fill material portions 226, which can be subsequently filled with a laterally-protruding annular portion of a respective contact via structure.

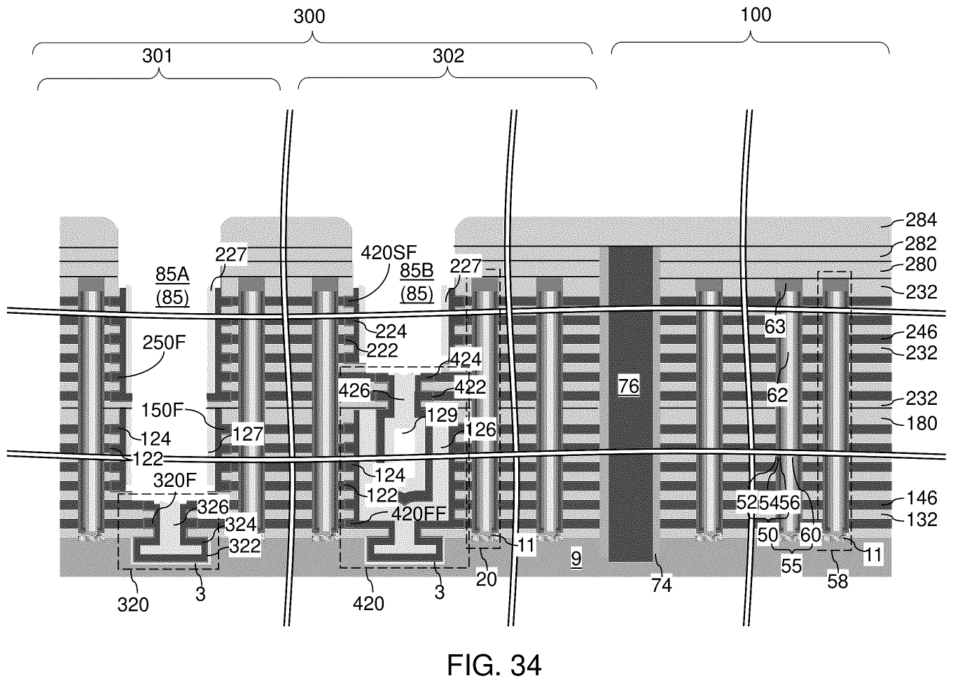

Referring to FIG. 34, an etch process can be performed to remove physically exposed portions of the first dielectric liners 122, the second dielectric liners 222 and the optional backside blocking dielectric layer (if present). An anisotropic etch process and/or an isotropic etch process may be performed. Each of the first electrically conductive layers 146 may have a respective annular top surface that is a physically exposed to a respective first contact via cavity 85A. Each of the second electrically conductive layers 246 may have a respective annular top surface that is physically exposed to a respective second contact via cavity 85B.

In one embodiment, each first dielectric liner 122 around the first contact via cavities 85A can be divided into two discrete portions by the etch process. In this case, each remaining portion of a first dielectric liner 122 that underlies a respective first contact via cavity 85A is herein referred to as a pillar dielectric liner 322. In one embodiment, each second dielectric liner 222 around the second contact via cavities 85B can be divided into two discrete portions by the etch process. In this case, each remaining portion of a second dielectric liner 222 that underlies a respective second contact via cavity 85B is herein referred to as an inner dielectric liner 422.

Each contiguous combination of a substrate dielectric liner 3 (which can be optional), a pillar dielectric liner 322, a pillar dielectric material layer 324, and a pillar fill dielectric material portion 326 that underlies a respective first contact via cavity 85A constitutes a first dielectric pillar structure 320. Each contiguous combination of a substrate dielectric liner 3 (which can be optional), a first dielectric liner 122, a first dielectric material layer 124, a first dielectric fill material portion 126, an inner dielectric liner 422, an inner dielectric material layer 424, an inner dielectric fill material portion 426, and an optional air gap 129 that underlies a respective second contact via cavity 85B constitutes a second dielectric pillar structure 420.

Each contiguous combination of a first dielectric liner 122, a first dielectric material layer 124, and a first tubular dielectric material portion 127 around a first contact via cavity 85A constitutes a first-tier dielectric spacer (122, 124, 127). Each contiguous combination of a second dielectric liner 222, a second dielectric material layer 224, and a second tubular dielectric material portion 227 around a contact via cavity 85 constitutes a second-tier dielectric spacer (222, 224, 227).

At least one of the first dielectric pillar structures 320 may comprise at least one first laterally-protruding fin portion 320F that protrudes outward at each level of a respective first subset of the first electrically conductive layers 146. In one embodiment, the first-tier dielectric spacer (122, 124, 127) comprises at least one first laterally-protruding fin portion 150F that protrudes outward at each level of a second subset of the first electrically conductive layers 146. The second-tier dielectric spacer (222, 224, 227) comprises at least one first laterally-protruding fin portion 250F that protrudes outward at each level of the second electrically conductive layers 246. At least one of the second dielectric pillar structures 420 may comprise first laterally-protruding fin portions 420FF that protrude outward at each level of the first electrically conductive layers 146 and in at least one second laterally-protruding fin portion 420SF that protrudes outward at each level of a respective first subset of the second electrically conductive layers 246.

In one embodiment, each first-tier dielectric spacer (122, 124, 127) is not in direct contact with a respective underlying first dielectric pillar structure 320, and may vertically extend through each first electrically conductive layer 146 within a respective second subset of the first electrically conductive layers 146. In one embodiment, each second-tier dielectric spacer (222, 224, 227) around a respective first contact via cavity 85A is not in direct contact with a respective underlying first-tier dielectric spacer (122, 124, 127), and may vertically extend through each second electrically conductive layer 246. In one embodiment, each second-tier dielectric spacer (222, 224, 227) around a respective second contact via cavity 85B is not in direct contact with a respective underlying second dielectric pillar structure 420, and may vertically extend through each second electrically conductive layer 246 within a respective second subset of the second electrically conductive layers 246.

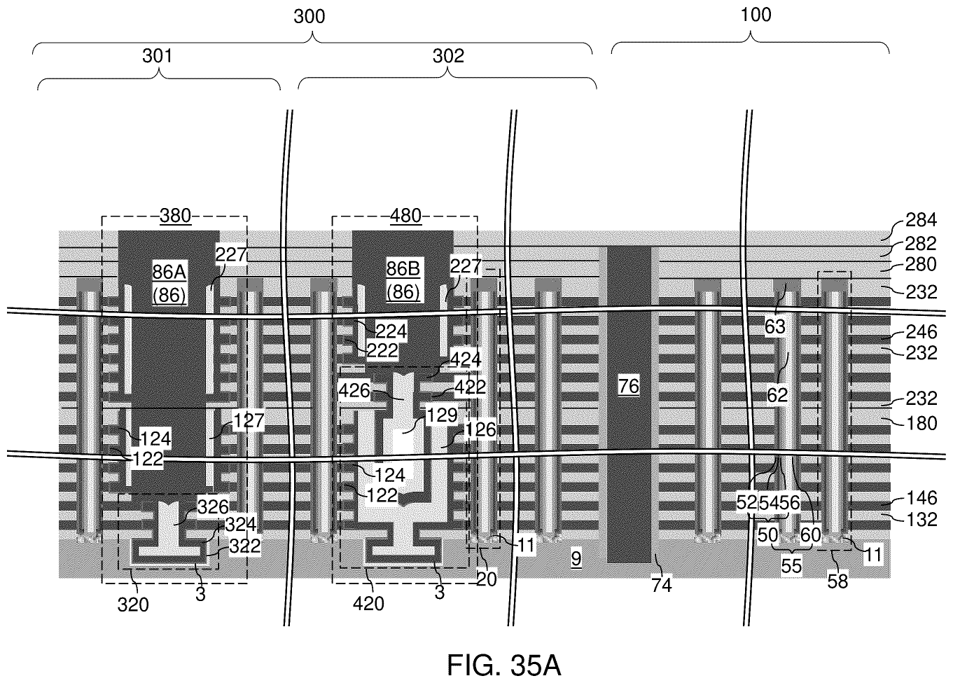

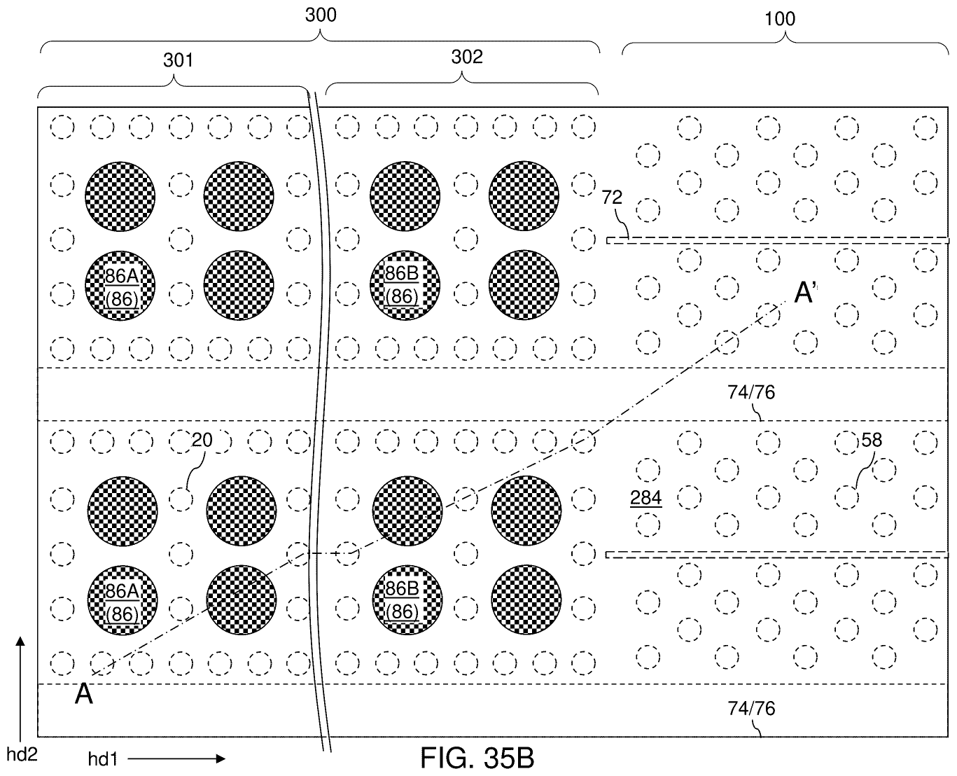

Referring to FIGS. 35A and 35B, at least one conductive material can be deposited in each of the first contact via cavities 85A and the second contact via cavities 85B. The at least one conductive material may comprise a metallic barrier liner and a metallic fill material. The metallic barrier liner may comprise a conductive metallic barrier material such as TiN, TaN, WN, MoN, TiC, TaC, and/or WC. The metallic fill material may comprise a metal or an intermetallic alloy such as Ti, Ta, W, Mo, Co, Ru, W, Cu, etc. Excess portions of the at least one conductive material can be removed from above the horizontal plane including the top surface of the third contact-level dielectric layer 284 by performing a planarization process. The planarization process may employ a chemical mechanical polishing process or recess etch process. Each remaining portion of the at least one conductive material that fills a respective first contact via cavity 85A constitutes a first contact via structure 86A. Each remaining portion of the at least one conductive material that fills a respective second contact via cavity 85B constitutes a second contact via structure 86B. The first contact via structures 86A and the second contact via structures 86B are herein collectively referred to as contact via structures 86.

Each contiguous combination of a first dielectric pillar structure 320, a first-tier dielectric spacer (122, 124, 127), a second-tier dielectric spacer (222, 224, 227), and a first contact via structure 86A constitutes a first support and contact assembly 380 located in the first contact region 301. Each contiguous combination of a second dielectric pillar structure 420, a second-tier dielectric spacer (222, 224, 227) (which may be referred to as a dielectric spacer or as an additional dielectric spacer), and a second contact via structure 86B constitutes a second support and contact assembly 480 in the second contact region 302. Each of the support and contact assemblies (380, 480) provides an electrical contact to a respective electrically conductive layer (146, 246).

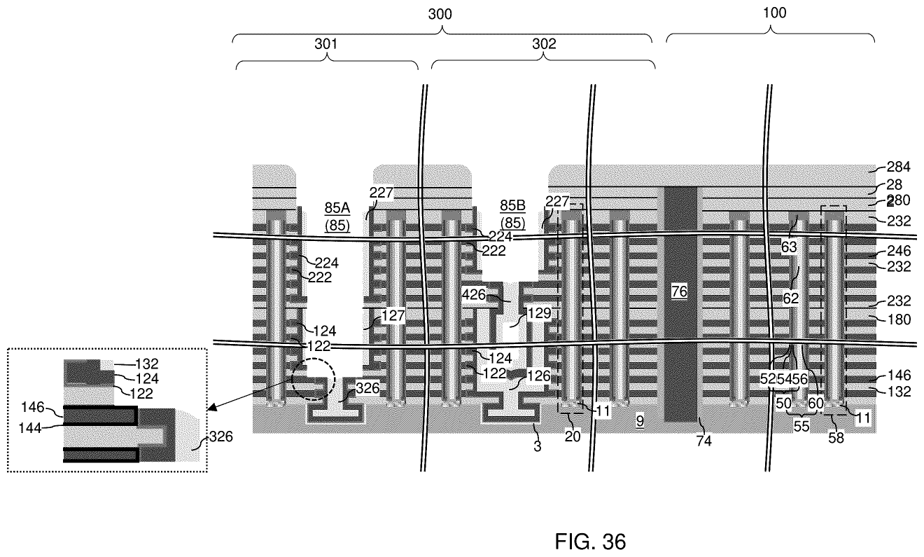

FIG. 36 illustrates an alternative first exemplary structure according to an alternative embodiment of the present disclosure. In the alternative embodiment, the first dielectric liner 122, the first dielectric material layer 124, and the exposed first insulating layer 132 are etched through during the etch steps shown in FIGS. 33 and 34 to expose the first backside blocking dielectric layer 144 located over the respective first electrically conductive layer 146, as shown in the inset in FIG. 36. The etch steps also etch through the second dielectric liner 222, the second dielectric material layer 224, and the exposed second insulating material layer 232 to expose the second backside blocking dielectric layer (not shown for clarity) located over the respective second electrically conductive layer 246.

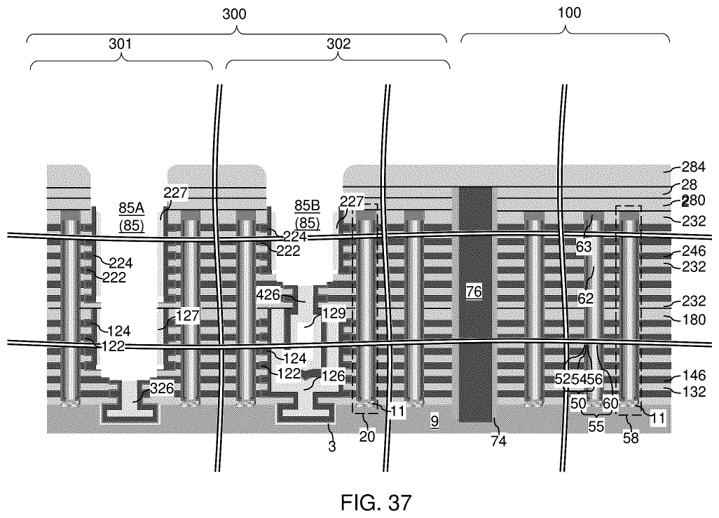

Referring to FIG. 37, the portions of the first and backside blocking dielectric layers exposed in the contact via cavities 85 may be removed by an etching process to expose a surface of an underlying electrically conductive layer (146, 246). If the backside blocking dielectric layers comprise aluminum oxide, then the etching process may comprise a hot phosphoric acid etch process.

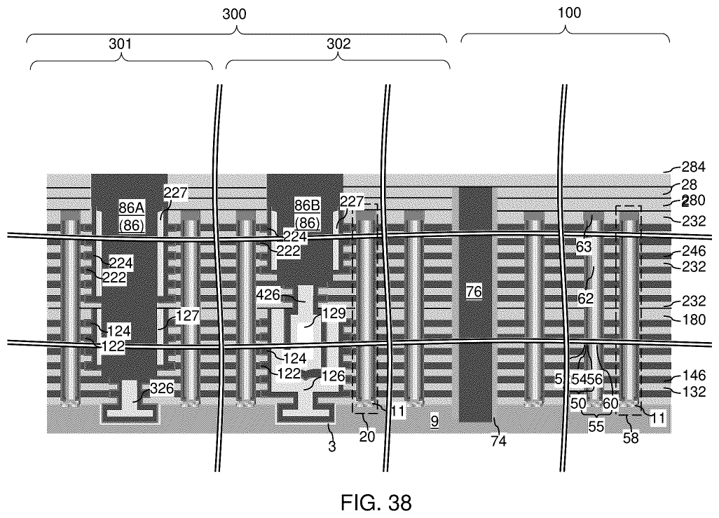

Referring to FIG. 38, the contact via structures 86 are formed in the contact via cavities 85 as described above with respect to FIGS. 35A and 35B. The process of the alternative embodiment of FIGS. 36-38 is advantageous if the etching process of FIG. 33 does not provide sufficient space between the electrically conductive layers (146, 246) and the contact via structures 86.

Referring collectively to FIGS. 1A-38 and according to various embodiments of the present disclosure, a memory device comprises: a first-tier alternating stack (132, 146) of first insulating layers 132 and first electrically conductive layers 146 located over a substrate 9; a second-tier alternating stack (232, 246) of second insulating layers 232 and second electrically conductive layers 246 overlying the first-tier alternating stack (132, 146); memory openings 49 vertically extending through the first-tier alternating stack (132, 146) and the second-tier alternating stack (232, 246); memory opening fill structures 58 located in the memory openings 49, wherein each of the memory opening fill structures 58 comprises a vertical semiconductor channel 60 and respective vertical stack of memory elements (e.g., portions of the memory film 50); and a first support and contact assembly 380 vertically extending through the first-tier alternating stack (132, 146) and the second-tier alternating stack (232, 246). The first support and contact assembly 380 comprises a first contact via structure 86A contacting an annular top surface of a first reference electrically conductive layer 146 that is one of the first electrically conductive layers 146 of the first-tier alternating stack (132, 146) and having a top surface located above a horizontal plane including a topmost surface of the second-tier alternating stack (232, 246); a first dielectric pillar structure 320 having at least one first laterally-protruding fin portion 320F that protrudes outward at each level of a first subset of the first electrically conductive layers 146 that underlies the first reference electrically conductive layer 146; and a first-tier dielectric spacer (122, 124, 127) that laterally surrounds the first contact via structure 86A, is not in direct contact with the first dielectric pillar structure 320, and vertically extending through each first electrically conductive layer 146 within a second subset of the first electrically conductive layers 146 that overlies the first reference electrically conductive layer 146.

As used herein, a “reference” layer refers to a layer that is selected as a reference among multiple layers having similar characteristics. Thus, for each first contact via structure 86A in the first exemplary structure, there exists one first electrically conductive layer 146 that is in direct contact with the first contact via structure 86A. The first electrically conductive layer 146 that is in direct contact with the first contact via structure 86A becomes a reference first electrically conductive layer 146 for that first contact via structure 86A. Likewise, the second electrically conductive layer 246 that is in direct contact with a second contact via structure 86B becomes a reference second electrically conductive layer 246 for that second contact via structure 86B.

In one embodiment, the memory device further comprises a second-tier dielectric spacer (222, 224, 227) that laterally surrounds the first contact via structure 86A, and is in contact with each of the second electrically conductive layers 246. In one embodiment, the second-tier dielectric spacer (222, 224, 227) is not in direct contact with the first-tier dielectric spacer (122, 124, 127).

In one embodiment, the first-tier dielectric spacer (122, 124, 127) comprises at least one first laterally-protruding fin portion 150F that protrudes outward at each level of a second subset of the first electrically conductive layers 146. The second-tier dielectric spacer (222, 224, 227) comprises at least one first laterally-protruding fin portion 250F that protrudes outward at each level of the second electrically conductive layers 246.

In one embodiment, the second-tier dielectric spacer (222, 224, 227) comprises an annular bottom surface in contact with a top surface of a bottommost second insulating layer 232 of the second insulating layers 232. In one embodiment, a topmost surface of the first-tier dielectric spacer (122, 124, 127) contacts a bottom surface of a bottommost second insulating layer 232 of the second insulating layers 232.

In one embodiment, the first dielectric pillar structure 320 comprises: a pillar dielectric liner 322 vertically extending through each first electrically conductive layer 146 within the first subset of the first electrically conductive layers 146; and a pillar dielectric material layer 324 laterally surrounded by the pillar dielectric liner 322 and comprising a vertically-extending portion that vertically extends from the first contact via structure 86A into a portion of the substrate 9 that underlies the first-tier alternating stack (132, 146). In one embodiment, the first dielectric pillar structure 320 further comprises a pillar dielectric fill material portion 326 that is laterally surrounded by the pillar dielectric material layer 324.

In one embodiment, the first-tier dielectric spacer (122, 124, 127) comprises: a first dielectric liner 122 in contact with each first electrically conductive layer 146 within the second subset of the first electrically conductive layers 146; and a first dielectric material layer 124 laterally surrounded by the first dielectric liner 122 and comprising a vertically-extending portion that extends through each first electrically conductive layer 146 within the second subset of the first electrically conductive layers 146.

In one embodiment, the first-tier dielectric spacer (122, 124, 127) further comprises a first tubular dielectric material portion 127 laterally surrounding the first dielectric material layer 124 and contacting a segment of a cylindrical sidewall of the first contact via structure 86A. In one embodiment, the first tubular dielectric material portion 127 is in contact within an annular top surface of a laterally-protruding annular portion of the first contact via structure 86A (which fills an annular recess underlying the first tubular dielectric material portion 127).

In one embodiment, the memory device further comprises a second support and contact assembly 480 vertically extending through the first-tier alternating stack (132, 146) and the second-tier alternating stack (232, 246). The second support and contact assembly 480 comprises: a second contact via structure 86B contacting an annular top surface of a second reference electrically conductive layer 246 that is one of the second electrically conductive layers 246 of the second-tier alternating stack (232, 246) and having a top surface located within the horizontal plane including the topmost surface of the second-tier alternating stack (232, 246); and a second dielectric pillar structure 420 underlying and contacting the second contact via structure 86B, and extending into the substrate 9.

In one embodiment, the second dielectric pillar structure 420 comprises second laterally-protruding fin portions 420FF that protrude outward at each level of the first electrically conductive layers 146. In one embodiment, the second dielectric pillar structure 420 further comprises at least one additional laterally-protruding fin portion 420SF that protrudes outward at each level of a first subset of the second electrically conductive layers 246 that underlies the second reference electrically conductive layer 246.

In one embodiment, the second dielectric pillar structure 420 comprises: a first dielectric liner 122 vertically extending through each layer within the first-tier alternating stack (132, 146); a first dielectric material layer 124 laterally surrounded by the first dielectric liner 122 and comprising a vertically-extending portion that vertically extends through each layer within the first-tier alternating stack (132, 146) and laterally-extending annular portions that comprise portions of the fin portions 420FF and laterally protrude outward from the vertically-extending portion at each level of the first electrically conductive layers 146; a first dielectric fill material portion 126 that is laterally surrounded by the first dielectric liner 122; an additional dielectric liner 422 (i.e., an inner dielectric liner 422) vertically extending from a bottom surface of the second contact via structure 86B into a volume located inside the first dielectric fill material portion 126 and having a bottom surface below a horizontal plane including a topmost surface of the first-tier alternating stack (132, 146).

In one embodiment, the first support and contact assembly 380 lacks an air gap 129 in the first dielectric pillar structure 320, while the second support and contact assembly 480 contains an air gap 129 in the second dielectric pillar structure 420.

The various embodiments of the present disclosure can be employed to provide a three-dimensional memory device including support and contact assemblies (380, 480). Each of the support and contact assemblies (380, 480) comprises a respective contact via structure 86 and a respective dielectric pillar structure (320 or 420) which provide structural support throughout the manufacturing process and after formation of the contact via structures 86. The dielectric pillar structures (320, 420) are formed below the respective contact via structures 86. Thus, the sides of the respective contact via structures 86 do not contact the sidewalls dielectric pillar structures (320, 420) which are vertically spaced from the contact via structures 86, or the sidewalls of the support pillar structure 20 which are laterally spaced from the contact via structures 86. This lacks of sidewall contact prevents or reduces undesirable, asymmetrically shaped contact via structures 86, which in turn reduces defects and open circuits. Furthermore, the combined dielectric pillar structures (320, 420) and the support pillar structure 20 have a high density, which prevents or reduces pattern collapse during replacement of the sacrificial material layers with the electrically conductive layers.

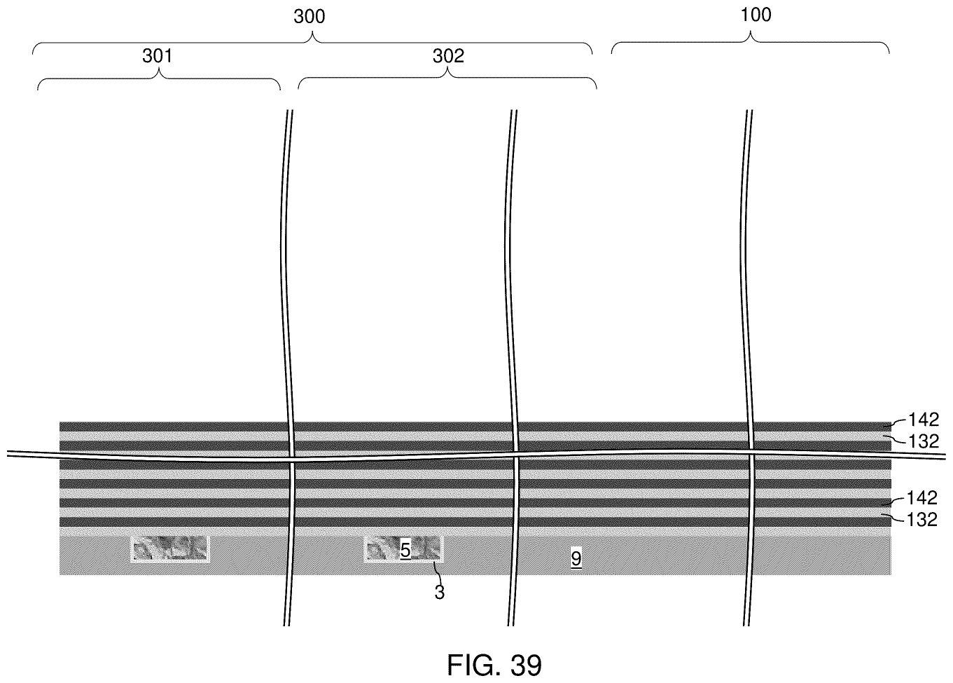

Referring to FIG. 39, a second exemplary structure according to a second embodiment of the present disclosure is illustrated. The second exemplary structure can be derived from the first exemplary structure illustrated in FIGS. 1A and 1B by forming a first-tier alternating stack (132, 142) by performing the processing steps described with reference to FIGS. 2A and 2B.

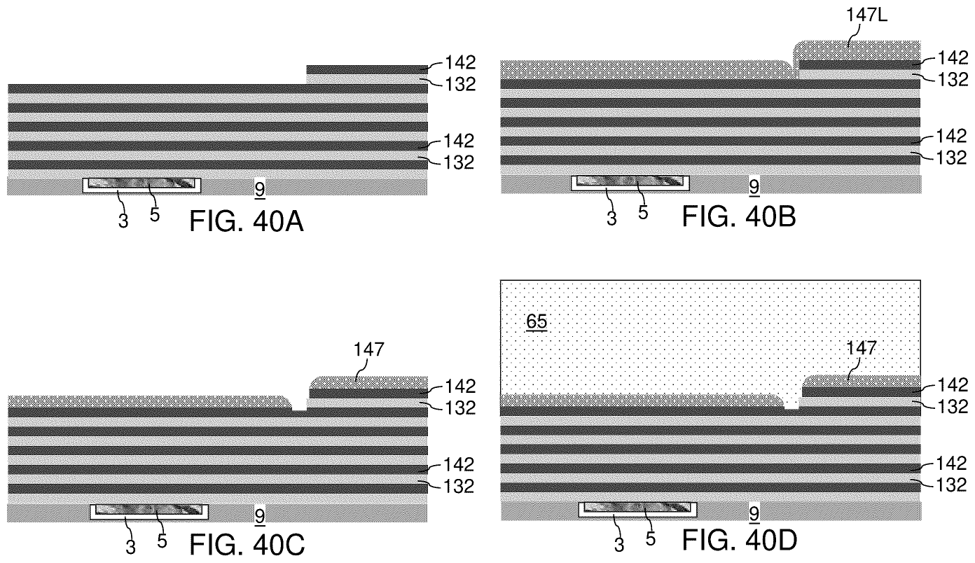

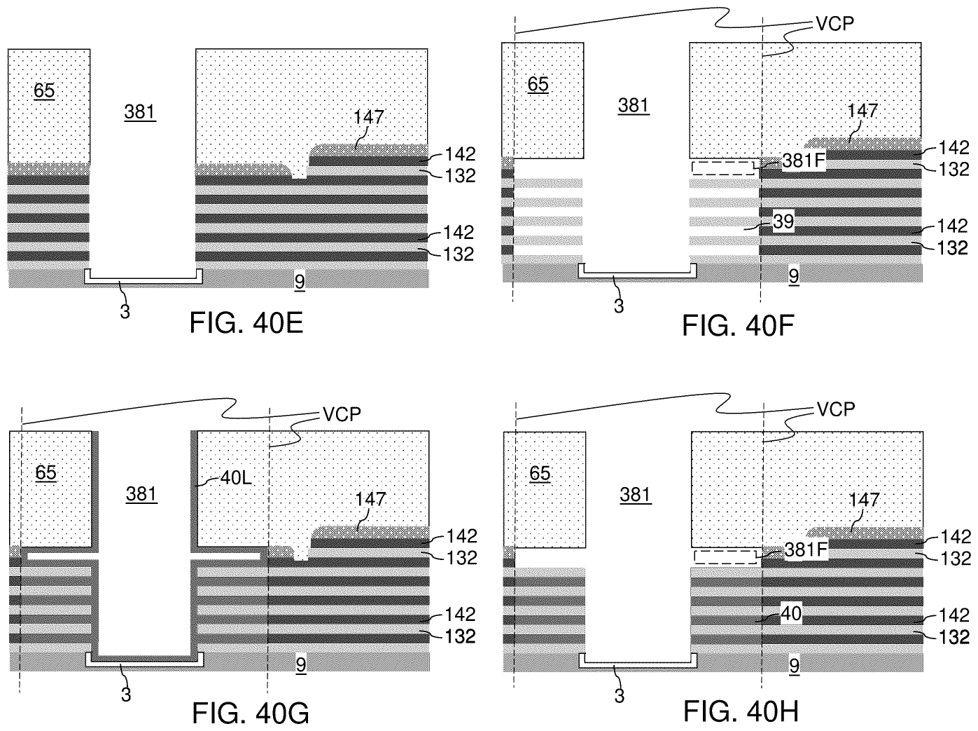

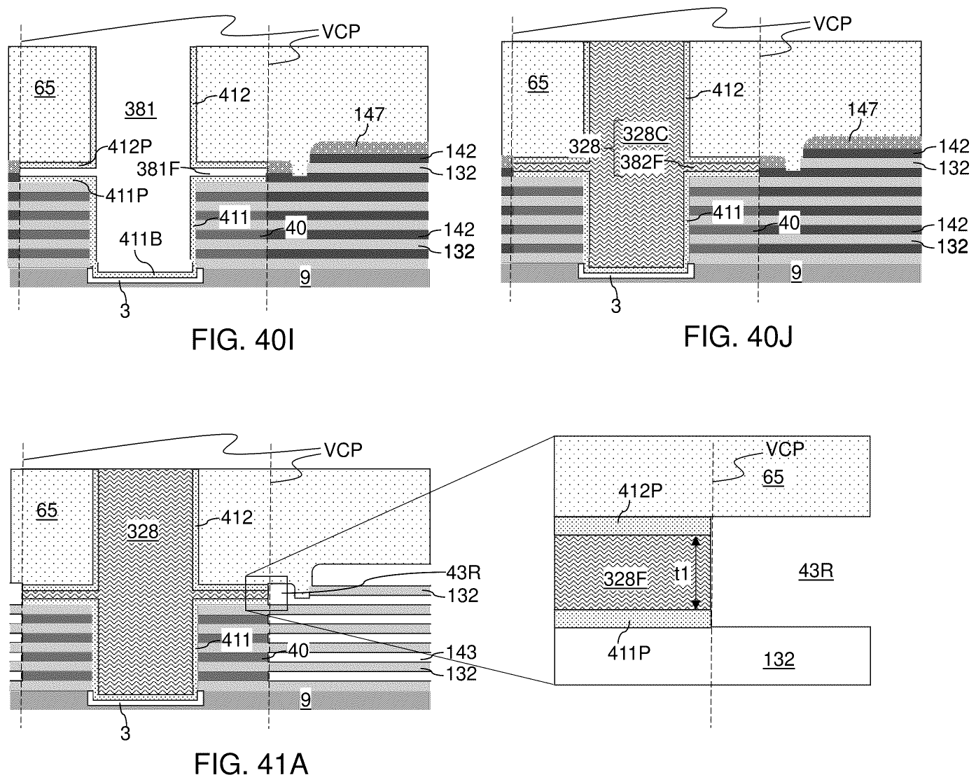

FIGS. 40A-40J are sequential vertical cross-sectional views of a region of the second exemplary structure during formation of a sacrificial via fill structure 328 according to an embodiment of the present disclosure.

Referring to FIG. 40A, stepped surfaces can be formed in the contact region 300 of the second exemplary structure. For example, a trimmable photoresist layer can be applied over the first-tier alternating stack (132, 142) to cover the entirety of the memory array region 100 and a predominant portion of the contact region 300 that is proximal to the memory array region 100, and an anisotropic etch process can be performed to etch portions of a pair of a first sacrificial material layer 142 and a first insulating layer 132 that are not covered by the trimmable photoresist layer to form a stepped surface including a horizontally-extending surface segment and a vertical step. Subsequently, the trimmable photoresist layer can be trimmed to physically expose a larger area including an unrecessed portion of the first-tier alternating stack (132, 142). A set of unit processing steps including an anisotropic etch process and a photoresist trimming process can be repeatedly performed to vertically recess pre-existing stepped surfaces and to form an additional stepped surface at each iteration of the set of unit processing steps. The stepped surfaces can be formed such that each first sacrificial material layer 142 has a physically-exposed horizontal surface segment, which is a horizontally-extending surface segment of stepped surfaces that continuously extend from the bottommost layer of the first-tier alternating stack (132, 142) to the topmost layer of the first-tier alternating stack (132, 142). The stepped surfaces of the first-tier alternating stack (132, 142) can be formed in the first contact region 301.

Referring to FIG. 40B, a sacrificial plate material layer 147L can be formed over the stepped surfaces of the first-tier alternating stack (132, 142) by anisotropically depositing a sacrificial plate material. In one embodiment, the sacrificial plate material may have the same material composition as, or may have a similar material composition as, the material of the first sacrificial material layers 142. For example, the sacrificial plate material layer 147L may comprise silicon nitride, which may be stoichiometric, silicon rich, or doped with hydrogen atoms. In one embodiment, the first sacrificial material layers 142 and the sacrificial plate material layer 147L may comprise silicon nitride. The anisotropic deposition of the sacrificial plate material may be performed by a plasma-enhanced chemical vapor deposition or physical vapor deposition.

The anisotropic nature of the deposition process causes horizontally-extending portions of the sacrificial plate material layer 147L to have a greater thickness (as measured along the vertical direction) than vertically-extending portions of the sacrificial plate material layer 147L (of which the thickness is measured along a horizontal direction). In one embodiment, the lateral thickness of the vertically-extending portions of the sacrificial plate material layer 147L may be in a range from 20% to 70%, such as from 40% to 60%, of the vertical thickness of the horizontally-extending portions of the sacrificial plate material layer 147L. The vertical thickness of the horizontally-extending portions of the sacrificial plate material layer 147L may be in a range from 40 nm to 200 nm, such as from 60 nm to 120 nm, although lesser and greater thicknesses may also be employed.

Referring to FIG. 40C, a etch process can be performed to recess the material of the sacrificial plate material layer 147L. The duration of the etch process can be selected such that the etch distance is greater than the lateral thickness of the vertically-extending portions of the sacrificial plate material layer 147L, but less than the thickness of the horizontally-extending portions of the sacrificial plate material layer 147L. The sacrificial plate material layer 147L is divided into a plurality of horizontally-extending sacrificial plate material portions that are disjoined from each other, which are herein referred to as sacrificial material plates 147. Each sacrificial material plate 147 can be formed on a top surface of a respective one of the first sacrificial material layers 142, and does not contact any first insulating layer 132. The vertical thickness of each sacrificial material plate 147 may be in a range from 40% to 200%, such as from 60% to 120%, of the thickness of a first sacrificial material layer 142. For example, the vertical thickness of each sacrificial material layer 147L may be in a range from 30 nm to 120 nm, such as from 40 nm to 80 nm, although lesser and greater vertical thicknesses may also be employed. Each sacrificial material plate 147 may have a respective bottom surface that contacts a top surface of a respective underlying first sacrificial material layer 142.

Referring to FIG. 40D, a dielectric fill material can be deposited over the stepped surfaces. Excess portions of the dielectric fill material can be removed from above the horizontal plane including the topmost surface of the first-tier alternating stack (132, 142). A remaining portion of the dielectric fill material comprises a dielectric material portion having a stepped bottom surface, which is herein referred to as a stepped dielectric material portion 65. The top surface of the stepped dielectric material portion 65 may be formed within the horizontal plane including the topmost surface of the first-tier alternating stack (132, 142).

Subsequently, the various processing steps described with the first exemplary structure can be performed. Specifically, the processing steps described with reference to FIGS. 2A and 2B can be performed to form first-tier openings (149, 119). The processing steps described with reference to FIG. 3 can be performed to form first-tier sacrificial opening fill structures (148, 118) and an inter-tier insulating layer 180. Via cavities can be formed through the inter-tier insulating layer 180, the stepped dielectric material portion 65, and the first-tier alternating stack (132, 142) within areas that overlie the optional sacrificial substrate pads 5 in a plan view, and can be filled with first-tier sacrificial via fill structures (not illustrated). Each first-tier sacrificial via fill structure can optionally be formed directly on and may have an areal overlap in a plan view with the optional sacrificial substrate pad 5. Alternatively, the sacrificial substrate pads 5 can be omitted.

The processing steps described with reference to FIG. 13 can be performed to form a second-tier alternating stack (232, 242). The processing steps described with reference to FIG. 40A may be repeated with suitable modifications during patterning of the second-tier alternating stack (232, 242) to form additional stepped surfaces on the second-tier alternating stack (232, 242). The additional stepped surfaces of the second-tier alternating stack (232, 242) may be formed in the second contact region 302 such that the stepped surfaces of the second-tier alternating stack (232, 242) are laterally offset relative to the stepped surfaces of the first-tier alternating stack (132, 142). The second-tier alternating stack (232, 242) may be completely removed within the area of the stepped dielectric material portion 65 that overlies the stepped surfaces of the first-tier alternating stack (132, 142). All layers of the first-tier alternating stack (132, 142) can be present within the area of the stepped surfaces of the second-tier alternating stack (232, 242) in the second contact region 30.

The processing steps described with reference to FIGS. 40B-40C can be subsequently performed to form an additional sacrificial plate material layer, to pattern the additional sacrificial plate material layer into additional sacrificial material plates, and to form an additional dielectric material portion (which may be an additional stepped dielectric material portion) having a top surface within a horizontal plane including the top surface of the topmost layer of the second-tier alternating stack (232, 242). The processing steps described with reference to FIGS. 14, 15, 16A and 16B, can be performed to form memory opening fill structures 58 and support pillar structures 20. A first contact-level dielectric layer 280 can be formed over the second-tier alternating stack (232, 242) as described with reference to FIG. 17A. Additional via cavities can be formed through the first contact-level dielectric layer 280, the additional stepped dielectric material portion, and the second-tier alternating stack (232, 242) over the areas of the first-tier sacrificial via fill structures.

Referring to FIG. 40E, the first-tier sacrificial via fill structures can be removed from inside the via cavities which vertically extend through the stepped dielectric material portion 65 and the first-tier alternating stack (132, 142). The sacrificial substrate pads (if present) 5 can be subsequently removed. A contact via cavity 381 can be formed within each contiguous void that includes a volume of an additional via cavity through the first contact-level dielectric layer 280, the additional stepped dielectric material portion, and the second-tier alternating stack (232, 242), a volume of a cavity formed by removal of a first-tier sacrificial via fill structure, and optionally volume of a cavity formed by removal of a sacrificial substrate pad 5. The optional substrate dielectric liner 3 can be physically exposed underneath each contact via cavity 381.

In summary, referring collectively to FIGS. 39-40E, an alternating stack of insulating layers (132 and optionally 232) and sacrificial material layers (142 and optionally 242) is formed over a substrate. Stepped surfaces can be formed by patterning the alternating stack. A sacrificial material plate 147 can be formed on a top surface segment (e.g., on a horizontally-extending surface segment of the stepped surfaces) of one of the sacrificial material layers (142 and optionally 242). A dielectric material portion (such as a stepped dielectric material portion 65) can be formed over the sacrificial material plate 147 and over the stepped surfaces. A contact via cavity 381 can be formed through the dielectric material portion (such as a stepped dielectric material portion 65), the sacrificial material plate 147, and a portion of the alternating stack {(132, 232), (142, 242)} that underlies the sacrificial material plate 147. A substrate dielectric liner 3 comprising an oxide of a semiconductor material in the substrate (e.g., silicon oxide liner 3) may be present underneath the contact via cavity 381.

Referring to FIG. 40F, an isotropic etch process can be performed to isotropically etch the materials of the sacrificial material plates 147 and the sacrificial material layers (142, 242). Each contact via cavity 381 can be laterally surrounded by and may vertically extend through a respective sacrificial material plate 147. Each sacrificial material plate 147 contacts a top surface of a respective one of the sacrificial material layers (142, 242). The isotropic etch process isotropically etches around each contact via cavity 381 proximal portions of a sacrificial material plate 147, proximal portions of a sacrificial material layer (142, 242) contacting a bottom surface of the sacrificial material plate 147, and proximal portions of any additional sacrificial material layers (142, 242) which underlie the sacrificial material layer (142, 242).

The isotropic etch process laterally expands each contact via cavity 381 by laterally recessing the sacrificial material plates 147 and each of the sacrificial material layers (142, 242) that are exposed to the contact via cavities 381. Each contact via cavity 381 is expanded to include a fin cavity 381F which is formed in a volume from which an annular portion of a sacrificial material plate 147 and an annular portion of an underlying sacrificial material layer (142 or 242) are removed, and optionally additional fin cavities 39 which are formed in volumes from which annular portions of additional sacrificial material layers (142 or 242) are removed. The isotropic etch process etches proximal portions of the sacrificial material plate 147, the one of the sacrificial material layers (142, 242) that contacts the bottom surface of the sacrificial material plate 147, and the at least one optional additional sacrificial material layer (142, 242) that underlies the one of the sacrificial material layers (142, 242).

In one embodiment, the sacrificial material plates 147 and the sacrificial material layers (142, 242) may comprise the same material, and the lateral extent of each fin cavity 381F formed in a volume from which an annular portion of a sacrificial material plate 147 and an annular portion of an underlying sacrificial material layer (142 or 242) may have the same lateral extent as the lateral extent of each additional fin cavity 39 that is formed underneath the fin cavity 381F through removal of portions of additional sacrificial material layers (142, 242). In this case, the sidewall of the fin cavity 381F and each sidewall of any additional underlying fin cavity 39 may be formed within a same vertically-extending cylindrical plane VCP. The lateral etch distance of the isotropic etch process may be in a range from 100% to 1,000%, such as from 150% to 600%, of the thickness of a sacrificial material layer (142, 242). In an illustrative example, if the sacrificial material plates 147 and the sacrificial material layers (142, 242) comprise silicon nitride, the isotropic etch process may comprise a wet etch process employing hot phosphoric acid. Each contact via cavity 381 comprises a cylindrical cavity portion and a fin cavity 381F that underlies and is vertically bounded by a dielectric material portion (such as the stepped dielectric material portion 65), and may optionally comprise at least one additional fin cavity 39 that underlies the fin cavity 381F. The fin cavity 381F has a greater height than the additional fin cavities 39.

Referring to FIG. 40G, an insulating material layer 40L, such as a silicon oxide layer, can be conformally deposited in the contact via cavities 381 by a conformal deposition process, such as a chemical vapor deposition process or an atomic layer deposition process. The thickness of the insulating material layer is greater than one half of the thickness of each sacrificial material layer (142, 242) (which is the same as the height of each additional fin cavity 39), and is less than one half the height of each fin cavity 381F that is formed by removal of portions of a combination of a sacrificial material plate 147 and an underlying sacrificial material layer (142, 242). Thus, the insulating material layer 40L partially fills the fin cavity 381F, and completely fills the additional fin cavities 39.

Referring to FIG. 40H, an isotropic etch process can be performed to isotropically etch the insulating material layer 40L. The duration of the isotropic etch process can be selected such that the etch distance of the isotropic etch process for the material of the insulating material layer 40L may be in a range from 100% to 150%, such as 110% to 140%, of the thickness of the insulating material layer 40L. The insulating material layer can be removed completely from inside the volumes of the cylindrical cavity and the fin cavity 381F of each contact via cavity 381 as formed after the processing steps of FIG. 40F, while remaining portions of the insulating material layer 40L remains in the volumes of the additional fin cavities 39. Remaining portions of the insulating material layer 40L filling the volumes of the additional fin cavities 39 may comprise a vertical stack of annular insulating fins 40, which laterally surrounds a lower portion of a remaining volume of a respective contact via cavity 381. Thus, the additional fin cavities 39 that are formed by isotropically etching the additional sacrificial material layers (142, 242) are filled with the annular insulating fins 40. Each of the annular insulating fins 40 may have a flat annular shape with a uniform thickness throughout. Each vertical stack of annular insulating fins 40 may be formed at levels of a subset of the sacrificial material layers (142, 242) that underlies the fin cavity 381 that is vertically bounded by an overlying dielectric material portion (such as stepped dielectric material portion 65).

Referring to FIG. 40I, a selective silicon oxide deposition process can be performed to grow a silicon oxide material from physically exposed surfaces of the insulating layers (132, 232), the stepped dielectric material portion 65 and the vertical stack of annular insulating fins 40 while suppressing growth of the silicon oxide material from any physically exposed surface of remaining portions of the sacrificial material plates 147 and the sacrificial material layers (142, 242) that are exposed to the fin cavities 381F. In an illustrative example, the sacrificial material plates 147 and the sacrificial material layers (142, 242) comprise silicon nitride, and the selective silicon oxide deposition process grows a silicon oxide material from the surfaces of the insulating layers (132, 232), the annular insulating fins 40, and the dielectric material portions (such as the silicon oxide stepped dielectric material portion 65) overlying the fin cavities 381F, while suppressing growth of the silicon oxide material from physically exposed sidewall surfaces of the silicon nitride sacrificial material plates 147 and the silicon nitride sacrificial material layers (142, 242).

In an exemplary silicon oxide area selective deposition (ASD) process, a precursor gas mixture including an organic silicon-containing precursor compound and an oxidizing agent such as ozone (O₃) or oxygen (O₂) may be employed in an area selective atomic layer deposition process. The organic silicon-containing precursor compound may comprise trisilylamine (TSA) ((SiH₃)3N) (e.g., Orthrus™ precursor from Air Liquide), bis(diethylamino)silane (BDEAS, also known as SAM-24,) [SiH₂[N(CH2CH₃)₂]₂, or 1,2-Bis(diisopropylamino)disilane (BDIPADS) (as described in Jeong-Min Lee, et al. “Inhibitor-free area-selective atomic layer deposition of SiO2 through chemoselective adsorption of an aminodisilane precursor on oxide versus nitride substrates”, Applied Surface Science 589(2022) 152939, incorporated herein by reference).

The deposition temperature may be maintained at a level that is sufficiently high to enable the chemical reaction of the silicon-containing compound with the oxygen species to form silicon oxide on the exposed silicon oxide areas, yet low enough to prevent this reaction on the silicon nitride surfaces, such as a deposition temperature in a range from 50 degrees Celsius to 250 degrees Celsius. In some embodiments, alternating cycles of atomic layer deposition and atomic layer etching may be used to enhance the area selective deposition of silicon oxide on silicon oxide surfaces versus on silicon nitride surfaces. In some embodiments, a hydrofluoric acid and/or plasma surface pre-treatment may be employed to increase the selectivity of the silicon oxide deposition process.

The selective silicon oxide deposition process can form a first silicon oxide liner 411 that grows from the physically exposed surfaces of the insulating layers (132, 232) and the vertical stack of annular insulating fins 40, and a second silicon oxide liner 412 that grows from a surface of the dielectric material portion (such as a stepped dielectric material portion 65) around the contact via cavity 381 and vertically spaced from the first silicon oxide liner 411 by a gap. The thickness of the first silicon oxide liner 411 and the second silicon oxide liner 412 may be the same, and is less than one half of the height of each fin cavity 381F as provided after the processing steps of FIG. 40H. The lower surface of the fin cavity 381F is covered with a horizontal plate portion 411P of the first silicon oxide liner 411, and the upper surface of the fin cavity 381F is covered with a horizontal plate portion 412P of the second horizontal liner 412.

In one embodiment, the first silicon oxide liner 411 may comprise a first cylindrical silicon oxide portion having a cylindrical configuration and formed on a vertical stack of annular insulating fins 40 and on cylindrical sidewalls of a subset of the insulating layers (132, 232). Further, the first silicon oxide liner 411 may comprise a first annular silicon oxide plate portion 411P that is formed in a lower portion of a fin cavity 381F. In one embodiment, outer cylindrical sidewalls of the vertical stack of annular insulating fins 40 may be formed within a vertically-extending cylindrical plane VCP including an outer cylindrical sidewall of the first annular silicon oxide plate portion 411P. In addition, the first silicon oxide liner 411 comprises a bottom plate portion 411P adjoined to a bottom periphery of the first cylindrical silicon oxide portion. In one embodiment, the bottom plate portion 411B of the first silicon oxide liner 411 may be formed below a horizontal plane including a bottommost surface of the alternating stack {(132, 232), (142, 242)}. The first silicon oxide liner 411 may have a uniform thickness throughout.

In one embodiment, the second silicon oxide liner 412 can be formed on the physically exposed surfaces of a dielectric material portion (such as a stepped dielectric material portion 65). The second silicon oxide liner 412 has a same material composition and a same thickness as the first silicon oxide liner 411. In one embodiment, the second silicon oxide liner 412 comprises a second cylindrical silicon oxide portion that is formed on a cylindrical sidewall of the dielectric material portion, and a second annular silicon oxide plate portion 412P that is formed in an upper region of a fin cavity 381F as provided after the processing steps of FIG. 40H.

In one embodiment, the thickness of the first silicon oxide liner 411 and the second silicon oxide liner 412 is selected such that the plate portion 412P of the second silicon oxide liner 412 is disjoined from (i.e., does not contact) the plate portion 411P of the first silicon oxide liner 411 in the fin cavity 381F. A vertical distance between the second silicon oxide liner 412 and the first silicon oxide liner 411 may be uniform. In an illustrative example, the thickness of the first silicon oxide liner 411 and the second silicon oxide liner 412 may be in a range from 6 nm to 40 nm, such as from 10 nm to 20 nm, although lesser and greater thicknesses may also be employed. The vertical distance between the first silicon oxide liner 411 and the second silicon oxide liner 412 may be in a range from 30 nm to 120 nm, such as from 50 nm to 80 nm, although lesser and greater vertical distances may also be employed.

Referring to FIG. 40J, a sacrificial fill material can be deposited in remaining volumes of the contact via cavities 381. Excess portions of the sacrificial fill material may be removed from above the horizontal plane including the top surface of the first contact-level dielectric layer 280 (shown, for example, in FIG. 25) to form sacrificial via fill structures 328. The sacrificial fill material may comprise a semiconductor material (such as amorphous silicon), a carbon-based material (such as amorphous carbon or diamond-like carbon), a dielectric material (such as porous organosilicate glass), or any other sacrificial material that may be subsequently removed selective to the material of the first silicon oxide liner 411, the second silicon oxide liner 412, and the material of a backside blocking dielectric layer to be subsequently formed. Each sacrificial via fill structure 328 may comprise a cylindrical portion 328C and flange portion 328F that laterally protrudes from the cylindrical portion. A cylindrical sidewall of a flange portion 328F of the sacrificial via fill structure 328 is located in the fin cavity 381F and contacts the respective plate portions (411P, 412P). The flange portion 328F may laterally extend to the vertically-extending cylindrical plane VCP that includes outer cylindrical sidewalls of a vertical stack of annular insulating fins 40.

In one embodiment, a dielectric material portion (such as a stepped dielectric material portion 65) overlies the flange portion 328F of each sacrificial via fill structure 328, and laterally surrounds the cylindrical portion 328C of the sacrificial via fill structure 328. In one embodiment, the top surface of each sacrificial via fill structure 328 can be formed within the horizontal plane including the top surface of the first contact-level dielectric layer 280. In this case, the top surface of the dielectric material portion (such as a stepped dielectric material portion 65) may be located below a horizontal plane including the top surfaces of the sacrificial via fill structures 328.

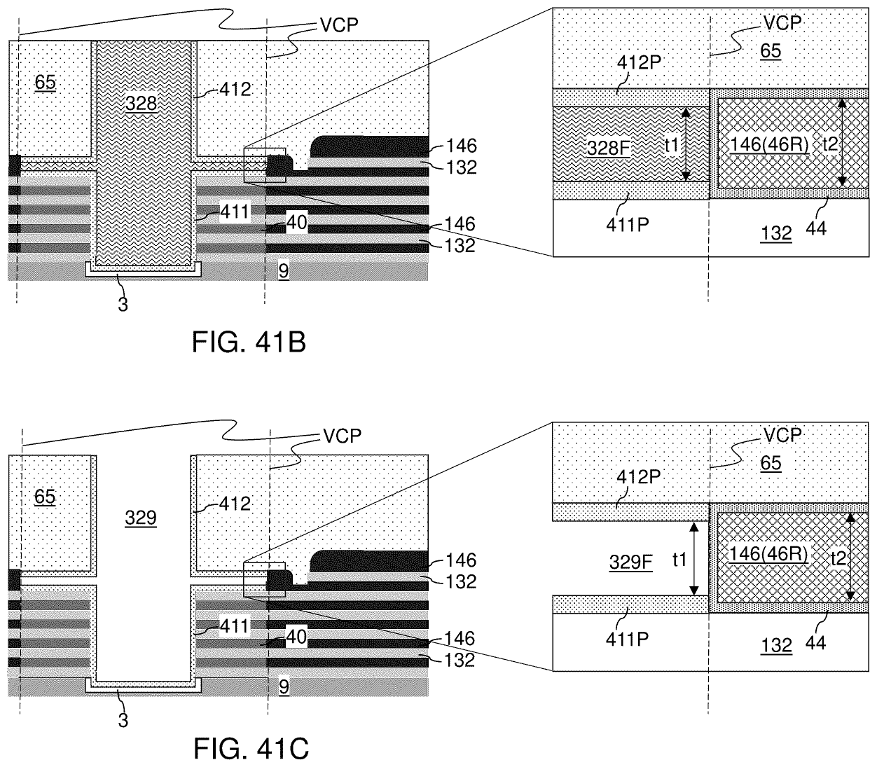

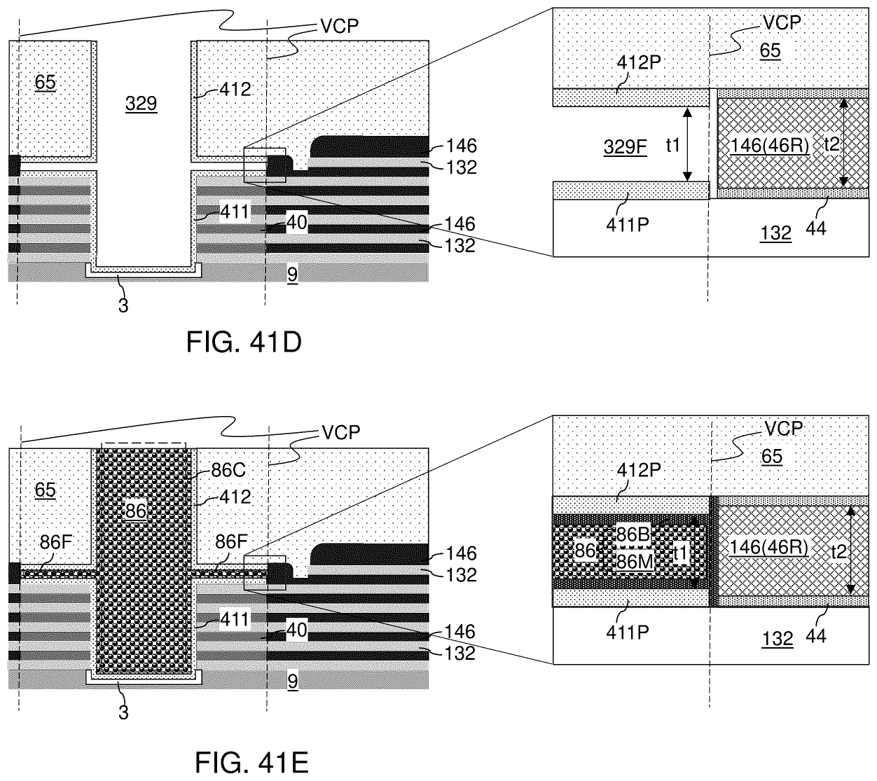

FIGS. 41A-41E are sequential vertical cross-sectional views of a region of a first configuration of the second exemplary structure during replacement of sacrificial material layers (142, 242) with electrically conductive layers (146, 246) and replacement of the sacrificial via fill structures 328 with contact via structures 86 according to the first aspect of the second embodiment of the present disclosure.

Referring to FIG. 41A, the processing steps described with reference to FIGS. 26A and 26B can be performed to form a second contact-level dielectric layer 282 and backside trenches 79. Subsequently, the isotropic etch process described with reference to FIG. 27 can be performed to form backside recesses. The backside recesses 43 may comprise first backside recesses 143, which are formed in volumes from which the first sacrificial material layers 142 and a subset of the sacrificial material plates 147 that are in contact with the first sacrificial material layers 142 are removed. A reference backside recess 43R is formed in a volume from which the sacrificial material plate 147 and the underlying first sacrificial material layer 142 is removed. The backside recesses 43 may further comprise second backside recesses (not illustrated in FIG. 41A), which are formed in volumes from which the second sacrificial material layers 242 a subset of the sacrificial material plates 147 that are in contact with the second sacrificial material layers 242 are removed.

The reference backside recess 43R that laterally surrounds the flange portion 328F of a respective sacrificial via fill structure 328 has a greater height than the height of any underlying backside recess 43, which equals the thickness of each sacrificial material layer (142, 242) at the processing steps of FIG. 40J. In one embodiment, each flange portion 328F of the sacrificial via fill structure 328 may have a cylindrical surface that is exposed to a respective reference backside recess 43R and located within a respective vertically-extending cylindrical plane VCP, within which sidewalls of an underlying vertical stack of annular insulating fins 40 may be located. The thickness of the flange portion 328F of the sacrificial via fill structure 328 is herein referred to as a first thickness t1.

Referring to FIG. 41B, the processing steps described with reference to FIG. 27 can be performed to form a backside blocking dielectric layer 44 and an electrically conductive layer (146 or 246) within each backside recess 43. Thus, the sacrificial material layers (142, 242) can be replaced with material portions including electrically conductive layers (146, 246). An alternating stack {(132, 232), (146, 246)} of insulating layers (132, 232) and electrically conductive layers (146, 246) is formed over the substrate. Memory openings 49 vertically extend through the alternating stack {(132, 232), (146, 246)}. Memory opening fill structures 58 can be located in the memory openings 49. Each of the memory opening fill structures 58 may comprise a respective vertical stack of memory elements (which comprise portions of a charge storage material layer 54 located at levels of electrically conductive layers (146, 246)) and a respective vertical semiconductor channel 60.

For each sacrificial via fill structure 328, an electrically conductive layer (146, 246) that fills the reference backside recess 43R and located at the same level as the flange portion 328F of the sacrificial via fill structure 328 is herein referred to as a reference electrically conductive layer 46R. The thickness of the portion of each reference electrically conductive layer 46R that is proximal to the flange portion 328F of a sacrificial via fill structure 328 is herein referred to as a second thickness t2. The second thickness t2 can be greater than the thickness of portions of the electrically conductive layers 146 underlying the reference electrically conductive layer 46R.

Referring to FIG. 41C, the processing steps described with reference to FIGS. 28 and 29A and 29B can be performed with modifications such that the connection via cavities 81 through the third contact-level dielectric layer 284 are formed directly over the sacrificial via fill structures 328. The sacrificial via fill structures 328 can be subsequently removed selective to the materials of the first silicon oxide liner 411, the second silicon oxide liner 412, and optionally the backside blocking dielectric layer 44. For example, if the sacrificial via fill structures 328 comprise a semiconductor material, a wet etch process employing tetramethylammonium hydroxide (TMAH) or trimethyl-2 hydroxyethyl ammonium hydroxide (“hot TMY”) may be performed to remove the sacrificial via fill structures 328. If the sacrificial via fill structures 328 comprise a carbon-based material, an ashing process may be performed to remove the sacrificial via fill structures 328. A void 329 is formed in the volume from which the sacrificial via fill structure 328 is removed. The void 329 may comprise a cylindrical portion and a flange portion 329F.

Referring to FIG. 41D, an isotropic etch process can be performed to remove portions of the backside blocking dielectric layers 44 that are proximal to the flange portions 329F of the voids 329 selective to the material of the electrically conductive layers (146, 246) and preferably selective to the material of the first silicon oxide liner 411 and the second silicon oxide liner 412. For example, if the backside blocking dielectric layer 44 comprises aluminum oxide, a wet etch process employing hot phosphoric acid may be performed to remove portions of the backside blocking dielectric layers 44 that are proximal to the voids 329. A cylindrical sidewall of a reference electrically conductive layer 46R can be physically exposed around each flange portion of the voids 329.

Referring to FIG. 41E, at least one metallic material can be conformally deposited in the voids 329 by performing at least one conformal metallic material deposition process. For example, a metallic barrier liner 86B including a metallic barrier material (such as TiN, TaN, WN, and/or MoN) can be conformally deposited on the physically exposed surfaces of the reference electrically conductive layer 46B and on the surfaces of the first silicon oxide liner 411 and the second silicon oxide liner 412 around each flange portion 329F of the void 329. The metallic barrier liner 86B can be deposited by a conformal deposition process, such as a chemical vapor deposition process. A metal fill material such as Cu, W, Mo, Co, Ru, Ti, and/or Ta can be deposited in remaining volumes of the voids on the metallic barrier liner 86B. The metal fill material can be deposited by chemical vapor deposition or electroplating. Excess portions of the metallic barrier liner 86B and the metal fill material can be removed from above the horizontal plane including the top surface of the third contact-level dielectric layer 284 (shown, for example, in FIG. 38) by performing a planarization process, such as a chemical mechanical polishing process. Each remaining portion of the metal fill material that fills a respective fraction of a void 329 constitutes a metal fill material portion 86M. Each contiguous combination of a metallic barrier liner 86B and a metal fill material portion 86M constitutes a contact via structure 86.

Each electrically conductive layer (146, 246) can be contacted by a respective contact via structure 86. Each contact via structure 86 may contact only one electrically conductive layer (146, 246). Thus, each contact via structure 86 contacts a respective reference electrically conductive layer 46R.

Each sacrificial via fill structure 328 can be replaced with a respective contact via structure 86 such that the contact via structure 86 contacts a vertical cylindrical sidewall of the respective reference electrically conductive layer 46R. The contact via structure 86 may have a top surface located above a horizontal plane including a topmost surface of the alternating stack {(132, 232), (146, 246)}. For example, the contact via structure 86 may have a top surface located at a horizontal plane including a third contact-level dielectric layer 284 (shown, for example, in FIG. 38). The contact via structure 86 may have a bottom surface located at or below a horizontal plane including a bottommost surface of the alternating stack {(132, 232), (146, 246)}.

In one embodiment, the contact via structure 86 comprises a cylindrical portion 86C that vertically extends from the top surface of the contact via structure 86 to the bottom surface of the contact via structure 86; and a flange portion 86F having an annular top surface, an annular bottom surface, and a vertical cylindrical surface that contacts the vertical cylindrical sidewall of the reference electrically conductive layer 46R. In one embodiment, the reference electrically conductive layer 46R is embedded within a backside blocking dielectric layer 44; the flange portion 86F has a first thickness t1; and the reference electrically conductive layer 46R has a second thickness t2 that is greater than the first thickness t1. In one embodiment, a cylindrical interface between the contact via structure 86 and the reference electrically conductive layer 46R may be located at a vertically-extending cylindrical plane VCP that contains outer cylindrical sidewalls of an underlying vertical stack of annular insulating fins 40.

In one embodiment, the flange portion 86F of each contact via structure 86 can have a peripheral portion having a same vertical thickness as a vertical spacing between a bottom surface of the first annular silicon oxide plate portion of an underlying first silicon oxide liner 411 and a top surface of the second annular silicon oxide plate portion of an overlying second silicon oxide liner 412.

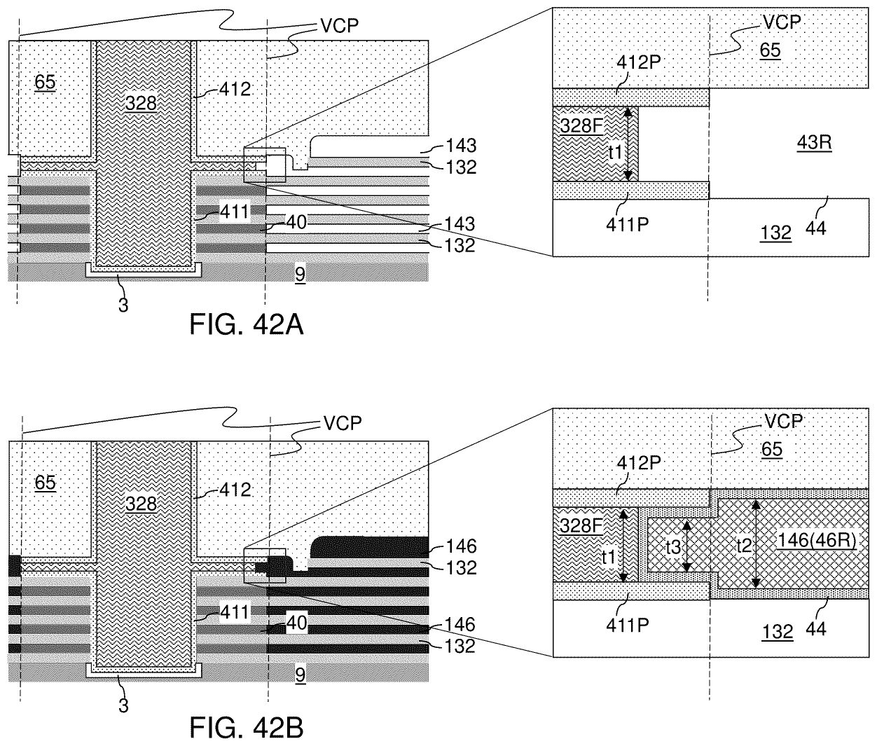

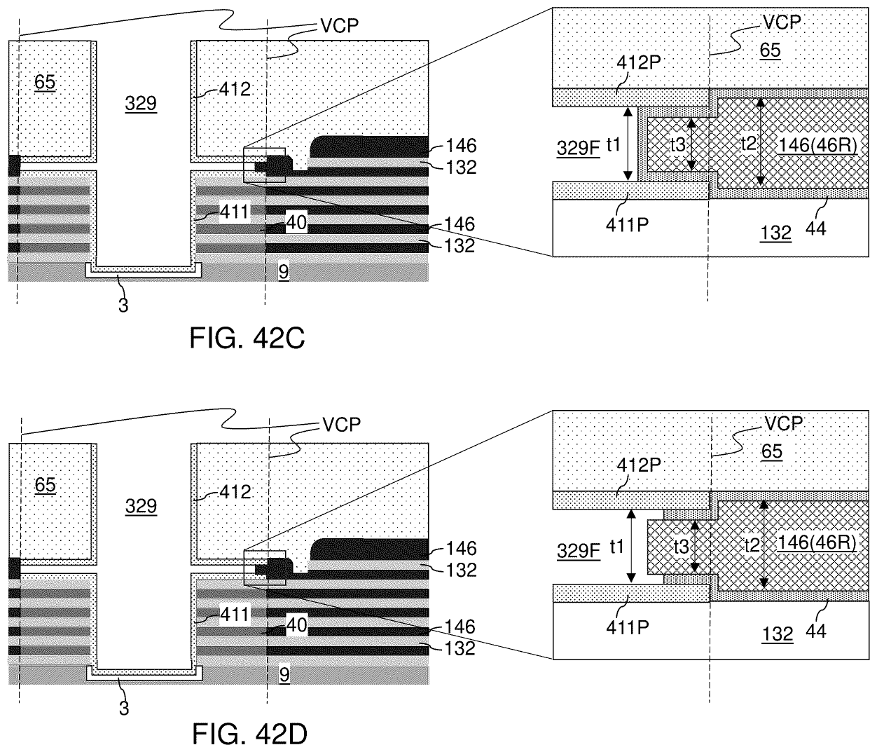

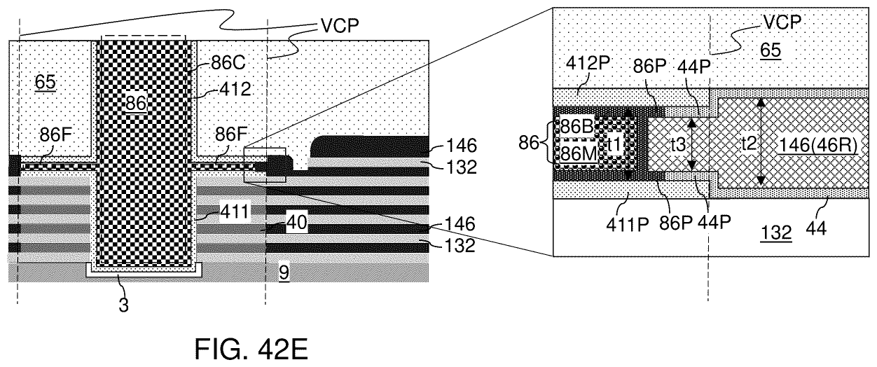

FIGS. 42A-42E are sequential vertical cross-sectional views of a region of a second configuration of the second exemplary structure during replacement of sacrificial material layers with electrically conductive layers (146, 246) and replacement of the sacrificial via fill structures with contact via structures 86 according to a second aspect of the second embodiment of the present disclosure.

Referring to FIG. 42A, the second configuration of the second exemplary structure can be derived from the first configuration of the exemplary structure illustrated in FIG. 41A by isotropically recessing a tubular surface region of the flange portion 328F of the sacrificial via fill structure 328 through the reference backside recess 43R. For example, if the sacrificial via fill structures 328 comprise a semiconductor material, a timed wet etch process employing tetramethylammonium hydroxide (TMAH) or trimethyl-2 hydroxyethyl ammonium hydroxide (“hot TMY”) may be performed to laterally recess the physically exposed sidewalls of the flange portion 328F of the sacrificial via fill structures 328. If the sacrificial via fill structures 328 comprise a carbon-based material, a timed ashing process having a low ashing rate can be performed for a short duration to remove surface portions of the flange portion 328F of the sacrificial via fill structures 328 that are exposed to the reference backside recess 43R.

Referring to FIG. 42B, the processing steps described with reference to FIG. 41B can be performed to form a backside blocking dielectric layer 44 and an electrically conductive layer (146, 246) within each backside recess 43. In one embodiment, each flange portion 328F of the sacrificial via fill structures 328 may have a first thickness t1; and each reference electrically conductive layer 46R in contact with a flange portion of a respective sacrificial via fill structure 328 may have a first portion having a second thickness t2 that is greater than the first thickness t1, and a second portion (which is a tubular portion) having a third thickness t3 that is less than the first thickness t1. The first portion having the second thickness t2 may be located outside the vertically-extending cylindrical plane VCP that includes cylindrical outer sidewalls of a vertical stack of annular insulating fins 40 that underlies the flange portion of the respective sacrificial via fill structure 328 and laterally surrounds the cylindrical portion of the respective sacrificial via fill structure 328. The second portion having the second thickness t3 may be located inside the vertically-extending cylindrical plane VCP between the second portion and the contact via structure 86 to formed in a subsequent step.

Referring to FIG. 42C, the processing steps described with reference to FIG. 41C can be performed to form voids 329. Each void 329 may include a volume from which a respective sacrificial via fill structure 328 is removed.

Referring to FIG. 42D, the isotropic etch described with reference to FIG. 41C can be performed to remove portions of the backside blocking dielectric layers 44 that are exposed on the flange portions 329F of the voids 329 selective to the material of the electrically conductive layers (146, 246) and preferably selective to the material of the first silicon oxide liner 411 and the second silicon oxide liner 412.

Referring to FIG. 42E, the processing steps described with reference to FIG. 41E can be performed to form the contact via structure 86. In one embodiment, the contact via structure 86 comprises a cylindrical portion 86C that vertically extends from the top surface of the contact via structure 86 to the bottom surface of the contact via structure 86; and a flange portion 86F having an annular top surface, an annular bottom surface, and a vertical cylindrical surface that contacts the vertical cylindrical sidewall of the reference electrically conductive layer 46R. In one embodiment, the reference electrically conductive layer 46R is embedded within a backside blocking dielectric layer 44; the flange portion 86F has a first thickness t1; and the reference electrically conductive layer 46R comprises a distal first portion that is distal from the flange portion 86F and has a second thickness t2 that is greater than the first thickness t1, and further comprises a proximal second portion that contacts the flange portion 86F of the contact via structure and has a third thickness t3 that is less than the first thickness t1. In one embodiment, a cylindrical interface between the contact via structure 86 and the reference electrically conductive layer 46R may be laterally offset inside from a vertically-extending cylindrical plane VCP that contains outer cylindrical sidewalls of an underlying vertical stack of annular insulating fins 40.

In one embodiment, the flange portion 86F of the contact via structure 86 may include protruding portions 86P that laterally protrude above and below the reference electrically conductive layer 46R. The protruding portions 86P contact an annular top surface segment and an annular bottom surface segment of the reference electrically conductive layer 46R. In one embodiment, the flange portion 86F of each contact via structure 86 can have a peripheral portion having a same vertical thickness as a vertical spacing between a bottom surface of the first annular silicon oxide plate portion of an underlying first silicon oxide liner 411 and a top surface of the second annular silicon oxide plate portion of an overlying second silicon oxide liner 412.

The protruding portions 86P include vertical cylindrical surfaces which contact the vertical cylindrical surfaces of respective protruding portions 44P the backside blocking dielectric layer 44. The protruding portions 44P the backside blocking dielectric layer 44 provide additional dielectric protection to the second portion of the reference electrically conductive layer 46P to reduce leakage current between the reference electrically conductive layer 46P and an underlying electrically conductive layer 146.

Referring to FIGS. 39-42E and according to various embodiments of the present disclosure, a memory device comprises: an alternating stack {(132, 232), (146, 246)} of insulating layers (132, 232) and electrically conductive layers (146, 246); memory openings 49 vertically extending through the alternating stack {(132, 232), (146, 246)}; memory opening fill structures 58 located in the memory openings 49, wherein each of the memory opening fill structures 58 comprises a respective vertical stack of memory elements (e.g., portions of the charge storage material layer 54 located at levels of electrically conductive layers (146, 246)) and a vertical semiconductor channel 60; and a contact via structure 86 contacting a reference electrically conductive layer 46R that is one of the electrically conductive layers (146, 246), and at least one silicon oxide liner (411, 412) laterally surrounding a cylindrical portion 86C of the contact via structure and contacting a laterally protruding portion 86F of the contact via structure.

In one embodiment, the cylindrical portion 86C of the contact via structure 86 has a top surface located above a horizontal plane including a topmost surface of the alternating stack {(132, 232), (146, 246)} and a bottom surface located at or below a horizontal plane including a bottommost surface of the alternating stack {(132, 232), (146, 246)}; and the laterally protruding portion comprises a flange portion 86F having an annular top surface, an annular bottom surface, and a vertical cylindrical surface that contacts the vertical cylindrical sidewall of the reference electrically conductive layer 46R.

In one embodiment, a vertical stack of annular insulating fins 40 may laterally surround the cylindrical portion 86C of the contact via structure 86 and underlying the flange portion 86F. In one embodiment, the vertical stack of annular insulating fins 40 is located at levels of a subset of the electrically conductive layers (146, 246) that underlies the reference electrically conductive layer 46R.

In one embodiment, the at least one silicon oxide liner (411, 412) comprises a first silicon oxide liner 411 comprising a first cylindrical silicon oxide portion interposed between the contact via structure 86 and the vertical stack of annular insulating fins 40. In one embodiment, the first silicon oxide liner 411 comprises a first annular silicon oxide plate portion 411P contacting the annular bottom surface of the flange portion 86F of the contact via structure 86. In one embodiment, outer cylindrical sidewalls of the vertical stack of annular insulating fins 40 are located within a vertically-extending cylindrical plane VCP including an outer cylindrical sidewall of the first annular silicon oxide plate portion 411P.

In one embodiment, the first silicon oxide liner 411 further comprises a bottom plate portion 411B adjoined to a bottom periphery of the first cylindrical silicon oxide portion and located underneath a horizontal plane including a bottom surface of a bottommost electrically conductive layer (146, 246) within the alternating stack {(132, 232), (146, 246)}. In one embodiment, a substrate dielectric liner 3 comprising an oxide of a semiconductor material in the substrate may contact a bottom surface of the bottom plate portion.

In one embodiment, a dielectric material portion (such as a stepped dielectric material portion 65) may overlie the flange portion 86F of the contact via structure 86 and may laterally surround the cylindrical portion 86C of the contact via structure 86. A top surface of the dielectric material portion is located below a horizontal plane including the top surface of the contact via structure 86.

In one embodiment, the at least one silicon oxide liner (411, 412) further comprises a second silicon oxide liner 412 interposed between the contact via structure 86 and the dielectric material portion (such as a stepped dielectric material portion 65). The second silicon oxide liner 412 may have a same material composition and a same thickness as the first silicon oxide liner 411. In one embodiment, the second silicon oxide liner 412 comprises: a second cylindrical silicon oxide portion laterally surrounding and contacting a segment of a cylindrical portion 86C of the contact via structure 86 that overlies the flange portion 86F; and a second annular silicon oxide plate portion 412P that contacts the annular top surface of the flange portion 86F of the contact via structure 86. In one embodiment, the second silicon oxide liner 412 is disjoined from the first silicon oxide liner 411; and a vertical distance between the second silicon oxide liner 412 and the first silicon oxide liner 411 equals a thickness of the flange portion 86F of the contact via structure 86.

In one embodiment shown in FIG. 41E, the reference electrically conductive layer 46R is embedded within a backside blocking dielectric layer 44; the flange portion 86F has a first thickness t1; and the reference electrically conductive layer 46R has a second thickness t2 that is greater than the first thickness t1.

In one embodiment shown in FIG. 42E, the reference electrically conductive layer 46R is embedded within a backside blocking dielectric layer 44; the flange portion 86F has a first thickness t1; and the reference electrically conductive layer 46R comprises a distal first portion that is distal from the flange portion 86F and has a second thickness t2 that is greater than the first thickness t1, and further comprises a proximal second portion that contacts the flange portion 86F and has a third thickness t3 that is less than the first thickness t1.

The contact via structures 86 described with reference to FIGS. 39-42E and related drawings vertically extend through each layer within an alternating stack {(132, 232), (146, 246)} of insulating layers (132, 232) and electrically conductive layers (146, 246), and are herein referred to as through-stack contact via structures. The through-stack via structures can be employed to provide reliable electrical contact to the respective reference electrically conductive layer 46R with a reduced leakage current to adjacent electrically conductive layers in the alternating stack. The plate portion 411P of the silicon oxide dielectric liner 411 provides increased isolation between the flange portion 86F of the contact via structure 86 and the underlying electrically conductive layer in the alternating stack, in case the insulating layer 132 between the reference electrically conductive layer 46R and the underlying electrically conductive layer 146 is excessively thinned during processing.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A memory device, comprising:
an alternating stack of insulating layers and electrically conductive layers located over a substrate;
memory openings vertically extending through the alternating stack;
memory opening fill structures located in the memory openings, wherein each of the memory opening fill structures comprises a respective vertical semiconductor channel and a vertical stack of memory elements;
a contact via structure contacting a reference electrically conductive layer that is one of the electrically conductive layers; and
at least one silicon oxide liner laterally surrounding a cylindrical portion of the contact via structure and contacting a laterally protruding portion of the contact via structure.

2. The memory device of claim 1, wherein:
the cylindrical portion of the contact via structure has a top surface located above a horizontal plane including a topmost surface of the alternating stack and a bottom surface located at or below a horizontal plane including a bottommost surface of the alternating stack; and
the laterally protruding portion of the contact via structure comprises a flange portion having an annular top surface, an annular bottom surface, and a vertical cylindrical surface that contacts a vertical cylindrical sidewall of the reference electrically conductive layer.

3. The memory device of claim 2, further comprising a vertical stack of annular insulating fins laterally surrounding the cylindrical portion of the contact via structure and underlying the flange portion.

4. The memory device of claim 3, wherein the vertical stack of annular insulating fins is located at levels of a subset of the electrically conductive layers that underlies the reference electrically conductive layer.

5. The memory device of claim 3, wherein:
the at least one silicon oxide liner comprises a first silicon oxide liner; and
the first silicon oxide liner comprises a first cylindrical silicon oxide portion interposed between the contact via structure and the vertical stack of annular insulating fins.

6. The memory device of claim 5, wherein the first silicon oxide liner further comprises a first annular silicon oxide plate portion contacting the annular bottom surface of the flange portion of the contact via structure.

7. The memory device of claim 6, wherein outer cylindrical sidewalls of the vertical stack of annular insulating fins are located within a vertically-extending cylindrical plane including an outer cylindrical sidewall of the first annular silicon oxide plate portion.

8. The memory device of claim 5, wherein the first silicon oxide liner further comprises a bottom plate portion adjoined to a bottom periphery of the first cylindrical silicon oxide portion and located underneath a horizontal plane including a bottom surface of a bottommost electrically conductive layer within the alternating stack.

9. The memory device of claim 8, further comprising a substrate dielectric liner comprising an oxide of a semiconductor material in the substrate and contacting a bottom surface of the bottom plate portion.

10. The memory device of claim 5, further comprising a dielectric material portion overlying the flange portion of the contact via structure and laterally surrounding the cylindrical portion of the contact via structure, wherein a top surface of the dielectric material portion is located below a horizontal plane including the top surface of the contact via structure.

11. The memory device of claim 10, wherein the at least one silicon oxide liner further comprises a second silicon oxide liner interposed between the contact via structure and the dielectric material portion and having a same material composition and a same thickness as the first silicon oxide liner.

12. The memory device of claim 11, wherein the second silicon oxide liner comprises:
a second cylindrical silicon oxide portion laterally surrounding and contacting a segment of a cylindrical portion of the contact via structure that overlies the flange portion; and
an annular silicon oxide plate portion that contacts the annular top surface of the flange portion of the contact via structure.

13. The memory device of claim 11, wherein:
the second silicon oxide liner is disjoined from the first silicon oxide liner; and
a vertical distance between the second silicon oxide liner and the first silicon oxide liner equals a thickness of the flange portion of the contact via structure.

14. The memory device of claim 2, wherein:
the reference electrically conductive layer is embedded within a backside blocking dielectric layer;
the flange portion has a first thickness; and
the reference electrically conductive layer has a second thickness that is greater than the first thickness.

15. The memory device of claim 2, wherein:
the reference electrically conductive layer is embedded within a backside blocking dielectric layer;
the flange portion has a first thickness; and
the reference electrically conductive layer comprises a distal portion that is distal from the flange portion and has a second thickness that is greater than the first thickness, and further comprises a proximal portion that contacts the flange portion and has a third thickness that is less than the first thickness.

16. A method of forming a device structure, comprising:
forming an alternating stack of insulating layers and sacrificial material layers over a substrate;
forming stepped surfaces by pattering the alternating stack;
forming a sacrificial material plate on a top surface segment of one of the sacrificial material layers;
forming a dielectric material portion over the sacrificial material plate and over the stepped surfaces;
forming a contact via cavity through the dielectric material portion, the sacrificial material plate, and a portion of the alternating stack that underlies the sacrificial material plate;
laterally expanding the contact via cavity by laterally recessing at least the sacrificial material plate and said one of the sacrificial material layers to expand the contact via cavity to include a fin cavity;
forming a sacrificial via fill structure in the contact via cavity;
replacing the sacrificial material layers with electrically conductive layers; and
replacing the sacrificial via fill structure with a contact via structure such that the contact via structure contacts a vertical cylindrical sidewall of one of the electrically conductive layers.

17. The method of claim 16, wherein:
the contact via cavity is laterally expanded by performing an isotropic etch process that isotropically etches the sacrificial material plate, said one of the sacrificial material layers, and additional sacrificial material layers of the sacrificial material layers in the alternating stack that underlie said one of the sacrificial material layers; and
the method further comprises forming a vertical stack of annular insulating fins in fin cavities that are formed by isotropically etching the additional sacrificial material layers.

18. The method of claim 17, further comprising:
forming memory openings vertically extending through the alternating stack; q
forming memory opening fill structures located in the memory openings, each memory opening fill structure comprising a respective vertical semiconductor channel and a vertical stack of memory elements; and
performing a selective silicon oxide deposition process that grows a silicon oxide material from physically exposed surfaces of the insulating layers and the vertical stack of annular insulating fins while suppressing growth of the silicon oxide material from a physically exposed surface of a remaining portion of the sacrificial material plate.

19. The method of claim 18, wherein the selective silicon oxide deposition process forms:
a first silicon oxide liner grown from the physically exposed surfaces of the insulating layers and the vertical stack of annular insulating fins; and
a second silicon oxide liner grown from a surface of the dielectric material portion around the contact via cavity and vertically spaced from the first silicon oxide liner by a gap.

20. The method of claim 16, wherein the sacrificial material plate is formed by:
anisotropically depositing a sacrificial plate material layer over the stepped surfaces such that horizontally-extending portions of the sacrificial plate material layer has a greater thickness than vertically-extending portions of the sacrificial plate material layer; and
etching the sacrificial plate material layer to thin the horizontally-extending portions of the sacrificial plate material layer and to completely remove the vertically-extending portions of the sacrificial plate material layer, wherein the sacrificial material plate comprises a remaining portion of the sacrificial plate material layer.
